(19) United States
(12) Patent Application Publication
(10) Pub. No.: US 2025/0294839 A1
(43) Pub. Date: Sep. 18, 2025

(54) METHOD FOR MANUFACTURING GROUP 3 NITRIDE SEMICONDUCTOR TEMPLATE AND SEMICONDUCTOR TEMPLATE MANUFACTURED THEREBY

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,627

(22) PCT Filed: Aug. 23, 2023
(86) PCT No.: PCT/KR2023/012453

§ 371 Date: Oct. 26, 2024

(30) Foreign Application Priority Data
Aug. 23, 2022 (KR) 10-2022-0105324
Sep. 29, 2022 (KR) 10-2022-0124414
Oct. 6, 2022 (KR) 10-2022-0127685
Oct. 6, 2022 (KR) 10-2022-0127687
Oct. 24, 2022 (KR) 10-2022-0137143
Nov. 28, 2022 (KR) 10-2022-0161635
Nov. 28, 2022 (KR) 10-2022-0161644
Jan. 10, 2023 (KR) 10-2023-0003479
Jan. 16, 2023 (KR) 10-2023-0006171

(51) Int. Cl. H10D 62/824; H10D 30/47; H10H 20/825

(52) U.S. Cl. CPC H10D 62/824; H10D 30/471; H10H 20/825

(57) ABSTRACT

The present invention relates to a method for manufacturing a group 3 nitride semiconductor template and a semiconductor template manufactured thereby, wherein a laser lift-off technique and a chemical lift-off technique are used so that a high-quality group 3 nitride semiconductor layer can be formed on the top of a high heat dissipation support substrate having the same or a similar lattice constant and thermal expansion coefficient.

### TECHNICAL FIELD

The present invention relates to a method of manufacturing a group III nitride semiconductor template and a semiconductor template manufactured using the same.

### BACKGROUND ART

In conventional gallium nitride (GaN) material-based power semiconductor (high electron mobility transistor (HEMT)) devices with a horizontal channel structure based on a technology that directly grows gallium nitride (GaN) materials on a silicon (Si) single crystalline growth substrate wafer, a design that suppresses a leakage current of a power semiconductor device through a high-quality epitaxy thin film growth technology with high breakdown voltage and high reliability characteristics is essential to allow the corresponding device to be driven stably at a high temperature with high voltage and/or high-speed switching functions.

To this end, conventional group III nitride semiconductor thin film materials and power semiconductor device structures have a structure in which 1) a silicon (Si) single crystalline growth substrate wafer having high electrical resistance characteristics, 2) a melt-back etching prevention layer containing aluminum nitride (AlN) materials (a nitride or nitride oxide including an aluminum (Al) composition) for suppressing a melt-back etching phenomenon through reaction at a high temperature with a surface layer of the silicon (Si) single crystalline growth substrate wafer, 3) a crack prevention compressive stress layer containing aluminum gallium nitride (AlGaN) materials (group III nitride including an aluminum (Al) or gallium (Ga) composition), and 4) an active layer of the power semiconductor containing gallium nitride (GaN) materials (group III nitride including a gallium (Ga) composition) are formed by being sequentially stacked.

In addition, the above-described active layer of the power semiconductor (HEMT) with the horizontal channel structure containing the gallium nitride (GaN) materials is typically formed by stacking four regions: 1) a gallium nitride (GaN) buffer layer, 2) a gallium nitride (GaN) channel layer (horizontal transistor), 3) an aluminum gallium nitride (AlGaN) barrier layer, and 4) a capping passivation layer (depletion mode) or p-type nitride semiconductor layer (enhancement mode).

That is, in the conventional group III nitride power semiconductor (HEMT) device structure in which the gallium nitride (GaN) materials are grown directly on the silicon (Si) single crystalline growth substrate wafer, the high-resistance silicon (Si) single crystalline growth substrate wafer is necessarily applied together with the formation of the high resistance gallium nitride (GaN) buffer layer under the gallium nitride (GaN) channel layer, but there are the following problems.

First, in the conventional group III nitride (gallium nitride (GaN) materials) power semiconductor (HEMT) device structure, a process is performed such that the gallium nitride (GaN) material-based single crystalline thin film and the power semiconductor device structure are directly grown on the silicon (Si) single crystalline wafer for a group III nitride power semiconductor growth substrate using a metal organic chemical vapor deposition (MOCVD) device. In this case, a process of growing (depositing) the gallium nitride (GaN) material-based single crystalline thin film containing gallium (Ga) atoms is basically performed at a high temperature of about 1000° C. and in a reducing atmosphere (H2, H+, NH3, radical ions), and the melt-back etching prevention film region for blocking Si—Ga metallic eutectic reactions from actively occurring between the silicon (Si) single crystalline wafer surface layer and the gallium (Ga) atoms with relatively small energy is absolutely needed.

The melt-back etching prevention film region may typically have a thickness of about 100 nm, and there is representatively an aluminum nitride (AlN) material layer grown by an in-situ process in a MOCVD chamber, but in addition, an aluminum nitride (AlN) or aluminum nitride oxide (AlNO) material layer may be deposited by an ex-situ process on the silicon (Si) single crystalline wafer for a group III nitride power semiconductor growth substrate before loading the silicon (Si) single crystalline wafer in the MOCVD chamber using another external deposition process device (sputter, pulsed laser deposition (PLD), atomic layer deposition (ALD)).

However, when the melt-back etching prevention film region is formed with the above-described aluminum nitride (AlN) material layer on the silicon (Si) single crystalline wafer for a growth substrate with electrically high resistance characteristics, there is a problem that although the level of damage to the surface of the silicon (Si) growth substrate is less during the growth of the aluminum nitride (AlN), the Si—Al metallic process reaction still occurs entirely or locally on the surface of the silicon (Si) growth substrate to form a conductive interface material layer, resulting in crystal quality deterioration of the gallium nitride (GaN) materials grown in a continuous process. In addition, there is a problem that the crystal quality deteriorates (crystallinity reduction) due to the formation of the conductive interface material (disordered SiAlN) caused by damage to the surface of the silicon (Si) growth substrate, and as a result, a leakage current increases due to an increase in a dislocation density, which is a major crystal defect, which ultimately promotes the insulation breakdown phenomenon.

Second, in the above-described conventional group III nitride (GaN material-based) power semiconductor (HEMT) device structure, when a material is grown (or deposited), a process needs to be performed in consideration of a lattice constant (LC) and coefficient of thermal expansion (CTE), which are material-specific values between different heterogeneous materials, and when the lattice constant (LC) and coefficient of thermal expansion (CTE) between the two materials are significantly different, micro or macro cracks inevitably occur in the grown (deposited) material thin film or the crystal quality deteriorates due to structural stress and thermo-mechanical induced stress occurring during or after the growth (deposition) process. In particular, when the gallium nitride (GaN) materials or the aluminum nitride (AlN) materials are directly grown (or deposited) on the Si single crystalline wafer for a group III nitride power semiconductor growth substrate, strong tensile stress is generated in terms of the coefficient of thermal expansion (CTE) and/or the lattice constant (LC), and thus not only cracking may be easily observed, but also a high breakdown voltage and high reliability device may be implemented through the growth to a predetermined thickness or more, but a thickness of the group III nitride power semiconductor device structure may not be large due to the tensile stress.

Although various technologies have been devised as a method of relieving the above-described tensile stress or suppressing cracks, as a method of introducing a material and process of artificially generating compressive stress to compensate for and relieve the tensile stress, a crack prevention compressive stress layer that suppresses the cracking by stacking the aluminum gallium nitride (AlGaN) materials containing the aluminum (Al) or gallium (Ga) composition on the above-described melt-back etching prevention film region in the already known multilayered structure is being introduced and used.

However, the crack prevention compressive stress layer with the above-described conventional group III nitride (GaN material-based) power semiconductor (HEMT) device structure has a problem that it is difficult to grow a high-quality thick layer when forming aluminum gallium nitride (AlGaN) materials with a high aluminum (Al) ratio, and dislocations are caused by a reduction in crystal quality, thereby promoting an increase in leakage current.

Third, in the conventional group III nitride (GaN material-based) power semiconductor (HEMT) device structure, to suppress a leakage current under the gallium nitride (GaN) channel layer, a gallium nitride (GaN) buffer layer heavily doped with impurities such as iron (Fe) or carbon (C) to have high resistance is typically formed.

However, according to the conventional group III nitride (GaN material-based) power semiconductor (HEMT) device structure, there is a problem that the crystal quality of the gallium nitride (GaN) materials greatly deteriorates due to excessively doped iron (Fe) or carbon (C) impurities, and a fatal crystal defect, that is, increased dislocation density, thereby promoting an increase in leakage current. In addition, due to the low crystal quality of the gallium nitride (GaN) buffer layer, the gallium nitride (GaN) channel layer and aluminum gallium nitride (AlGaN) barrier layer grown on the same in a continuous process also have a problem of low crystal quality.

Meanwhile, in the conventional GaN on sapphire technology, that is, a technology that directly grows a single crystalline GaN material-based device epitaxy on a single crystalline sapphire growth substrate wafer at a high temperature, the three influencing factors of a difference (ΔT) in surface temperature, a difference (Δa) in lattice constant, and a difference (Δα) in coefficient of thermal expansion between upper and lower portions of the sapphire substrate gradually induce stress in the GaN epitaxy, resulting in the phenomenon such as concave or convex bowing.

As shown in FIG. 26, first, describing the first influencing factor, in a stage before high-temperature growth, while a bottom face located close to a heating system is hotter (normally, the wafer heating system is disposed under a wafer), a top face is colder, and thus due to first stress caused by the difference (ΔT) in surface temperature between the upper and lower portions of the sapphire growth substrate, there is a problem that while a lower surface of the sapphire growth substrate wafer exhibits a tensile behavior, an upper surface exhibits a compressive behavior, and the overall shape of the wafer exhibits the concave bowing phenomenon. In this case, the concave bowing phenomenon is typically more prominent as an area of the growth substrate wafer is larger and a growth temperature is higher.

Next, describing the second influencing factor, in a high-temperature growth stage, wafer bowing occurs due to second stress caused by the difference (Δa) in the lattice constant (LC, a), which is a unique property of the sapphire growth substrate wafer and the GaN materials, and typically, since the sapphire lattice constant (0.475 nm) is larger than that of the GaN materials (0.354 to 0.311 nm), there is a problem that tensile stress occurs inside the epitaxy during the growth process, causing the wafer shape to exhibit the concave bowing phenomenon. In this case, as the growth speed increases and the thickness increases, the stress increases, resulting in the phenomenon that a temperature gradient difference between a center and edge of the wafer becomes severe.

Due to the above-described first and second influencing factors, the epitaxy thickness dispersion increases due to the temperature gradient difference between the center and edge of the wafer, and at the same time, the non-uniformity of a composition ratio and the dopant doping amount of a ternary (InGaN, AlGaN, InAlN) or quaternary (AlGaInN) alloy material layer is large, resulting in issues of deterioration in performance, quality, and yield of the device.

Next, describing the third influencing factor, in a stage of cooling to room temperature of 25° C. after finishing high-temperature growth, there is a problem that wafer bowing occurs due to the difference (Δα) in coefficient of thermal expansion (CTE, α), which is a unique property of the sapphire growth substrate wafer and the GaN materials. Typically, since the coefficient of thermal expansion (6.8 ppm) of sapphire is much larger than that (4.5 to 6 ppm) of the GaN materials, compressive stress occurs inside the epitaxy, causing the wafer shape to exhibit the convex bowing behavior.

Due to the above-described three stress influencing factors, the following problems occur when GaN material-based device products are manufactured from the GaN on sapphire epitaxy wafer.

First, when micro LED devices are grown, the epitaxy wafer bowing phenomenon occurs due to the above-described three stress influencing factors, and thus the surface temperature difference between the center and edge regions causes non-uniformity of an indium (In) composition ratio during the growth of an InGaN-based active layer (multi quantum wells (MQWs)), which greatly disperses the wavelength and photoelectric characteristics (operating voltage, optical output) in the wafer and significantly affects the yield of good products, resulting in increased manufacturing costs. In addition, due to the wafer bowing phenomenon, the uniformity of the aluminum (Al) composition ratio and the doping amount of magnesium (Mg) that is a p-type dopant atom is degraded in the p-type AlGaN that serves as an electron blocking layer that is continuously, subsequently grown during the growth of micro LED devices with the InGaN-based active layer (MQWs), resulting in the issue of dispersion of the photoelectric characteristics in the wafer.

In addition, even when the power semiconductor device is grown, the above three stress influencing factors cause the epitaxy wafer bowing phenomenon, and thus there is a problem that the uniformity of the thickness and aluminum (Al) composition ratio of the AlGaN barrier with a thickness of about 20 nm in a HEMT with the horizontal channel structure is degraded, tensile stress further worsens during the growth of a thick GaN of 10 μm or more for the power semiconductor device with the vertical drift structure, thereby causing quality deterioration, and wafer bowing becomes severe during wafer cooling to room temperature after growth, thereby increasing the possibility of cracks.

In addition, even during the growth of a communication filter device, such as BAW or SAW, made of AlN materials, in a film device in which the crystallinity and thickness uniformity of AlN with high piezoelectricity significantly affect quality, there is a problem that the above three stress influencing factors cause the epitaxy wafer bowing phenomenon, and there is a problem that many cracks and quality deterioration occur inside AlN about 500 nm due to strong tensile stress during the growth of AlN. Typically, a thickness of about 1.5 μm is essentially required for use as an AlN communication filter.

### DISCLOSURE

### Technical Problem

The present invention has been made as a result of efforts to solve the conventional problems and is directed to providing a method of manufacturing a group III semiconductor template and a semiconductor template manufactured using the same, in which a high-quality group III nitride semiconductor layer may be formed on a high heat dissipation support substrate with an epitaxy growth surface having the same or similar lattice constant and coefficient of thermal expansion, using a laser lift off (LLO) technique and a chemical lift off (CLO) technique.

### Technical Solution

According to the present invention, the above object is achieved by a group III nitride semiconductor template including a support substrate, a bonding layer disposed on the support substrate, a group III nitride semiconductor channel layer disposed on the bonding layer, and a reinforcement layer disposed in contact with an upper surface or lower surface of the bonding layer so that bonding strength of the bonding layer is reinforced and compressive stress is induced.

According to the present invention, the above object is achieved by a method of manufacturing a group III nitride semiconductor template including a first operation of preparing a growth substrate, a temporary substrate, and a support substrate, a second operation of forming a first sacrificial layer on the growth substrate, growing a first group III nitride semiconductor buffer layer on the first sacrificial layer, and then growing a group III nitride semiconductor channel layer on the first group III nitride semiconductor buffer layer, a third operation of forming an epitaxy protection layer on the group III nitride semiconductor channel layer and then forming a first adhesive layer on the epitaxy protection layer, a fourth operation of forming a second sacrificial layer on the temporary substrate and then forming a second adhesive layer on the second sacrificial layer, a fifth operation of bonding the first adhesive layer and the second adhesive layer to form an adhesive layer, a sixth operation of separating the growth substrate from the first sacrificial layer using a laser lift off (LLO) technique, a seventh operation of etching and removing the first sacrificial layer or the group III nitride semiconductor buffer layer, an eighth operation of forming a first bonding layer on the first group III nitride semiconductor buffer layer or the group III nitride semiconductor channel layer, a ninth operation of forming a second bonding layer on the support substrate, a tenth operation of bonding the first bonding layer to form a bonding layer and the second bonding layer, an eleventh operation of separating the temporary substrate from the second sacrificial layer using an LLO technique, and a twelfth operation of etching and removing the second sacrificial layer, the adhesive layer, and the epitaxy protection layer.

According to the present invention, the above object is achieved by a method of manufacturing a group III nitride semiconductor template including a first operation of preparing a growth substrate, a temporary substrate, and a support substrate, a second operation of growing a seed layer on the growth substrate, a third operation of forming a first adhesive layer on the seed layer, forming a second adhesive layer on the temporary substrate, and then bonding the first adhesive layer and the second adhesive layer to form an adhesive layer, a fourth operation of separating the growth substrate from the seed layer using a laser lift off (LLO) technique, a fifth operation of forming a first bonding layer on the seed layer, forming a second bonding layer on the support substrate, and then bonding the first bonding layer and the second bonding layer to form a bonding layer, a sixth operation of separating the temporary substrate from the adhesive layer using an LLO technique, a seventh operation of etching and removing the adhesive layer, and an eighth operation of forming a device active layer on the seed layer.

According to the present invention, the above object is achieved by a method of manufacturing a group III nitride semiconductor template including a first operation of preparing a growth substrate, a temporary substrate, and a support substrate, a second operation of forming a first sacrificial layer on the growth substrate, growing a first buffer layer on the first sacrificial layer, and then growing a channel layer on the first buffer layer, a third operation of forming an epitaxy protection layer on the channel layer and then forming a first adhesive layer on the epitaxy protection layer, a fourth operation of forming a second sacrificial layer on the temporary substrate and then forming a second adhesive layer on the second sacrificial layer, a fifth operation of bonding the first adhesive layer and the second adhesive layer to form an adhesive layer, a sixth operation of separating the growth substrate from the first sacrificial layer using a chemical lift off (CLO) technique, a seventh operation of etching and removing the first sacrificial layer or etching and removing the first sacrificial layer and the first buffer layer, an eighth operation of forming a first bonding layer on the first buffer layer or forming the first bonding layer on the channel layer, a ninth operation of forming a second bonding layer on the support substrate, a tenth operation of bonding the first bonding layer and the second bonding layer to form a bonding layer, an eleventh operation of separating the temporary substrate from the second sacrificial layer using a CLO technique, and a twelfth operation of etching and removing the second sacrificial layer, the adhesive layer, and the epitaxy protection layer.

According to the present invention, the above object is achieved by a method of manufacturing a group III nitride semiconductor template including a first operation of preparing a growth substrate, a temporary substrate, and a support substrate, a second operation of forming a first sacrificial layer on the growth substrate, growing a first buffer layer on the first sacrificial layer, and then growing a channel layer on the first buffer layer, a third operation of forming a first adhesive layer on the channel layer, a fourth operation of forming a second sacrificial layer on the temporary substrate and then forming a second adhesive layer on the second sacrificial layer, a fifth operation of bonding the first adhesive layer and the second adhesive layer to form an adhesive layer, a sixth operation of separating the growth substrate from the first sacrificial layer using a laser lift off (LLO) technique, a seventh operation of etching and removing the first sacrificial layer, an eighth operation of forming a first bonding layer on the first buffer layer, a ninth operation of forming a second bonding layer on the support substrate, a tenth operation of bonding the first bonding layer and the second bonding layer to form a bonding layer, an eleventh operation of separating the temporary substrate from the second sacrificial layer using a chemical lift off (CLO) technique, and a twelfth operation of etching and removing the second sacrificial layer and the adhesive layer.

According to the present invention, the above object is achieved by a method of manufacturing a group III nitride semiconductor template including a first operation of preparing a growth substrate, a temporary substrate, and a support substrate, a second operation of forming a first sacrificial layer on the growth substrate, growing a first buffer layer on the first sacrificial layer, and then growing a channel layer on the first buffer layer, a third operation of forming a first adhesive layer on the channel layer, a fourth operation of forming a second sacrificial layer on the temporary substrate and then forming a second adhesive layer on the second sacrificial layer, a fifth operation of bonding the first adhesive layer and the second adhesive layer to form an adhesive layer, a sixth operation of separating the growth substrate from the first sacrificial layer using a chemical lift off (CLO) technique, a seventh operation of etching and removing the first sacrificial layer, an eighth operation of forming a first bonding layer on the first buffer layer, a ninth operation of forming a second bonding layer on the support substrate, a tenth operation of bonding the first bonding layer and the second bonding layer to form a bonding layer, an eleventh operation of separating the temporary substrate from the second sacrificial layer using a laser lift off (LLO) technique, and a twelfth operation of etching and removing the second sacrificial layer and the adhesive layer.

### Advantageous Effects

According to the present invention, since a reinforcement layer including a bonding reinforcement layer and a compressive stress layer, which have high-resistance insulation properties, on an upper surface (lower portion of a group III nitride semiconductor layer) or a lower surface (upper portion of a support substrate) of a bonding layer may be formed to effectively block a leakage current to the lower support substrate (or in a horizontal direction), a low-quality high-resistance gallium nitride (GaN) buffer layer doped with iron (Fe) or carbon (C) is not needed. Therefore, it is possible to secure a HEMT active region such as a high-quality gallium nitride (GaN) channel layer and aluminum nitride gallium (AlGaN) barrier layer by omitting the low-quality high-resistance gallium nitride (GaN) buffer layer, thereby significantly improving the reliability and performance of a power semiconductor device.

In addition, the present invention can be applied not only to implement high-quality power semiconductor devices but also to epitaxy growth of high-quality BGR (blue, green, red) micro LED structures.

In addition, according to the present invention, since it is not necessary to directly grow a melt-back etching prevention layer and a compressive stress layer that are essential for the growth substrate of the related art, a high-quality aluminum nitride gallium (AlGaN) barrier layer can be grown on the high-quality group III nitride semiconductor layer. In addition, compared to a method of directly growing the melt-back etching prevention layer and the compressive stress layer on the conventional silicon (Si) growth substrate, a high-quality group III nitride semiconductor layer having few defects can be grown. In addition, since the growth of the melt-back etching prevention layer and the compressive stress layer is excluded, it is possible to implement a group III nitride power semiconductor structure (particularly, a HEMT) with a smaller thickness than before, thereby improving material costs and yield.

In addition, according to the present invention, a compressive stress layer can be introduced and used between gallium nitride (GaN) materials (a gallium nitride (GaN) buffer or a gallium nitride (GaN) channel) and a sapphire growth substrate through an external deposition process. That is, the growth of the thick gallium nitride (GaN) materials with a predetermined thickness or more without cracks is possible even without a compressive stress layer, such as aluminum nitride gallium (AlGaN) or aluminum nitride/gallium nitride (AlN/GaN SLs) with a superlattice structure, which is grown by an in-situ process in a metal organic chemical vapor deposition (MOCVD) chamber. In addition, instead of a gallium nitride (GaN) buffer layer and a gallium nitride (GaN) channel layer, aluminum nitride (AlN), aluminum oxide (Al2O3), etc. with a leakage current blocking function and physical properties such as a larger coefficient of thermal expansion than a sapphire support substrate can be grown thickly, and a power semiconductor device using the same can be implemented.

In addition, it is possible to re-grow a high-quality group III nitride semiconductor thin film by having a surface (structure in which a growth substrate separation surface and a final support substrate bonding surface have the same polarity) through a laser lift off (LLO) and chemical lift off (CLO) process.

Meanwhile, the effects of the present invention are not limited to the above-described effects, and may include various effects within a range that is apparent to those skilled in the art from the following descriptions.

### DESCRIPTION OF DRAWINGS

FIG. 1 shows a group III nitride semiconductor template according to a first embodiment of the present invention.

FIG. 2 shows that a re-growth layer is re-grown on the group III nitride semiconductor template according to the first embodiment of the present invention.

FIG. 3 is a flowchart of a method of manufacturing a group III nitride semiconductor template according to the first embodiment of the present invention.

FIG. 4 shows a process of manufacturing the group III nitride semiconductor template according to the first embodiment of the present invention.

FIG. 5 shows a group III nitride semiconductor template according to a second embodiment of the present invention.

FIG. 6 shows that a re-growth layer is re-grown on the group III nitride semiconductor template according to the second embodiment of the present invention.

FIG. 7 is a flowchart of a method of manufacturing a group III nitride semiconductor template according to the second embodiment of the present invention.

FIG. 8 shows a process of manufacturing the group III nitride semiconductor template according to the second embodiment of the present invention.

FIG. 9 shows a group III nitride semiconductor template according to a third embodiment of the present invention.

FIG. 10 shows that a re-growth layer is re-grown on the group III nitride semiconductor template according to the third embodiment of the present invention.

FIG. 11 is a flowchart of a method of manufacturing a group III nitride semiconductor template according to the third embodiment of the present invention.

FIG. 12 shows a process of manufacturing the group III nitride semiconductor template according to the third embodiment of the present invention.

FIG. 13 shows a group III nitride semiconductor template according to a fourth embodiment of the present invention.

FIG. 14 shows that a re-growth layer is re-grown on the group III nitride semiconductor template according to the fourth embodiment of the present invention.

FIG. 15 is a flowchart of a method of manufacturing a group III nitride semiconductor template according to the fourth embodiment of the present invention.

FIG. 16 shows a process of manufacturing the group III nitride semiconductor template according to the fourth embodiment of the present invention.

FIG. 17 shows a group III nitride semiconductor template according to a fifth embodiment of the present invention.

FIG. 18 shows that a re-growth layer is re-grown on the group III nitride semiconductor template according to the fifth embodiment of the present invention.

FIG. 19 is a flowchart of a method of manufacturing a group III nitride semiconductor template according to the fifth embodiment of the present invention.

FIG. 20 shows a process of manufacturing the group III nitride semiconductor template according to the fifth embodiment of the present invention.

FIG. 21 shows a group III nitride semiconductor template according to a sixth embodiment of the present invention.

FIG. 22 shows that a re-growth layer is re-grown on the group III nitride semiconductor template according to the sixth embodiment of the present invention.

FIG. 23 is a flowchart of a method of manufacturing a group III nitride semiconductor template according to the sixth embodiment of the present invention.

FIG. 24 shows a process of manufacturing the group III nitride semiconductor template according to the sixth embodiment of the present invention.

FIG. 25 shows a reinforcement layer disposed in various ways on the group III nitride semiconductor template according to the first embodiment to the sixth embodiment of the present invention.

FIG. 26 shows an epitaxy wafer shape for each product according to a surface temperature difference, a lattice constant difference, and a coefficient of thermal expansion difference between upper and lower portions of a sapphire growth substrate in a GaN on sapphire technology according to the related art.

FIG. 27 is a flowchart of a method of manufacturing a group III nitride semiconductor template according to seventh to ninth embodiments of the present invention.

FIG. 28 shows a process of manufacturing a semiconductor device by the method of manufacturing a group III nitride semiconductor template according to the seventh to ninth embodiments of the present invention.

FIG. 29 shows that the semiconductor device is formed on the semiconductor template manufactured by the method of manufacturing a group III nitride semiconductor template according to the seventh to ninth embodiments of the present invention.

FIG. 30 shows an epitaxy wafer shape for each product according to a surface temperature difference, a lattice constant difference, and a coefficient of thermal expansion difference between upper and lower portions of a sapphire support substrate in the semiconductor device manufactured by the method of manufacturing a group III nitride semiconductor template according to the seventh to ninth embodiments of the present invention.

FIG. 31 is a flowchart of a method of manufacturing a group III nitride semiconductor template according to a tenth embodiment of the present invention.

FIG. 32 shows a process of manufacturing the group III nitride semiconductor template according to the tenth embodiment of the present invention.

FIG. 33 is a flowchart of a method of manufacturing a group III nitride semiconductor template according to an eleventh embodiment of the present invention.

FIG. 34 shows a process of manufacturing the group III nitride semiconductor template according to the eleventh embodiment of the present invention.

FIG. 35 is a flowchart of a method of manufacturing a group III nitride semiconductor template according to a twelfth embodiment of the present invention.

FIG. 36 shows a process of manufacturing the group III nitride semiconductor template according to the twelfth embodiment of the present invention.

FIG. 37 shows another process of manufacturing the group III nitride semiconductor template according to the twelfth embodiment of the present invention.

FIG. 38 is a flowchart of a method of manufacturing a group III nitride semiconductor template according to a thirteenth embodiment of the present invention.

FIG. 39 shows a process of manufacturing the group III nitride semiconductor template according to the thirteenth embodiment of the present invention.

FIG. 40 is a flowchart of a method of manufacturing a group III nitride semiconductor template according to a fourteenth embodiment of the present invention.

FIG. 41 shows a process of manufacturing the group III nitride semiconductor template according to the fourteenth embodiment of the present invention.

FIG. 42 is a flowchart of a method of manufacturing a group III nitride semiconductor template according to a fifteenth embodiment of the present invention.

FIG. 43 shows a process of manufacturing the group III nitride semiconductor template according to the fifteenth embodiment of the present invention.

FIG. 44 shows a reinforcement layer disposed in various ways on the group III nitride semiconductor template according to the tenth embodiment to the fifteenth embodiment of the present invention.

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another, and the nature, sequence, order, or the like of the corresponding component is not limited by the terms.

Hereinafter, a group III nitride semiconductor template according to a first embodiment of the present invention will be described in detail with reference to the accompanying drawings.

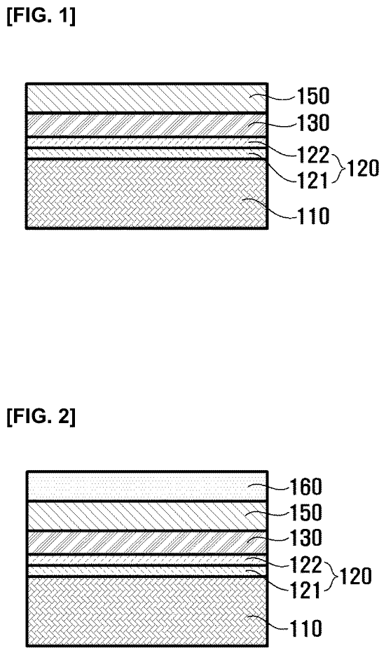

FIG. 1 shows a group III nitride semiconductor template according to a first embodiment of the present invention, and FIG. 2 shows that a re-growth layer is re-grown on the group III nitride semiconductor template according to the first embodiment of the present invention.

As shown in FIGS. 1 and 2, the group III nitride semiconductor template according to the first embodiment of the present invention includes a support substrate 110, a reinforcement layer 120, a bonding layer 130, and a group III nitride semiconductor channel layer thickness of each layer may vary depending on the type of a power semiconductor device and a growth substrate G that are applied.

The support substrate 110 is a substrate that supports the group III nitride semiconductor channel layer 150 and a re-growth layer 160 re-grown on the group III nitride semiconductor channel layer 150, and the support substrate 110 may be made of a material that has high heat dissipation performance (60 W/mK or more) and has a coefficient of thermal expansion (CTE, ppm) that is equal to or less than that of the group III nitride semiconductor channel layer 150 (GaN CTE about 5.6 ppm) and may be formed in a polycrystalline or single crystalline microstructure.

More specifically, the support substrate 110 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 110. In addition, the silicon (Si) or silicon carbide (SiC) support substrate 110 is preferably formed in a polycrystalline microstructure through a high-temperature sintering process rather than a single crystalline microstructure wafer, and thus there is an advantage in that it is possible to secure cost competitiveness.

The bonding layer 130 is used to bond the support substrate 110 and the group III nitride semiconductor channel layer 150, may be disposed on the reinforcement layer 120 to be described below, and made of a permanent bonding material.

More specifically, the bonding layer 130 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as spin on glass (SOG) or hydrogen silsesquioxane (HSQ) to improve surface roughness. In particular, it is preferable to use a chemical vapor deposition (CVD) process such as a metal organic chemical vapor deposition (MOCVD) or atomic layer deposition (ALD) process for aluminum nitride (AlN), aluminum gallium nitride (AlGaN), gallium nitride (GaN), indium gallium nitride (InGaN), and indium nitride (InN) materials.

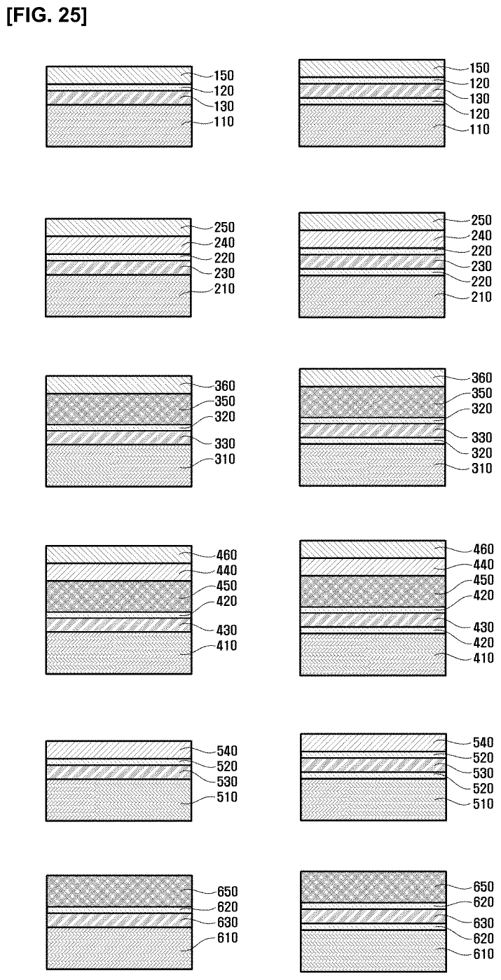

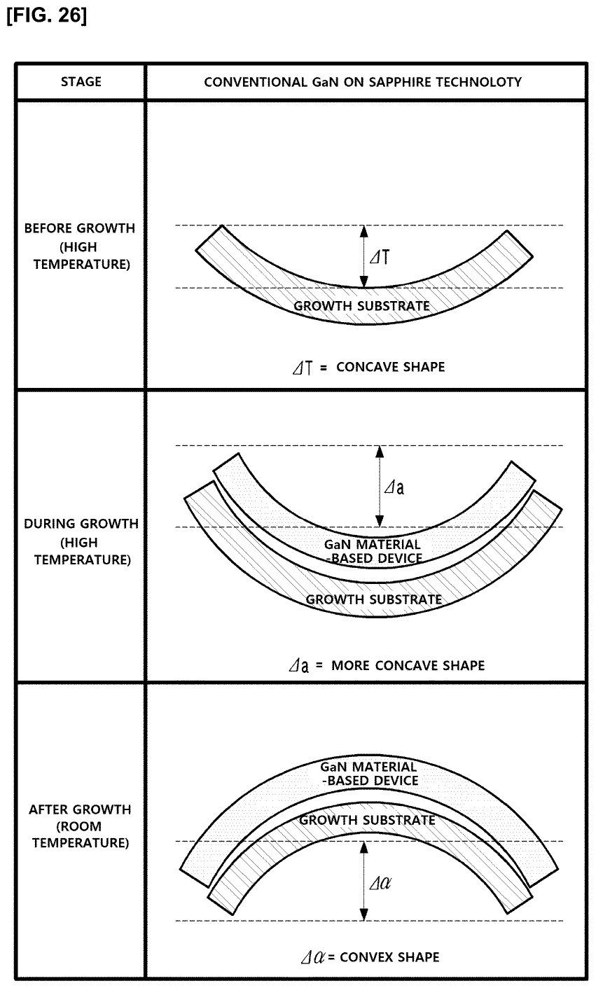

The reinforcement layer 120 is formed so that the group III nitride semiconductor channel layer 150 may be more strongly bonded to the support substrate 110, induces compressive stress, and is disposed in contact with an upper surface or lower surface of the bonding layer 130. That is, as shown in FIG. 25, the reinforcement layer 120 may be disposed between the support substrate 110 and the bonding layer 130 and/or between the group III nitride semiconductor layer and the bonding layer 130.

More specifically, the reinforcement layer 120 includes a bonding reinforcement layer 121 and a compressive stress layer 122.

The bonding reinforcement layer 121 is a layer introduced to reinforce bonding strength when the group III nitride semiconductor channel layer 150 is bonded on the final support substrate 110 through the bonding layer 130, and it is preferable that a material forming the bonding reinforcement layer 121 be preferentially selected from silicon oxide (SiO2), silicon nitride (SiNx), etc.

The compressive stress layer 122 is a layer that induces compressive stress and is made of a material that has a value larger than the coefficient of thermal expansion of the final support substrate 110, for example, a material that relieves tensile stress, that is, induces compressive stress, such as aluminum nitride (AlN, 4.6 ppm), aluminum nitride oxide (AlNO, 4.6 to 6.8 ppm; depending on a content ratio of AlN and Al2O3), or aluminum oxide (Al2O3, 6.8 ppm), which serves to induce the quality improvement of products through stress control.

Meanwhile, in the present invention, the bonding reinforcement layer 121 or the compressive stress layer 122 may be omitted in some cases, and in some cases, the entire reinforcement layer 120 may be omitted so that the support substrate 110 may be in direct contact with the bonding layer 130. This case is a structure in which a material with a larger coefficient of thermal expansion than the Si (or SiC) support substrate is deposited on the bonding layer 130 to induce compressive stress together with a bonding function, or the bonding reinforcement layer 121 or the compressive stress layer 122 is provided by being deposited on the surface of the group III nitride semiconductor channel layer 150 with a nitrogen polarity (not shown).

The group III nitride semiconductor channel layer 150 may be disposed on the bonding layer 130, formed of a single layer or multiple layers of group III nitride semiconductors, and made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), etc., which have high-temperature (HT) and high-resistance (HR) characteristics. The group III nitride semiconductor channel layer 150 is a critical quality factor in reducing fatal crystal defects, that is, the density of threading dislocations (present in a vertical direction with respect to an initial growth substrate G) (≤Low 108/cm2).

Then, a high-quality group III nitride semiconductor re-growth layer 160 may be re-grown on the group III nitride semiconductor channel layer 150. In this case, the re-grown re-growth layer 160 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

In addition, as needed, before directly re-growing the re-grown re-growth layer 160 on the group III nitride semiconductor channel layer 150, the channel layer 150 may be surface-treated in a MOCVD chamber and/or additionally, a separate channel layer may be grown and inserted using a group III nitride semiconductor having a larger energy band gap than the channel layer 150 (not shown).

Hereinafter, a method S100 of manufacturing the group III nitride semiconductor template according to the first embodiment of the present invention will be described in detail with reference to the accompanying drawings.

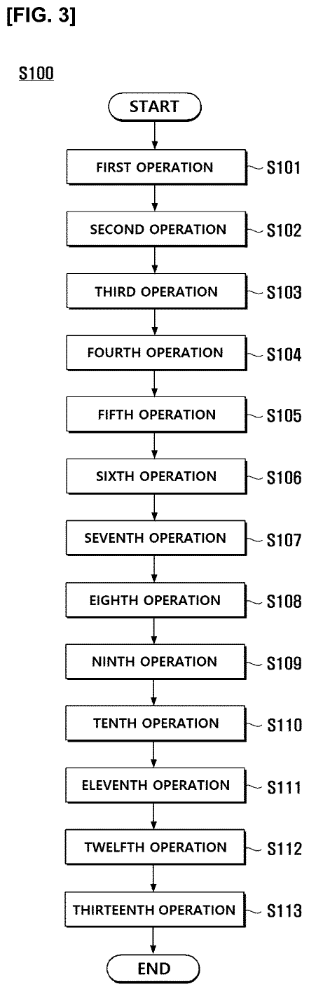

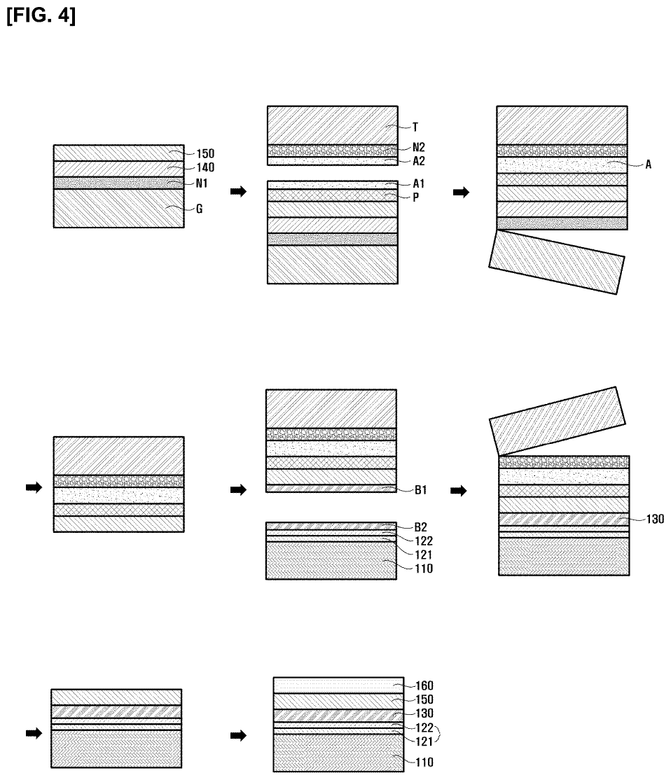

FIG. 3 is a flowchart of a method of manufacturing a group III nitride semiconductor template according to the first embodiment of the present invention, and FIG. 4 shows a process of manufacturing the group III nitride semiconductor template according to the first embodiment of the present invention.

As shown in FIGS. 3 and 4, the method S100 of manufacturing the group III nitride semiconductor template according to the first embodiment of the present invention includes a first operation S101, a second operation S102, a third operation S103, a fourth operation S104, a fifth operation S105, a sixth operation S106, a seventh operation S107, an eighth operation S108, a ninth operation S109, a tenth operation S110, an eleventh operation S111, a twelfth operation S112, and a thirteenth operation S113.

The first operation S101 is an operation of preparing the growth substrate G, a temporary substrate T, and the support substrate 110.

The growth substrate G is an optically transparent and high-temperature heat-resistant substrate in which a laser beam (single-wavelength light) is 100% transmitted (theoretically) without absorption after the group III nitride semiconductor channel layer 150 is grown and preferably, is preferentially made of a material such as sapphire (α-phase Al2O3), ScMgAlO4, 4H—SiC, or 6H-SiC. In addition, the growth substrate G preferably has a protrusion shape patterned regularly or irregularly in various dimensions (size and shape) in microscale or nanoscale to minimize crystal defects inside the group III nitride semiconductor thin film grown thereon.

The support substrate 110 is a substrate that supports the group III nitride semiconductor channel layer 150 and the re-growth layer 160 after undergoing each operation of the method S100 of manufacturing the group III nitride semiconductor template according to the first embodiment of the present invention, may be made of a material that has high heat dissipation performance (60 W/mK or more) and has a coefficient of thermal expansion (CTE, ppm) that is equal to or less than that of the group III nitride semiconductor channel layer 150 (GaN CTE about 5.6 ppm), and formed in a polycrystalline or single-crystalline microstructure.

More specifically, the support substrate 110 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 110. In addition, the silicon (Si) or silicon carbide (SiC) support substrate 110 is preferably formed in a polycrystalline microstructure through a high-temperature sintering process rather than a single crystalline microstructure wafer, and thus there is an advantage in that it is possible to secure cost competitiveness.

The temporary substrate T is made of a material that has a coefficient of thermal expansion that is the same as or similar to that of the growth substrate G and at the same time, optically transparent, and it is preferable that a difference in coefficient of thermal expansion with the growth substrate G does not exceed a maximum of 2 ppm. The most preferable temporary substrate T material that satisfies the above may include sapphire used as the group III nitride semiconductor growth substrate G, silicon carbide (SiC), or glass whose coefficient of thermal expansion (CTE) has been adjusted to have a difference of 2 ppm or less from the growth substrate G.

The second operation S102 is an operation of forming a first sacrificial layer N1 on the growth substrate G and then growing a high-quality group III nitride semiconductor layer (including a buffer layer and a channel layer) on the first sacrificial layer N1 in a single layer or multiple layers and specifically, is an operation of growing a high-quality group III nitride semiconductor buffer layer 140 on the first sacrificial layer N1 in a single layer or multiple layers and growing a high-quality group III nitride semiconductor channel layer 150 on the group III nitride semiconductor buffer layer 140 in a single layer or multiple layers.

Here, the first sacrificial layer N1 is a layer required for growing a high-quality group III nitride semiconductor layer (including the buffer layer and the channel layer) and may be made of a material capable of sacrificial separation by a thermal-chemical decomposition reaction caused by a laser beam, and for example, a sapphire growth substrate G may contain indium gallium nitride (InGaN), gallium nitride (GaN), aluminum gallium nitride (AlGaN), and indium aluminum nitride (InAlN), and a silicon carbide (SiC) growth substrate G may contain indium gallium nitride (InGaN) and indium aluminum nitride (InAlN). The first sacrificial layer N1 is grown directly on the initial growth substrate G to minimize crystal defects in the group III nitride semiconductor layer and serves as a buffer layer.

In addition, the group III nitride semiconductor layer (including the buffer layer and the channel layer) may be formed of a single layer or multiple layers of group III nitride semiconductors and made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), etc., which have high-temperature (HT) and high-resistance (HR) characteristics. The group III nitride semiconductor layer is a critical quality factor in reducing fatal crystal defects, that is, the density of threading dislocations (present in a vertical direction with respect to the initial growth substrate G) (≤Low 108/cm2).

Meanwhile, since a surface of the group III nitride semiconductor buffer layer 140 or the group III nitride semiconductor channel layer 150 formed on the growth substrate G and a surface of the group III nitride semiconductor buffer layer 140 or the group III nitride semiconductor channel layer 150 transferred onto the temporary substrate T are inverted, it is preferable to form a microstructure by treating a surface of the growth substrate G so that a predetermined preferred buffer layer or channel layer surface may be formed. For example, in the case of a gallium nitride (GaN) semiconductor channel layer, a gallium polarity (Ga-polarity) or nitrogen polarity (N-polarity) surface may be selectively adjusted according to the surface treatment and growth conditions of the growth substrate G. Typically, when a group III nitride semiconductor channel layer 150 is grown on the sapphire growth substrate G in a MOCVD chamber, while the group III nitride semiconductor channel layer 150 has a surface with a metal (M: Ga, Al, In) polarity with 3 valence electrons, an interface in direct contact with the sapphire growth substrate G has a nitrogen polarity with 5 valence electrons.

The third operation S103 is an operation of forming an epitaxy protection layer P on the group III nitride semiconductor channel layer 150 and then forming a first adhesive layer A1 on the epitaxy protection layer P. Here, the epitaxy protection layer P is a layer for preventing the group III nitride semiconductor channel layer 150 from being damaged during a subsequent process and may be made of a material in consideration of selective wet etching, and the epitaxy protection layer P may preferentially contain, for example, an oxide including silicon oxide (SiO2), a nitride including silicon nitride (SiNx), etc.

The fourth operation S104 is an operation of forming a second sacrificial layer N2 on the temporary substrate T and then forming a second adhesive layer A2 on the second sacrificial layer N2.

Here, the optically transparent temporary substrate T is a substrate that is finally easily separated by an LLO technique in the subsequent process, and before forming the second adhesive layer A2, the second sacrificial layer N2 (LLO sacrificial layer) may be deposited on the temporary substrate T. The above-described second sacrificial layer N2 material may include oxides, nitrides, etc., which may be deposited by a PVD technique such as a sputtering, pulsed laser deposition (PLD), or evaporator technique and specifically, may contain a material such as indium tin oxide (ITO), gallium oxide (GaOx), gallium oxide nitride (GaON), gallium nitride (GaN), indium gallium nitride (InGaN), tin oxide (ZnO), indium gallium tin oxide (InGaZnO), indium tin oxide (InZnO), or indium gallium oxide (InGaO). In addition, as needed, a bonding reinforcement layer 120 may be separately provided before the second sacrificial layer N2 is deposited so that the second sacrificial layer N2 material may be strongly bonded to an upper portion of the temporary substrate T. In this case, the bonding reinforcement layer 120 may contain a material that is optically transparent when irradiated with a laser beam, for example, preferentially, an oxide including silicon oxide (SiO2), a nitride including silicon nitride (SiNx), etc. In addition, a protective film layer of silicon oxide (SiO2) may be included as needed.

Here, the first adhesive layer A1 and the second adhesive layer A2 may include benzocyclobutene (BCB), polyimide (PI), a SU-8 polymer, an epoxy, organic, indium (In), tin (Sn) material-based solder, or a flowable oxide (FOx) such as SOG or HSQ for improving surface roughness.

The fifth operation S105 is an operation of forming an adhesive layer A by bonding the first adhesive layer A1 and the second adhesive layer A2. That is, the fifth operation S105 is an operation of turning over the temporary substrate T on which the second adhesive layer A2 has been formed and pressing and bonding the same to the growth substrate G on which the first adhesive layer A1 has been formed at a temperature of lower than 300° C.

The sixth operation S106 is an operation of separating the growth substrate G from the first sacrificial layer N1 using an LLO technique. Here, the LLO technique is a technique of separating an epitaxy-grown layer from the growth substrate G by irradiating a back surface of the transparent growth substrate G with an ultraviolet (UV) laser beam having a uniform optical output and beam profile, and a single wavelength. When the initial growth substrate G is separated, the inside of the group III nitride semiconductor channel layer 150 transferred onto the temporary substrate T is in a state in which the stress has been completely relieved and maintains a flat state together with the temporary substrate T. Then, it is preferable that a region damaged due to the separation of the growth substrate G, contaminated surface residue, and low-quality single crystalline thin film region be removed as completely as possible.

The seventh operation S107 is an operation of exposing the group III nitride semiconductor channel layer 150 by etching and removing the first sacrificial layer N1 and the group III nitride semiconductor buffer layer 140. A lower surface of the group III nitride semiconductor channel layer 150 from which the first sacrificial layer N1 and the group III nitride semiconductor buffer layer 140 have been removed is a nitrogen polarity surface and is in a state of thermal-chemical damage, which makes it difficult to obtain a high-quality group III nitride semiconductor thin film through the re-growth layer 160 to be described below. Therefore, for bonding with the final support substrate 110, it is very important to ensure that the lower surface of the group III nitride semiconductor channel layer 150 exposed to air has a surface in a particle-zero (0) state with residues completely removed.

Meanwhile, in some cases, it is preferable to introduce a regular or irregular patterning process to the group III nitride semiconductor channel layer 150 to improve the bonding strength with the final support substrate 110 in the subsequent process; in some cases, it is preferable to introduce a CMP process to increase a contact area with the final support substrate 110 in the subsequent process; and in some cases, it is preferable to deposit aluminum nitride (AlN), aluminum nitride oxide (AlNO), aluminum oxide (Al2O3), etc. at the lower surface side of the group III nitride semiconductor channel layer 150 to improve the quality of the product by inducing compressive stress.

The eighth operation S108 is an operation of forming a first bonding layer B1 on the group III nitride semiconductor channel layer 150. Although not shown, in some cases, the bonding reinforcement layer 121 or the compressive stress layer 122 described in the ninth operation S109 may be deposited and introduced to the surface of the group III nitride semiconductor channel layer 150 with a nitrogen polarity.

The ninth operation S109 is an operation of forming the reinforcement layer 120 on the support substrate 110 and then forming a second bonding layer B2 on the reinforcement layer 120. More specifically, the reinforcement layer 120 includes a bonding reinforcement layer 121 and a compressive stress layer 122.

The bonding reinforcement layer 121 is a layer introduced to reinforce bonding strength when the group III nitride semiconductor channel layer 150 is bonded on the final support substrate 110 through the bonding layer 130, and it is preferable that a material forming the bonding reinforcement layer 121 be preferentially selected from silicon oxide (SiO2), silicon nitride (SiNx), etc.

The compressive stress layer 122 is a layer that induces compressive stress and is made of a material that has a value larger than the coefficient of thermal expansion of the final support substrate 110, for example, a material that relieves tensile stress, that is, induces compressive stress, such as aluminum nitride (AlN, 4.6 ppm), aluminum nitride oxide (AlNO, 4.6 to 6.8 ppm), or aluminum oxide (Al2O3, 6.8 ppm), which serves to induce the quality improvement of products through stress control.

Meanwhile, in the present invention, the bonding reinforcement layer 121 or the compressive stress layer 122 may be omitted in some cases, and in some cases, the entire reinforcement layer 120 may be omitted so that the support substrate 110 may be in direct contact with the bonding layer 130. This case is a structure in which a material with a larger coefficient of thermal expansion than the Si (or SiC) support substrate is deposited on the bonding layer 130 to induce compressive stress together with a bonding function, or the bonding reinforcement layer 121 or the compressive stress layer 122 is provided by being deposited on the surface of the group III nitride semiconductor channel layer 150 with a nitrogen polarity (not shown).

In addition, the first bonding layer B1 and the second bonding layer B2 are each preferentially selected from materials whose properties do not change in the MOCVD chamber (at a temperature of 1000° C. or higher and in a reducing atmosphere) that grows group III nitride semiconductors, may contain, for example, silicon oxide (SiO2, 0.8 ppm), silicon nitride (SiNx, 3.8 ppm), silicon carbon nitride (SiCN, 3.8 to 4.8 ppm), aluminum nitride (AlN, 4.6 ppm), aluminum oxide (Al2O3, 6.8 ppm), and furthermore, may contain a flowable oxide (FOx) such as SOG (liquid SiO2) or HSQ to improve surface roughness.

The tenth operation S110 is an operation of forming the bonding layer 130 by bonding the first bonding layer B1 and the second bonding layer B2 to separate the temporary substrate T. That is, the tenth operation S110 is an operation of turning over the growth substrate G on which the first bonding layer B1 has been formed (deposited) and the temporary substrate T and pressing and bonding the same to the support substrate 110 on which the second bonding layer B2 has been formed at a temperature of lower than 300° C.

Conventionally, although epitaxy wafer bowing occurs due to thermo-mechanical induced stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

The eleventh operation S111 is an operation of separating the temporary substrate T from the second sacrificial layer N2 using the LLO technique.

The twelfth operation S112 is an operation of etching and removing the second sacrificial layer N2, the adhesive layer A, and the epitaxy protection layer P. Here, the second sacrificial layer N2, the adhesive layer A, and the epitaxy protection layer P may be formed through dry etching and wet etching. Then, the residue on the surface of the contaminated group III nitride semiconductor channel layer 150 may be removed, and as needed, it is preferable to perform an annealing process at a high temperature of 400° C. or higher to reinforce the bonding strength of the permanent bonding layer 130.

The thirteenth operation S113 is an operation of re-growing a high-quality group III nitride semiconductor re-growth layer 160 on the group III nitride semiconductor channel layer 150. In this case, the re-grown layer may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

In addition, as needed, before re-growing the re-grown re-growth layer 160 on the group III nitride semiconductor channel layer 150, the channel layer 150 may be surface-treated in the MOCVD chamber and/or additionally, a separate channel layer may be grown and inserted using a group III nitride semiconductor having a larger energy band gap than the channel layer 150.

Hereinafter, a group III nitride semiconductor template according to a second embodiment of the present invention will be described in detail with reference to the accompanying drawings.

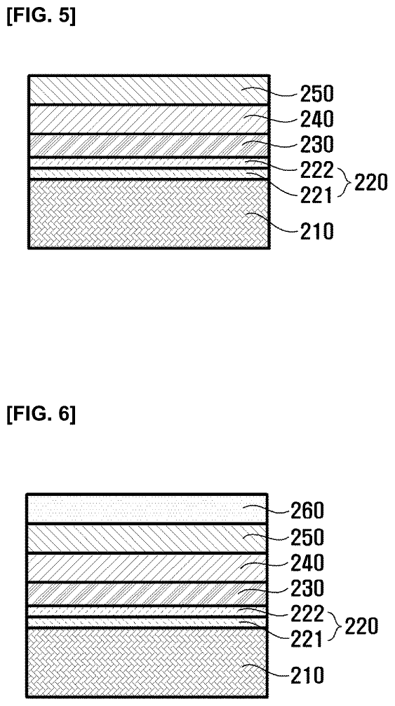

FIG. 5 shows a group III nitride semiconductor template according to a second embodiment of the present invention, and FIG. 6 shows that a re-growth layer is re-grown on the group III nitride semiconductor template according to the second embodiment of the present invention.

As shown in FIGS. 5 and 6, the group III nitride semiconductor template according to the second embodiment of the present invention includes a support substrate 210, a reinforcement layer 220, a bonding layer 230, a group III nitride semiconductor buffer layer 240, and a group III nitride semiconductor channel layer 250. In this case, the formation and thickness of each layer may vary depending on the type of a power semiconductor device and a growth substrate G that are applied.

The support substrate 210 is a substrate that supports the group III nitride semiconductor buffer layer 240, the group III nitride semiconductor channel layer 250, and a re-growth layer 260 re-grown on the group III nitride semiconductor channel layer 250, and the support substrate 210 may be made of a material that has high heat dissipation performance (60 W/mK or more) and has a coefficient of thermal expansion (CTE, ppm) that is equal to or less than that of the group III nitride semiconductor buffer layer 240 or the group III nitride semiconductor channel layer 250 (GaN CTE about 5.6 ppm) and may be formed in a polycrystalline or single crystalline microstructure.

More specifically, the support substrate 210 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 210. In addition, the silicon (Si) or silicon carbide (SiC) support substrate 210 is preferably formed in a polycrystalline microstructure through a high-temperature sintering process rather than a single crystalline microstructure wafer, and thus there is an advantage in that it is possible to secure cost competitiveness.

The bonding layer 230 is used to bond the support substrate 210 and the group III nitride semiconductor channel layer 250, may be disposed on the reinforcement layer 220 to be described below, and made of a permanent bonding material.

More specifically, the bonding layer 230 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or HSQ to improve surface roughness. In particular, it is preferable to use a chemical vapor deposition (CVD) process such as an MOCVD or ALD process for aluminum nitride (AlN), aluminum gallium nitride (AlGaN), gallium nitride (GaN), indium gallium nitride (InGaN), and indium nitride (InN) materials.

The reinforcement layer 220 is formed so that the group III nitride semiconductor buffer layer 240 may be more strongly bonded to the support substrate 210, induces compressive stress, and is disposed in contact with an upper surface or lower surface of the bonding layer 230. That is, as shown in FIG. 25, the reinforcement layer 220 may be disposed between the support substrate 210 and the bonding layer 230 and/or between the group III nitride semiconductor layer and the bonding layer 230.

More specifically, the reinforcement layer 220 includes a bonding reinforcement layer 221 and a compressive stress layer 222.

The bonding reinforcement layer 221 is a layer introduced to reinforce bonding strength when the group III nitride semiconductor buffer layer 240 is bonded on the final support substrate 210 through the bonding layer 230, and it is preferable that a material forming the bonding reinforcement layer 221 be preferentially selected from silicon oxide (SiO2), silicon nitride (SiNx), etc.

The compressive stress layer 222 is a layer that induces compressive stress and is made of a material that has a value larger than the coefficient of thermal expansion of the final support substrate 210, for example, a material that relieves tensile stress, that is, induces compressive stress, such as aluminum nitride (AlN, 4.6 ppm), aluminum nitride oxide (AlNO, 4.6 to 6.8 ppm; depending on a content ratio of AlN and Al2O3), or aluminum oxide (Al2O3, 6.8 ppm), which serves to induce the quality improvement of products through stress control.

Meanwhile, in the present invention, the bonding reinforcement layer 221 or the compressive stress layer 222 may be omitted in some cases, and in some cases, the entire reinforcement layer 220 may be omitted so that the support substrate 210 may be in direct contact with the bonding layer 230. This case is a structure in which a material with a larger coefficient of thermal expansion than the Si (or SiC) support substrate is deposited on the bonding layer 230 to induce compressive stress together with a bonding function, or the bonding reinforcement layer 221 or the compressive stress layer 222 is provided by being deposited on the surface of the group III nitride semiconductor channel layer 250 (not shown).

The group III nitride semiconductor buffer layer 240 may be disposed on the bonding layer 230 and formed of a single layer or multiple layers of group III nitride semiconductors, and the group III nitride semiconductor buffer layer 240 according to the present embodiment may be made of a gallium nitride (GaN) material with high resistance characteristics for a leakage current and doped with iron (Fe), carbon (C), etc. to increase resistance as needed.

The group III nitride semiconductor channel layer 250 may be disposed on the group III nitride semiconductor buffer layer 240, formed of a single layer or multiple layers of group III nitride semiconductors, and may be made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), etc., which have high-temperature (HT) and high-resistance (HR) characteristics The group III nitride semiconductor channel layer 250 is a critical quality factor in reducing fatal crystal defects, that is, the density of threading dislocations (present in a vertical direction with respect to an initial growth substrate G) (≤Low 108/cm2).

Then, a high-quality group III nitride semiconductor re-growth layer 260 may be re-grown on the group III nitride semiconductor channel layer 250. In this case, the re-grown re-growth layer 260 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

In addition, as needed, before directly re-growing the aluminum gallium nitride (AlGaN) barrier layer 260 on the group III nitride semiconductor channel layer 250, the channel layer 250 may be surface-treated in a MOCVD chamber and/or additionally, a separate channel layer may be grown and inserted using a group III nitride semiconductor having a larger energy band gap than the channel layer 250 (not shown).

Hereinafter, a method S200 of manufacturing the group III nitride semiconductor template according to the second embodiment of the present invention will be described in detail with reference to the accompanying drawings.

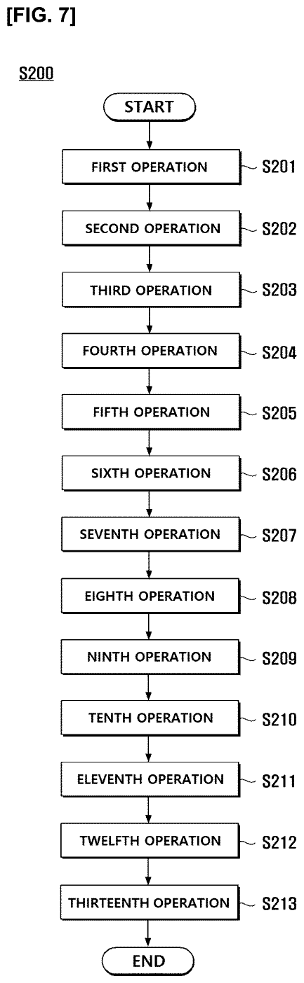

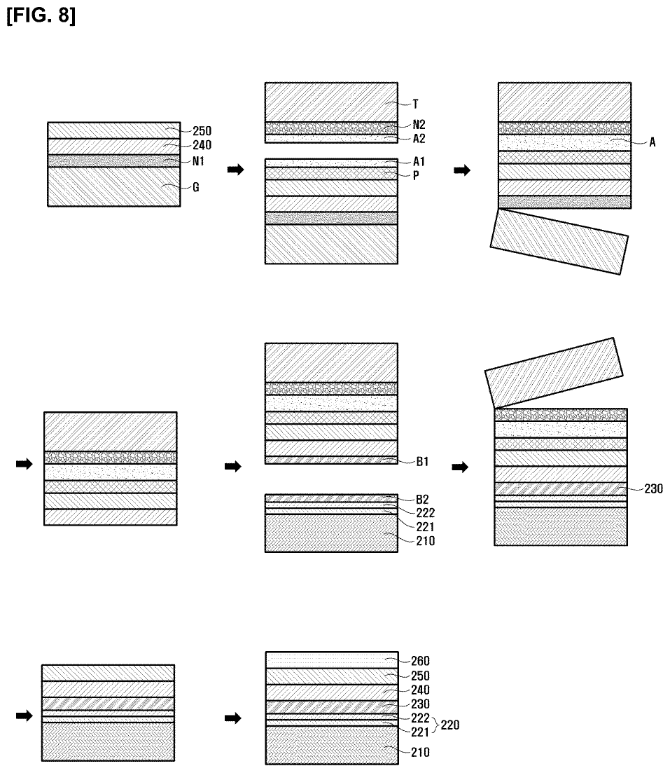

FIG. 7 is a flowchart of a method of manufacturing a group III nitride semiconductor template according to the second embodiment of the present invention, and FIG. 8 shows a process of manufacturing the group III nitride semiconductor template according to the second embodiment of the present

As shown in FIGS. 7 and 8, the method S200 of manufacturing the group III nitride semiconductor template according to the second embodiment of the present invention includes a first operation S201, a second operation S202, a third operation S203, a fourth operation S204, a fifth operation S205, a sixth operation S206, a seventh operation S207, an eighth operation S208, a ninth operation S209, a tenth operation S210, an eleventh operation S211, a twelfth operation S212, and a thirteenth operation S213.

The first operation S201 is an operation of preparing the growth substrate G, the temporary substrate T, and a support substrate 210.

The support substrate 210 is a substrate that supports a group III nitride semiconductor buffer layer 240, a group III nitride semiconductor channel layer 250, and a re-growth layer 260 re-grown on the group III nitride semiconductor channel layer 250, and the support substrate 210 may be made of a material that has high heat dissipation performance (60 W/mK or more) and has a coefficient of thermal expansion (CTE, ppm) that is equal to or less than that of the group III nitride semiconductor buffer layer 240 or the group III nitride semiconductor channel layer 250 (GaN CTE about 5.6 ppm) and formed in a polycrystalline or single crystalline microstructure.

Since the following first operation S201 to sixth operation S206 are the same as those of the method S100 of manufacturing the group III nitride semiconductor template according to the first embodiment of the present invention, overlapping descriptions thereof will be omitted.

The seventh operation S207 is an operation of exposing the group III nitride semiconductor buffer layer 240 by etching and removing the first sacrificial layer N1. A lower surface of the group III nitride semiconductor buffer layer 240 from which the first sacrificial layer N1 and the group III nitride semiconductor buffer layer 240 have been removed is a nitrogen polarity surface and is in a state of thermal-chemical damage, which makes it difficult to obtain a high-quality group III nitride semiconductor thin film through the re-growth layer 260 to be described below. Therefore, it is very important to ensure that the lower surface of the group III nitride semiconductor buffer layer 240 exposed to air has a surface in a particle-zero (0) state with residues completely removed. In addition, the group III nitride semiconductor buffer layer 240 may be made of a gallium nitride (GaN) material with high resistance characteristics for a leakage current, and may be doped with iron (Fe), carbon (C), etc. to increase resistance as needed.

Meanwhile, in some cases, it is preferable to introduce a regular or irregular patterning process to the group III nitride semiconductor channel layer 150 to improve the bonding strength with the final support substrate 210 in the subsequent process; in some cases, it is preferable to introduce a CMP process to increase a contact area with the final support substrate 210 in the subsequent process; and in some cases, it is preferable to deposit aluminum nitride (AlN), aluminum nitride oxide (AlNO), aluminum oxide (Al2O3), etc. at the lower surface side of the group III nitride semiconductor channel layer 150 to improve the quality of the product by inducing compressive stress.

The eighth operation S208 is an operation of forming a first bonding layer B1 on the group III nitride semiconductor buffer layer 240. Although not shown, in some cases, the bonding reinforcement layer 221 or the compressive stress layer 222 described in the ninth operation S209 may be deposited and introduced to the surface of the group III nitride semiconductor buffer layer 240 with a nitrogen polarity.

The ninth operation S209 is an operation of forming the reinforcement layer 220 on the support substrate 210 and then forming a second bonding layer B2 on the reinforcement layer 220. Here, the reinforcement layer 220 includes a bonding reinforcement layer 221 and a compressive stress layer 222, and since the following descriptions are the same as those of the method S100 of manufacturing the group III nitride semiconductor template according to the first embodiment of the present invention, overlapping descriptions will be omitted.

The tenth operation S210 is an operation of forming the bonding layer 230 by bonding the first bonding layer B1 and the second bonding layer B2 to separate the temporary substrate T. That is, the tenth operation S210 is an operation of turning over the group III nitride semiconductor buffer layer 240 on which the first bonding layer B1 has been formed (deposited) and the temporary substrate T and pressing and bonding the same to the support substrate 210 on which the second bonding layer B2 has been formed at a temperature of lower than 300° C.

Conventionally, although epitaxy wafer bowing occurs due to thermo-mechanical induced stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

Since the eleventh operation S211 to the thirteenth operation S213 are the same as those of the method S100 of manufacturing the group III nitride semiconductor template according to the first embodiment of the present invention, overlapping descriptions thereof will be omitted.

Hereinafter, a group III nitride semiconductor template according to a third embodiment of the present invention will be described in detail with reference to the accompanying drawings.

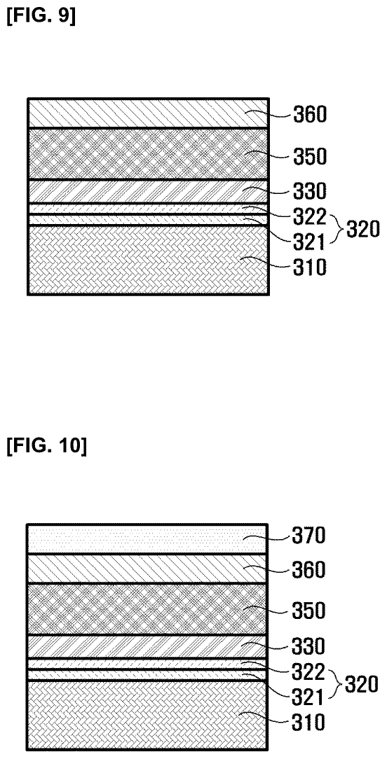

FIG. 9 shows a group III nitride semiconductor template according to a third embodiment of the present invention, and FIG. 10 shows that a re-growth layer is re-grown on the group III nitride semiconductor template according to the third embodiment of the present invention.

As shown in FIGS. 9 and 10, the group III nitride semiconductor template according to the third embodiment of the present invention includes a support substrate 310, a reinforcement layer 320, a bonding layer 330, a second group III nitride semiconductor buffer layer 350, and a group III nitride semiconductor channel layer 360. In this case, the formation and thickness of each layer may vary depending on the type of a power semiconductor device and a growth substrate G that are applied.

The support substrate 310 is a substrate that supports the second group III nitride semiconductor buffer layer 350, the group III nitride semiconductor channel layer 360, and a re-growth layer 370 re-grown on the group III nitride semiconductor channel layer 360, and the support substrate 310 may be made of a material that has high heat dissipation performance (60 W/mK or more) and has a coefficient of thermal expansion (CTE, ppm) that is equal to or less than that of the second group III nitride semiconductor buffer layer 350 or the group III nitride semiconductor channel layer 360 (GaN CTE about 5.6 ppm) and may be formed in a polycrystalline or single crystalline microstructure.

More specifically, the support substrate 310 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 310. In addition, the silicon (Si) or silicon carbide (SiC) support substrate 310 is preferably formed in a polycrystalline microstructure through a high-temperature sintering process rather than a single crystalline microstructure wafer, and thus there is an advantage in that it is possible to secure cost competitiveness.

The bonding layer 330 is used to bond the support substrate 310 and the second group III nitride semiconductor buffer layer 350, may be disposed on the reinforcement layer 320 to be described below, and made of a permanent bonding material.

More specifically, the bonding layer 330 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or HSQ to improve surface roughness. In particular, it is preferable to use a chemical vapor deposition (CVD) process such as an MOCVD or ALD process for aluminum nitride (AlN), aluminum gallium nitride (AlGaN), gallium nitride (GaN), indium gallium nitride (InGaN), and indium nitride (InN) materials.

The reinforcement layer 320 is formed so that the second group III nitride semiconductor buffer layer 350 may be more strongly bonded to the support substrate 310, induces compressive stress, and is disposed in contact with an upper surface or lower surface of the bonding layer 330. That is, as shown in FIG. 25, the reinforcement layer 320 may be disposed between the support substrate 310 and the bonding layer 330 and/or between the group III nitride semiconductor layer and the bonding layer 330.

More specifically, the reinforcement layer 320 includes a bonding reinforcement layer 321 and a compressive stress layer 322.

The bonding reinforcement layer 321 is a layer introduced to reinforce bonding strength when the second group III nitride semiconductor buffer layer 350 is bonded on the final support substrate 310 through the bonding layer 330, and it is preferable that a material forming the bonding reinforcement layer 321 be preferentially selected from silicon oxide (SiO2), silicon nitride (SiNx), etc.

The compressive stress layer 322 is a layer that induces compressive stress and is made of a material that has a larger value than the coefficient of thermal expansion of the final support substrate 310, for example, a material that relieves tensile stress, that is, induces compressive stress, such as aluminum nitride (AlN, 4.6 ppm), aluminum nitride oxide (AlNO, 4.6 to 6.8 ppm; depending on a content ratio of AlN and Al2O3), or aluminum oxide (Al2O3, 6.8 ppm), which serves to induce the improvement in quality of products through stress control.

Meanwhile, in the present invention, the bonding reinforcement layer 321 or the compressive stress layer 322 may be omitted in some cases, and in some cases, the entire reinforcement layer 320 may be omitted so that the support substrate 310 may be in direct contact with the bonding layer 330. This case is a structure in which a material with a larger coefficient of thermal expansion than the Si (or SiC) support substrate is deposited on the bonding layer 330 to induce compressive stress together with a bonding function, or the bonding reinforcement layer 321 or the compressive stress layer 322 is provided by being deposited on the surface of the second group III nitride semiconductor buffer layer 350 with a nitrogen polarity (not shown).

The second group III nitride semiconductor buffer layer 350 may be disposed on the bonding layer 330 and formed of a single layer or multiple layers of group III nitride semiconductors, and the second group III nitride semiconductor buffer layer 350 according to the present embodiment may be made of one or more of aluminum nitride (AlN), aluminum nitride oxide (AlNO), and aluminum oxide (Al2O3), which have high resistance characteristics for a leakage current even without separate doping such as iron (Fe) or carbon (C).

The group III nitride semiconductor channel layer 360 may be disposed on the second group III nitride semiconductor buffer layer 350, formed of a single layer or multiple layers of group III nitride semiconductors, and made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), etc., which have high-temperature (HT) and high-resistance (HR) characteristics. The group III nitride semiconductor channel layer 360 is a critical quality factor in reducing fatal crystal defects, that is, the density of threading dislocations (present in a vertical direction with respect to an initial growth substrate G) (≤Low 108/cm2).

Then, a high-quality group III nitride semiconductor re-growth layer 370 may be re-grown on the group III nitride semiconductor channel layer 360. In this case, the re-grown re-growth layer 370 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

In addition, as needed, before directly re-growing the aluminum gallium nitride (AlGaN) barrier layer 370 on the group III nitride semiconductor channel layer 360, the channel layer 360 may be surface-treated in a MOCVD chamber and/or additionally, a separate channel layer may be grown and inserted using a group III nitride semiconductor having a larger energy band gap than the channel layer 360 (not shown).

Hereinafter, a method S300 of manufacturing the group III nitride semiconductor template according to the third embodiment of the present invention will be described in detail with reference to the accompanying drawings.

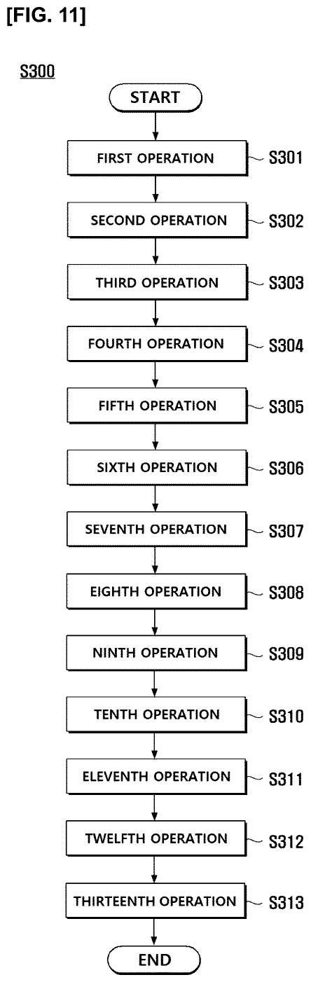

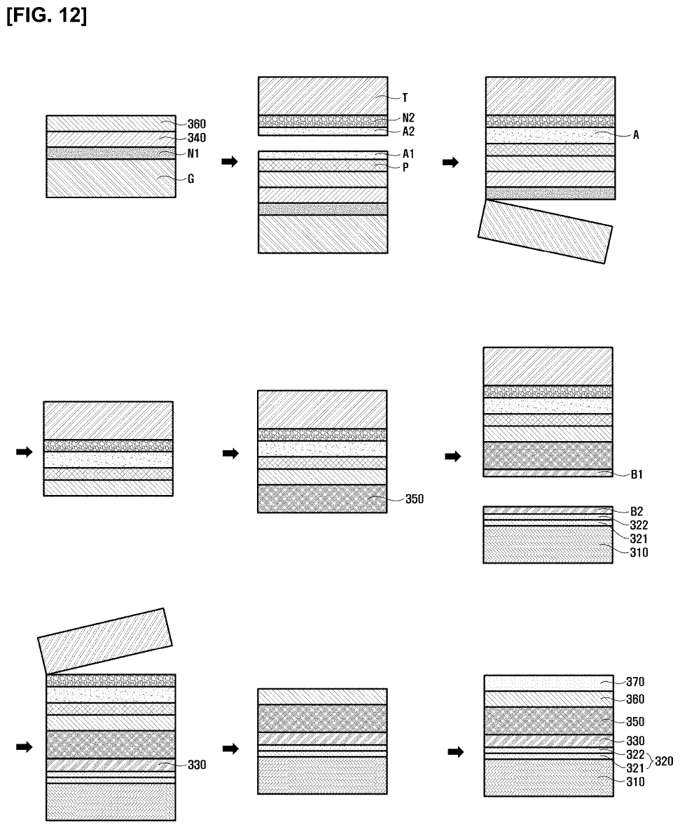

FIG. 11 is a flowchart of a method of manufacturing a group III nitride semiconductor template according to the third embodiment of the present invention, and FIG. 12 shows a process of manufacturing the group III nitride semiconductor template according to the third embodiment of the present invention.

As shown in FIGS. 11 and 12, the method S300 of manufacturing the group III nitride semiconductor template according to the third embodiment of the present invention includes a first operation S301, a second operation S302, a third operation S303, a fourth operation S304, a fifth operation S305, a sixth operation S306, a seventh operation S307, an eighth operation S308, a ninth operation S309, a tenth operation S310, an eleventh operation S311, a twelfth operation S312, and a thirteenth operation S313.

The first operation S301 is an operation of preparing the growth substrate G, the temporary substrate T, and a support substrate 310.

The support substrate 310 is a substrate that supports a second group III nitride semiconductor buffer layer 350, a group III nitride semiconductor channel layer 360, and a re-growth layer 370 re-grown on the group III nitride semiconductor channel layer 360, and the support substrate 310 may be made of a material that has high heat dissipation performance (60 W/mK or more) and has a coefficient of thermal expansion (CTE, ppm) that is equal to or less than that of the second group III nitride semiconductor buffer layer 350 or the group III nitride semiconductor channel layer 360 (GaN CTE about 5.6 ppm) and may be formed in a polycrystalline or single crystalline microstructure.

Since the first operation S301 to the sixth operation S306 are the same as those of the method S100 of manufacturing the group III nitride semiconductor template according to the first embodiment of the present invention, overlapping descriptions thereof will be omitted.

The seventh operation S307 is an operation of exposing the group III nitride semiconductor channel layer 360 by etching and removing the first sacrificial layer N1 and a first group III nitride semiconductor buffer layer 340. A lower surface of the group III nitride semiconductor channel layer 360 from which the first sacrificial layer N1 and the first group III nitride semiconductor buffer layer 340 have been removed is a nitrogen polarity surface and is in a state of thermal-chemical damage, which makes it difficult to obtain a high-quality group III nitride semiconductor thin film through the re-growth layer 370 to be described below. Therefore, it is very important to ensure that the lower surface of the group III nitride semiconductor channel layer 360 exposed to air has a surface in a particle-zero (0) state with residues completely removed.

The eighth operation S308 is an operation of depositing a new second group III nitride semiconductor buffer layer 350 on a surface of the group III nitride semiconductor channel layer 360 with a nitrogen polarity and forming a first bonding layer B1 on the second group III nitride semiconductor buffer layer 350. Here, the newly formed second group III nitride semiconductor buffer layer 350 may be made of a material such as aluminum nitride (AlN), aluminum nitride oxide (AlNO), or aluminum oxide (Al2O3), which has high resistance characteristics for a leakage current without separate doping such as iron (Fe) or carbon (C). Although not shown, in some cases, the bonding reinforcement layer 321 or the compressive stress layer 322 described in the ninth operation S309 may be deposited and introduced to the surface of the second group III nitride semiconductor buffer layer 350.

The ninth operation S309 is an operation of forming the reinforcement layer 320 on the support substrate 310 and then forming a second bonding layer B2 on the reinforcement layer 320. Here, the reinforcement layer 320 includes a bonding reinforcement layer 321 and a compressive stress layer 322, and since the following descriptions are the same as those of the method S100 of manufacturing the group III nitride semiconductor template according to the first embodiment of the present invention, overlapping descriptions will be omitted.

The tenth operation S310 is an operation of forming the bonding layer 330 by bonding the first bonding layer B1 and the second bonding layer B2 to separate the temporary substrate T. That is, the tenth operation S310 is an operation of turning over the second group III nitride semiconductor buffer layer 350 on which the first bonding layer B1 has been formed (deposited) and the temporary substrate T and pressing and bonding the same to the support substrate 310 on which the second bonding layer B2 has been formed at a temperature of lower than 300° C.

Conventionally, although epitaxy wafer bowing occurs due to thermo-mechanical induced stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

Since the eleventh operation S311 to the thirteenth operation S313 are the same as those of the method S100 of manufacturing the group III nitride semiconductor template according to the first embodiment of the present invention, overlapping descriptions thereof will be omitted.

Hereinafter, a group III nitride semiconductor template according to a fourth embodiment of the present invention will be described in detail with reference to the accompanying drawings.

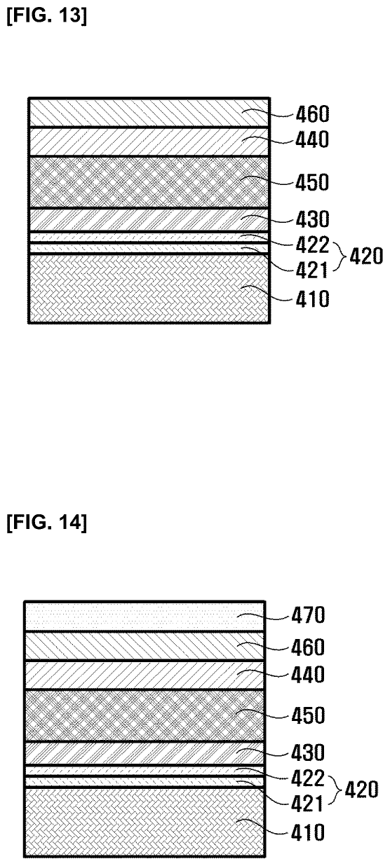

FIG. 13 shows a group III nitride semiconductor template according to a fourth embodiment of the present invention, and FIG. 14 shows that a re-growth layer is re-grown on the group III nitride semiconductor template according to the fourth embodiment of the present invention.

As shown in FIGS. 13 and 14, the group III nitride semiconductor template according to the fourth embodiment of the present invention includes a support substrate 410, a reinforcement layer 420, a bonding layer 430, a first group III nitride semiconductor buffer layer 440, a second group III nitride semiconductor buffer layer 450, and a group III nitride semiconductor channel layer 460. In this case, the formation and thickness of each layer may vary depending on the type of a power semiconductor device and a growth substrate G that are applied.

The support substrate 410 is a substrate that supports the first group III nitride semiconductor buffer layer 440, the second group III nitride semiconductor buffer layer 450, the group III nitride semiconductor channel layer 460, and a re-growth layer 470 re-grown on the group III nitride semiconductor channel layer 460, and the support substrate 410 may be made of a material that has high heat dissipation performance (60 W/mK or more) and has a coefficient of thermal expansion (CTE, ppm) that is equal to or less than that of the second group III nitride semiconductor buffer layer 450 or the group III nitride semiconductor channel layer 460 (GaN CTE about 5.6 ppm) and may be formed in a polycrystalline or single crystalline microstructure.

More specifically, the support substrate 410 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 410. In addition, the silicon (Si) or silicon carbide (SiC) support substrate 410 is preferably formed in a polycrystalline microstructure through a high-temperature sintering process rather than a single crystalline microstructure wafer, and thus there is an advantage in that it is possible to secure cost competitiveness.

The bonding layer 430 is used to bond the support substrate 410 and the second group III nitride semiconductor buffer layer 450, may be disposed on the reinforcement layer 420 to be described below, and made of a permanent bonding material.

More specifically, the bonding layer 430 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or HSQ to improve surface roughness. In particular, it is preferable to use a chemical vapor deposition (CVD) process such as an MOCVD or ALD process for aluminum nitride (AlN), aluminum gallium nitride (AlGaN), gallium nitride (GaN), indium gallium nitride (InGaN), and indium nitride (InN) materials.

The reinforcement layer 420 is formed so that the second group III nitride semiconductor channel layer 450 may be more strongly bonded to the support substrate 410, induces compressive stress, and is disposed in contact with an upper surface or lower surface of the bonding layer 430. That is, as shown in FIG. 25, the reinforcement layer 420 may be disposed between the support substrate 410 and the bonding layer 430 and/or between the group III nitride semiconductor layer and the bonding layer 430.

More specifically, the reinforcement layer 420 includes a bonding reinforcement layer 421 and a compressive stress layer 422.

The bonding reinforcement layer 421 is a layer introduced to reinforce bonding strength when the second group III nitride semiconductor buffer layer 450 is bonded on the final support substrate 410 through the bonding layer 430, and it is preferable that a material forming the bonding reinforcement layer 421 be preferentially selected from silicon oxide (SiO2), silicon nitride (SiNx), etc.

The compressive stress layer 422 is a layer that induces compressive stress and is made of a material that has a value larger than the coefficient of thermal expansion of the final support substrate 410, for example, a material that relieves tensile stress, that is, induces compressive stress, such as aluminum nitride (AlN, 4.6 ppm), aluminum nitride oxide (AlNO, 4.6 to 6.8 ppm; depending on a content ratio of AlN and Al2O3), or aluminum oxide (Al2O3, 6.8 ppm), which serves to induce the quality improvement of products through stress control.

Meanwhile, in the present invention, the bonding reinforcement layer 421 or the compressive stress layer 422 may be omitted in some cases, and in some cases, the entire reinforcement layer 420 may be omitted so that the support substrate 410 may be in direct contact with the bonding layer 430. This case is a structure in which a material with a larger coefficient of thermal expansion than the Si (or SiC) support substrate is deposited on the bonding layer 430 to induce compressive stress together with a bonding function, or the bonding reinforcement layer 421 or the compressive stress layer 422 is provided by being deposited on the surface of the second group III nitride semiconductor channel layer 450 with a nitrogen polarity (not shown).

The first group III nitride semiconductor buffer layer 440 may be disposed on the second group III nitride semiconductor buffer layer 450 to be described below, and the first group III nitride semiconductor buffer layer 440 according to the present embodiment may be made of a gallium nitride (GaN) material with high resistance characteristics for a leakage current and doped with iron (Fe), carbon (C), etc. to increase resistance as needed.

The second group III nitride semiconductor buffer layer 450 may be disposed on the bonding layer 430 and formed of a single layer or multiple layers of group III nitride semiconductors, and the second group III nitride semiconductor buffer layer 450 according to the present embodiment may be made of one or more of aluminum nitride (AlN), aluminum nitride oxide (AlNO), and aluminum oxide (Al2O3), which have high resistance characteristics for a leakage current even without separate doping such as iron (Fe) or carbon (C).

The group III nitride semiconductor channel layer 460 may be disposed on the first group III nitride semiconductor buffer layer 440, formed of a single layer or multiple layers of group III nitride semiconductors, and made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), etc., which have high-temperature (HT) and high-resistance (HR) characteristics. The group III nitride semiconductor channel layer 460 is a critical quality factor in reducing fatal crystal defects, that is, the density of threading dislocations (present in a vertical direction with respect to an initial growth substrate G) (≤Low 108/cm2).

Then, a high-quality group III nitride semiconductor re-growth layer 470 may be re-grown on the group III nitride semiconductor channel layer 460. In this case, the re-grown re-growth layer 470 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

In addition, as needed, before directly re-growing the aluminum gallium nitride (AlGaN) barrier layer 470 on the group III nitride semiconductor channel layer 460, the channel layer 460 may be surface-treated in a MOCVD chamber and/or additionally, a separate channel layer may be grown and inserted using a group III nitride semiconductor having a larger energy band gap than the channel layer 460 (not shown).

Hereinafter, a method S400 of manufacturing the group III nitride semiconductor template according to the fourth embodiment of the present invention will be described in detail with reference to the accompanying drawings.

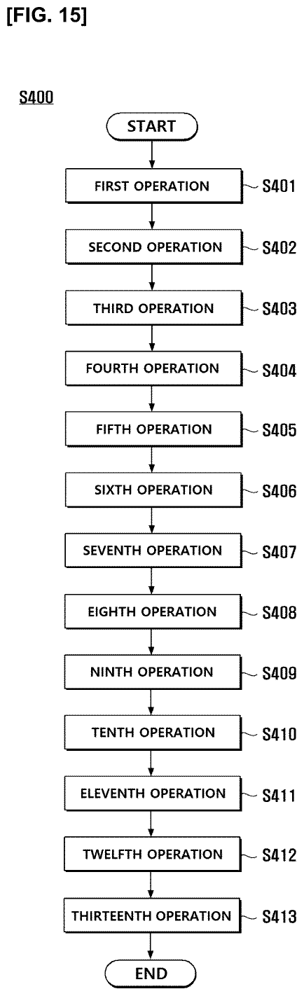

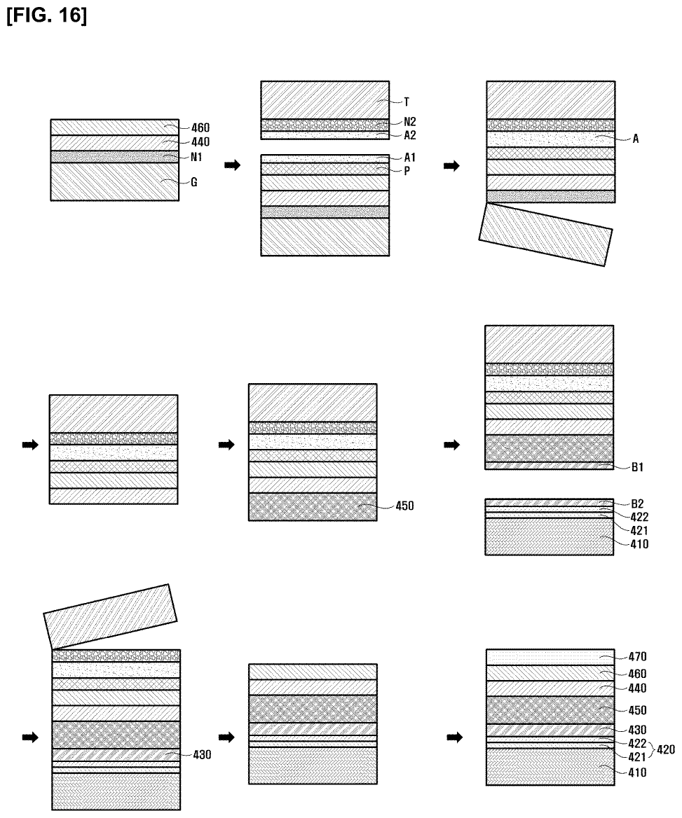

FIG. 15 is a flowchart of a method of manufacturing a group III nitride semiconductor template according to the fourth embodiment of the present invention, and FIG. 16 shows a process of manufacturing the group III nitride semiconductor template according to the fourth embodiment of the present invention.

As shown in FIGS. 15 and 16, the method S400 of manufacturing the group III nitride semiconductor template according to the fourth embodiment of the present invention includes a first operation S401, a second operation S402, a third operation S403, a fourth operation S404, a fifth operation S405, a sixth operation S406, a seventh operation S407, an eighth operation S408, a ninth operation S409, a tenth operation S410, an eleventh operation S411, a twelfth operation S412, and a thirteenth operation S413.

The first operation S401 is an operation of preparing the growth substrate G, the temporary substrate T, and a support substrate 410.

The support substrate 410 is a substrate that supports a first group III nitride semiconductor buffer layer 440, a second group III nitride semiconductor buffer layer 450, a group III nitride semiconductor channel layer 460, and a re-growth layer 470 re-grown on the group III nitride semiconductor channel layer 460, and the support substrate 410 may be made of a material that has high heat dissipation performance (60 W/mK or more) and has a coefficient of thermal expansion (CTE, ppm) that is equal to or less than that of the second group III nitride semiconductor buffer layer 450 or the group III nitride semiconductor channel layer 460 (GaN CTE about 5.6 ppm) and may be formed in a polycrystalline or single crystalline microstructure.

Since the first operation S401 to the sixth operation S406 are the same as those of the method S100 of manufacturing the group III nitride semiconductor template according to the first embodiment of the present invention, overlapping descriptions thereof will be omitted.

The seventh operation S407 is an operation of exposing the first group III nitride semiconductor buffer layer 440 by etching and removing the first sacrificial layer N1. A lower surface of the first group III nitride semiconductor buffer layer 440 from which the first sacrificial layer N1 has been removed is a nitrogen polarity surface and is in a state of thermal-chemical damage, which makes it difficult to obtain a high-quality group III nitride semiconductor thin film through the re-growth layer 470 to be described below. Therefore, it is very important to ensure that the lower surface of the first group III nitride semiconductor buffer layer 440 exposed to air has a surface in a particle-zero (0) state with residues completely removed. In addition, the first group III nitride semiconductor buffer layer 440 may be made of a gallium nitride (GaN) material with high resistance characteristics for a leakage current, and may be doped with iron (Fe), carbon (C), etc. to increase resistance as needed.

The eighth operation S408 is an operation of depositing a new second group III nitride semiconductor buffer layer 450 on a surface of the first group III nitride semiconductor channel layer 440 with a nitrogen polarity and forming a first bonding layer B1 on the second group III nitride semiconductor buffer layer 450. Here, the newly formed second group III nitride semiconductor buffer layer 450 may be made of a material such as aluminum nitride (AlN), aluminum nitride oxide (AlNO), or aluminum oxide (Al2O3), which has high resistance characteristics for a leakage current without separate doping such as iron (Fe) or carbon (C). Although not shown, in some cases, the bonding reinforcement layer 421 or the compressive stress layer 422 described in the ninth operation S409 may be deposited and introduced to the surface of the second group III nitride semiconductor buffer layer 450.

The ninth operation S409 is an operation of forming the reinforcement layer 420 on the support substrate 410 and then forming a second bonding layer B2 on the reinforcement layer 420. Here, the reinforcement layer 420 includes a bonding reinforcement layer 421 and a compressive stress layer 422, and since the following descriptions are the same as those of the method S100 of manufacturing a group III nitride semiconductor template according to the first embodiment of the present invention, overlapping descriptions will be omitted.

The tenth operation S410 is an operation of forming the bonding layer 430 by bonding the first bonding layer B1 and the second bonding layer B2 to separate the temporary substrate T. That is, the tenth operation S410 is an operation of turning over the second group III nitride semiconductor buffer layer 450 on which the first bonding layer B1 has been formed (deposited) and the temporary substrate T and pressing and bonding the same to the support substrate 410 on which the second bonding layer B2 has been formed at a temperature of lower than 300° C.

Conventionally, although epitaxy wafer bowing occurs due to thermo-mechanical induced stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

Since the eleventh operation S411 to the thirteenth operation S413 are the same as those of the method S100 of manufacturing the group III nitride semiconductor template according to the first embodiment of the present invention, overlapping descriptions thereof will be omitted.

Hereinafter, a group III nitride semiconductor template according to a fifth embodiment of the present invention will be described in detail with reference to the accompanying drawings.

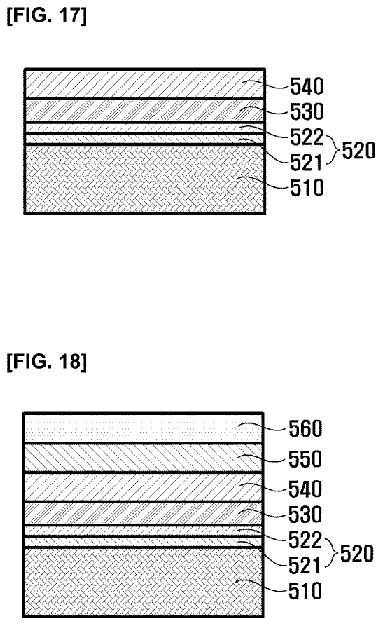

FIG. 17 shows a group III nitride semiconductor template according to a fifth embodiment of the present invention, and FIG. 18 shows that a re-growth layer is re-grown on the group III nitride semiconductor template according to the fifth embodiment of the present invention.

As shown in FIGS. 17 and 18, the group III nitride semiconductor template according to the fifth embodiment of the present invention includes a support substrate 510, a reinforcement layer 520, a bonding layer 530, and a group III nitride semiconductor buffer layer 540. In this case, the formation and thickness of each layer may vary depending on the type of a power semiconductor device and a growth substrate G that are applied.

The support substrate 510 is a substrate that supports the group III nitride semiconductor buffer layer 540, and a group III nitride semiconductor channel layer 550 and a re-growth layer 560 that are re-grown on the group III nitride semiconductor channel layer 540, and the support substrate 510 may be made of a material that has high heat dissipation performance (60 W/mK or more) and has a coefficient of thermal expansion (CTE, ppm) that is equal to or less than that of the group III nitride semiconductor buffer layer 540 or the group III nitride semiconductor channel layer 550 (GaN CTE about 5.6 ppm) and formed in a polycrystalline or single crystalline microstructure.

More specifically, the support substrate 510 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 510. In addition, the silicon (Si) or silicon carbide (SiC) support substrate 510 is preferably formed in a polycrystalline microstructure through a high-temperature sintering process rather than a single crystalline microstructure wafer, and thus there is an advantage in that it is possible to secure cost competitiveness.

The bonding layer 530 is used to bond the support substrate 510 and the group III nitride semiconductor channel layer 540, may be disposed on the reinforcement layer 520 to be described below, and made of a permanent bonding material.

More specifically, the bonding layer 530 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or HSQ to improve surface roughness. In particular, it is preferable to use a chemical vapor deposition (CVD) process such as an MOCVD or ALD process for aluminum nitride (AlN), aluminum gallium nitride (AlGaN), gallium nitride (GaN), indium gallium nitride (InGaN), and indium nitride (InN) materials.

The reinforcement layer 520 is formed so that the group III nitride semiconductor buffer layer 540 may be more strongly bonded to the support substrate 510, induces compressive stress, and is disposed in contact with an upper surface or lower surface of the bonding layer 530. That is, as shown in FIG. 25, the reinforcement layer 520 may be disposed between the support substrate 510 and the bonding layer 530 and/or between the group III nitride semiconductor layer and the bonding layer 530.

More specifically, the reinforcement layer 520 includes a bonding reinforcement layer 521 and a compressive stress layer 522.

The bonding reinforcement layer 521 is a layer introduced to reinforce bonding strength when the group III nitride semiconductor buffer layer 540 is bonded on the final support substrate 510 through the bonding layer 530, and it is preferable that a material forming the bonding reinforcement layer 521 be preferentially selected from silicon oxide (SiO2), silicon nitride (SiNx), etc.

The compressive stress layer 522 is a layer that induces compressive stress and is made of a material that has a value larger than the coefficient of thermal expansion of the final support substrate 510, for example, a material that relieves tensile stress, that is, induces compressive stress, such as aluminum nitride (AlN, 4.6 ppm) or aluminum oxide (Al2O3, 6.8 ppm), which serves to induce the quality improvement of products through stress control.

Meanwhile, in the present invention, the bonding reinforcement layer 521 or the compressive stress layer 522 may be omitted in some cases, and in some cases, the entire reinforcement layer 520 may be omitted so that the support substrate 510 may be in direct contact with the bonding layer 530. This case is a structure in which a material with a larger coefficient of thermal expansion than the Si (or SiC) support substrate is deposited on the bonding layer 530 to induce compressive stress together with a bonding function, or the bonding reinforcement layer 521 or the compressive stress layer 522 is provided by being deposited on the surface of the group III nitride semiconductor channel layer 540 with a nitrogen polarity (not shown).

The group III nitride semiconductor buffer layer 540 may be disposed on the bonding layer 530 and formed of a single layer or multiple layers of group III nitride semiconductors, and the group III nitride semiconductor buffer layer 540 according to the present embodiment may be made of a gallium nitride (GaN) material with high resistance characteristics for a leakage current and doped with iron (Fe), carbon (C), etc. to increase resistance as needed.

Then, a high-quality group III nitride semiconductor channel layer 550 may be re-grown on the group III nitride semiconductor buffer layer 540, and the group III nitride semiconductor re-growth layer 560 may be re-grown in a continuous process on the group III nitride semiconductor channel layer 550. In this case, the re-grown re-growth layer 560 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

In addition, as needed, a separate channel layer may be grown and inserted between the group III nitride semiconductor channel layer 550 and the re-grown re-growth layer 560 that are re-grown on the group III nitride semiconductor buffer layer 540 using a group III nitride semiconductor with a larger energy band gap than the channel layer 550 (not shown).

Hereinafter, a method S500 of manufacturing the group III nitride semiconductor template according to the fifth embodiment of the present invention will be described in detail with reference to the accompanying drawings.

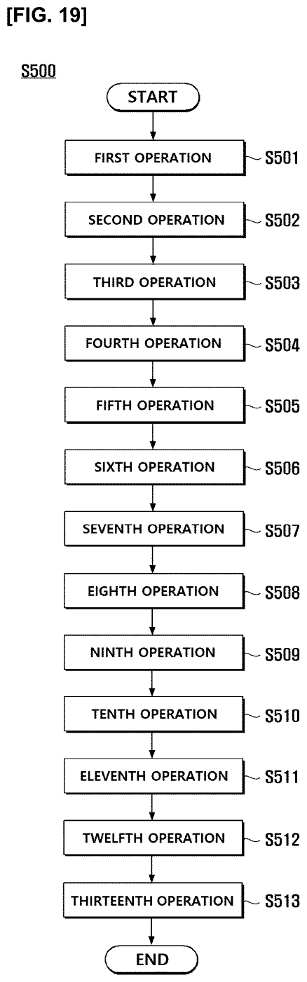

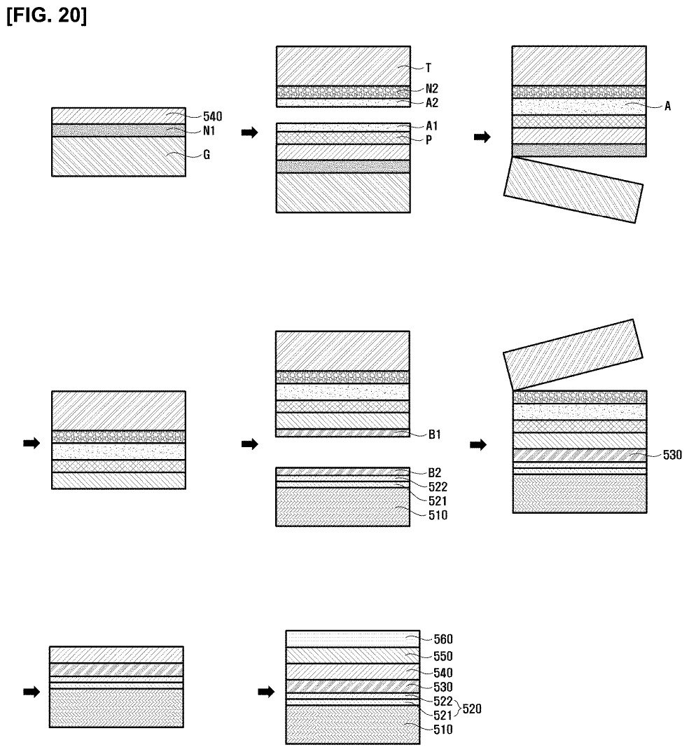

FIG. 19 is a flowchart of a method of manufacturing a group III nitride semiconductor template according to the fifth embodiment of the present invention, and FIG. 20 shows a process of manufacturing the group III nitride semiconductor template according to the fifth embodiment of the present invention.

As shown in FIGS. 19 and 20, the method S500 of manufacturing the group III nitride semiconductor template according to the fifth embodiment of the present invention includes a first operation S501, a second operation S502, a third operation S503, a fourth operation S504, a fifth operation S505, a sixth operation S506, a seventh operation S507, an eighth operation S508, a ninth operation S509, a tenth operation S510, an eleventh operation S511, a twelfth operation S512, and a thirteenth operation S513.

The first operation S501 is an operation of preparing the growth substrate G, the temporary substrate T, and a support substrate 510.

The growth substrate G is an optically transparent and high-temperature heat-resistant substrate in which a laser beam (single-wavelength light) is 100% transmitted (theoretically) without absorption after the group III nitride semiconductor channel layer 550 is grown and preferably, is preferentially made of a material such as sapphire (α-phase Al2O3), ScMgAlO4, 4H-SiC, or 6H-SiC. In addition, the growth substrate G preferably has a protrusion shape patterned regularly or irregularly in various dimensions (size and shape) in microscale or nanoscale to minimize crystal defects inside the group III nitride semiconductor thin film grown thereon.

The support substrate 510 is a substrate that supports the group III nitride semiconductor buffer layer 540, and the group III nitride semiconductor channel layer 550 and a re-growth layer 560 that are re-grown on the group III nitride semiconductor channel layer 540, and the support substrate 510 may be made of a material that has high heat dissipation performance (60 W/mK or more) and has a coefficient of thermal expansion (CTE, ppm) that is equal to or less than that of the group III nitride semiconductor buffer layer 540 or the group III nitride semiconductor channel layer 550 (GaN CTE about 5.6 ppm) and formed in a polycrystalline or single crystalline microstructure.

More specifically, the support substrate 510 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 110. In addition, the silicon (Si) or silicon carbide (SiC) support substrate 510 is preferably formed in a polycrystalline microstructure through a high-temperature sintering process rather than a single crystalline microstructure wafer, and thus there is an advantage in that it is possible to secure cost competitiveness.

The temporary substrate T is made of a material that has a coefficient of thermal expansion that is the same as or similar to that of the growth substrate G and at the same time, optically transparent, and it is preferable that a difference in coefficient of thermal expansion with the growth substrate G does not exceed a maximum of 2 ppm. The most preferable temporary substrate T material that satisfies the above may include sapphire used as the group III nitride semiconductor growth substrate G, silicon carbide (SiC), or glass whose coefficient of thermal expansion (CTE) has been adjusted to have a difference of 2 ppm or less with the growth substrate G.

The second operation S502 is an operation of forming a first sacrificial layer N1 on the growth substrate G and then growing only a high-quality group III nitride semiconductor buffer layer 540 on the first sacrificial layer N1 in a single layer or multiple layers. In this case, the grown group III nitride semiconductor buffer layer 540 may be formed of a single layer or multiple layers of group III nitride semiconductors, and the group III nitride semiconductor buffer layer 540 according to the present embodiment may be made of a gallium nitride (GaN) material with high resistance characteristics for a leakage current and doped with iron (Fe), carbon (C), etc. to increase resistance as needed.

The third operation S503 is an operation of forming an epitaxy protection layer P on the group III nitride semiconductor channel layer 540 and then forming an first adhesive layer A1 on the epitaxy protection layer P. Since the following description of the third operation S503 and the following descriptions of the fourth operation S504 to the sixth operation S506 are the same as those of the method S100 of manufacturing the group III nitride semiconductor template according to the first embodiment of the present invention, overlapping descriptions thereof will be omitted.

The seventh operation S507 is an operation of exposing the group III nitride semiconductor buffer layer 540 by etching and removing the first sacrificial layer N1. A lower surface of the first group III nitride semiconductor buffer layer 540 from which the first sacrificial layer N1 has been removed is a nitrogen polarity surface and is in a state of thermal-chemical damage, which makes it difficult to obtain the high-quality group III nitride semiconductor thin film through the re-growth layer 560 to be described below. Therefore, for bonding with the final support substrate 510, it is very important to ensure that the lower surface of the group III nitride semiconductor channel layer 540 exposed to air has a surface in a particle-zero (0) state with residues completely removed.

Meanwhile, in some cases, it is preferable to introduce a regular or irregular patterning process to the group III nitride semiconductor channel layer 540 to improve the bonding strength with the final support substrate 510 in the subsequent process; in some cases, it is preferable to introduce a CMP process to increase a contact area with the final support substrate 510 in the subsequent process; and in some cases, it is preferable to deposit aluminum nitride (AlN), aluminum nitride oxide (AlNO), aluminum oxide (Al2O3), etc. at the lower surface side of the group III nitride semiconductor channel layer 150 to improve the quality of the product by inducing compressive stress.

The eighth operation S508 is an operation of forming a first bonding layer B1 on the group III nitride semiconductor buffer layer 540. Although not shown, in some cases, the bonding reinforcement layer 521 or the compressive stress layer 522 described in the ninth operation S509 may be deposited and introduced to the surface of the group III nitride semiconductor buffer layer 540 with a nitrogen polarity.

The ninth operation S509 is an operation of forming the reinforcement layer 520 on the support substrate 510 and then forming a second bonding layer B2 on the reinforcement layer 520. Here, the reinforcement layer 520 includes a bonding reinforcement layer 521 and a compressive stress layer 522, and since the following descriptions are the same as those of the method S100 of manufacturing the group III nitride semiconductor template according to the first embodiment of the present invention, overlapping descriptions will be omitted.

The tenth operation S510 is an operation of forming the bonding layer 530 by bonding the first bonding layer B1 and the second bonding layer B2 to separate the temporary substrate T. That is, the tenth operation S510 is an operation of turning over the group III nitride semiconductor buffer layer 540 on which the first bonding layer B1 has been formed (deposited) and the temporary substrate T and pressing and bonding the same to the support substrate 510 on which the second bonding layer B2 has been formed at a temperature of lower than 300° C.

Conventionally, although epitaxy wafer bowing occurs due to thermo-mechanical induced stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

Since the eleventh operation S511 and the twelfth operation S512 are the same as those of the method S100 of manufacturing the group III nitride semiconductor template according to the first embodiment of the present invention, overlapping descriptions thereof will be omitted.

The thirteenth operation S513 is an operation of re-growing a high-quality group III nitride semiconductor channel layer 550 on the group III nitride semiconductor buffer layer 540 and re-growing a high-quality group III nitride semiconductor re-growth layer 560 on the group III nitride semiconductor channel layer 550. In this case, the re-grown re-growth layer 560 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

Hereinafter, a group III nitride semiconductor template according to a sixth embodiment of the present invention will be described in detail with reference to the accompanying drawings.

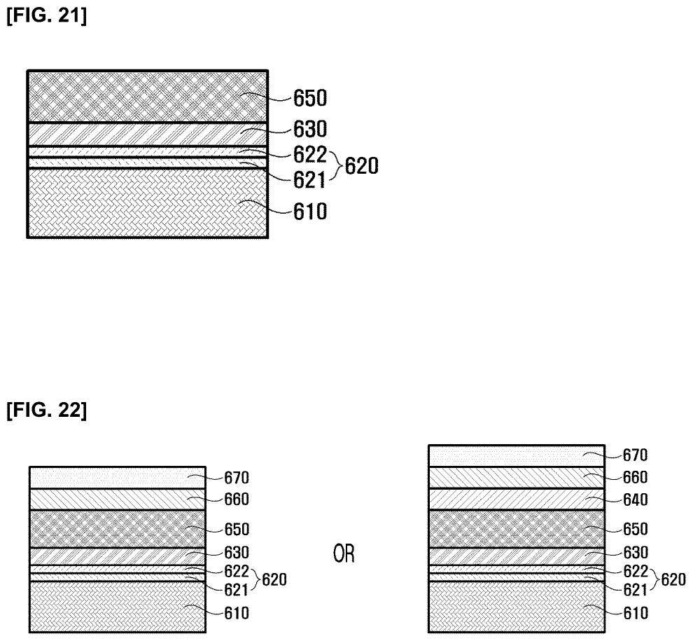

FIG. 21 shows a group III nitride semiconductor template according to a sixth embodiment of the present invention, and FIG. 22 shows that a re-growth layer is re-grown on the group III nitride semiconductor template according to the sixth embodiment of the present invention.

As shown in FIGS. 21 and 22, the group III nitride semiconductor template according to the sixth embodiment of the present invention includes a support substrate 610, a reinforcement layer 620, a bonding layer 630, and a second group III nitride semiconductor buffer layer 650. In this case, the formation and thickness of each layer may vary depending on the type of a power semiconductor device and a growth substrate G that are applied.

The support substrate 610 is a substrate that supports the second group III nitride semiconductor buffer layer 650, and a first group III nitride semiconductor buffer layer 640, a group III nitride semiconductor channel layer 660, or a re-growth layer 670, which is re-grown on the second group III nitride semiconductor buffer layer, and the support substrate 610 may be made of a material that has high heat dissipation performance (60 W/mK or more) and has a coefficient of thermal expansion (CTE, ppm) that is equal to or less than that of the second group III nitride semiconductor buffer layer 650 (GaN CTE about 5.6 ppm) and formed in a polycrystalline or single crystalline microstructure.

More specifically, the support substrate 610 may include at least one material selected from materials including silicon (Si) and silicon carbide (SiC). Here, the heat dissipation performance of silicon (Si) is 149 W/mK, the heat dissipation performance of silicon carbide (SiC) ranges from 300 to 450 W/mK, the coefficient of thermal expansion of silicon (Si) is 2.6 ppm, and the coefficient of thermal expansion of silicon carbide (SiC) ranges from 4 to 4.8 ppm (depending on quality), which are each suitable as a material of the high heat dissipation support substrate 610. In addition, the silicon (Si) or silicon carbide (SiC) support substrate 610 is preferably formed in a polycrystalline microstructure through a high-temperature sintering process rather than a single crystalline microstructure wafer, and thus there is an advantage in that it is possible to secure cost competitiveness.

The bonding layer 630 is used to bond the support substrate 610 and the second group III nitride semiconductor buffer layer 650, may be disposed on the reinforcement layer 620 to be described below, and made of a permanent bonding material.

More specifically, the bonding layer 630 may contain a metal such as aluminum (Al), tungsten (W), or molybdenum (Mo) or an alloy thereof, silicon oxide (SiOx), silicon nitride (SiNx), aluminum oxide (Al2O3), aluminum nitride (AlN), aluminum gallium nitride (AlGaN), gallium nitride (GaN), indium gallium nitride (InGaN), indium nitride (InN), amorphous or polycrystalline silicon (Si), zinc oxide (ZnO), C60 (fullerene), or furthermore, may additionally contain a flowable oxide (FOx) such as SOG or HSQ to improve surface roughness. In particular, it is preferable to use a chemical vapor deposition (CVD) process such as an MOCVD or ALD process for aluminum nitride (AlN), aluminum gallium nitride (AlGaN), gallium nitride (GaN), indium gallium nitride (InGaN), and indium nitride (InN) materials.

The reinforcement layer 620 is formed so that the second group III nitride semiconductor channel layer 650 may be more strongly bonded to the support substrate 610, induces compressive stress, and is disposed in contact with an upper surface or lower surface of the bonding layer 630. That is, as shown in FIG. 25, the reinforcement layer 620 may be disposed between the support substrate 610 and the bonding layer 630 and/or between the group III nitride semiconductor layer and the bonding layer 630.

More specifically, the reinforcement layer 620 includes a bonding reinforcement layer 621 and a compressive stress layer 622.

The bonding reinforcement layer 621 is a layer introduced to reinforce bonding strength when the second group III nitride semiconductor buffer layer 650 is bonded on the final support substrate 610 through the bonding layer 630, and it is preferable that a material forming the bonding reinforcement layer 621 be preferentially selected from silicon oxide (SiO2), silicon nitride (SiNx), etc.

The compressive stress layer 622 is a layer that induces compressive stress and is made of a material that has a value larger than the coefficient of thermal expansion of the final support substrate 610, for example, a material that relieves tensile stress, that is, induces compressive stress, such as aluminum nitride (AlN, 4.6 ppm), aluminum nitride oxide (AlNO, 4.6 to 6.8 ppm; depending on a content ratio of AlN and Al2O3), or aluminum oxide (Al2O3, 6.8 ppm), which serves to induce the improvement in quality of products through stress control.

Meanwhile, in the present invention, the bonding reinforcement layer 621 or the compressive stress layer 622 may be omitted in some cases, and in some cases, the entire reinforcement layer 620 may be omitted so that the support substrate 610 may be in direct contact with the bonding layer 630. This case is a structure in which a material with a larger coefficient of thermal expansion than the Si (or SiC) support substrate is deposited on the bonding layer 630 to induce compressive stress together with a bonding function, or the bonding reinforcement layer 621 or the compressive stress layer 622 is provided by being deposited on the surface of the second group III nitride semiconductor channel layer 650 with a nitrogen polarity (not shown).

The second group III nitride semiconductor buffer layer 650 may be disposed on the bonding layer 630 and formed of a single layer or multiple layers of group III nitride semiconductors, and the second group III nitride semiconductor buffer layer 650 according to the present embodiment may be made of one or more of aluminum nitride (AlN), aluminum nitride oxide (AlNO), and aluminum oxide (Al2O3), which have high resistance characteristics for a leakage current even without separate doping such as iron (Fe) or carbon (C).

Then, a high-quality group III nitride semiconductor channel layer 660 may be re-grown on the second group III nitride semiconductor buffer layer 650, and the group III nitride semiconductor re-growth layer 670 may be re-grown on the group III nitride semiconductor channel layer 660. In this case, the re-grown re-growth layer 670 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

Alternatively, a first high-quality group III nitride semiconductor buffer layer 640 may be re-grown on the second group III nitride semiconductor buffer layer 650, and after the group III nitride semiconductor channel layer 660 is re-grown on the first group III nitride semiconductor buffer layer 640, the group III nitride semiconductor re-grown layer 670 may be re-grown on the group III nitride semiconductor channel layer 660. In this case, the first group III nitride semiconductor buffer layer 640 may be formed of a single layer or multiple layers of group III nitride semiconductors, and the first group III nitride semiconductor buffer layer 640 according to the present embodiment may be made of a gallium nitride (GaN) material with high resistance characteristics for a leakage current and doped with iron (Fe), carbon (C), etc. to increase resistance as needed.

Hereinafter, a method S600 of manufacturing the group III nitride semiconductor template according to the sixth embodiment of the present invention will be described in detail with reference to the accompanying drawings.

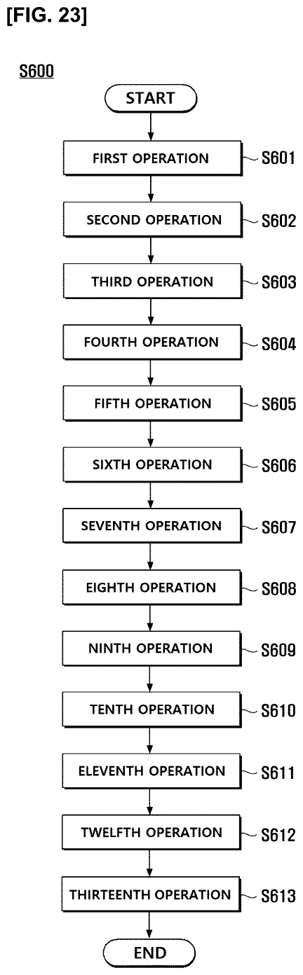

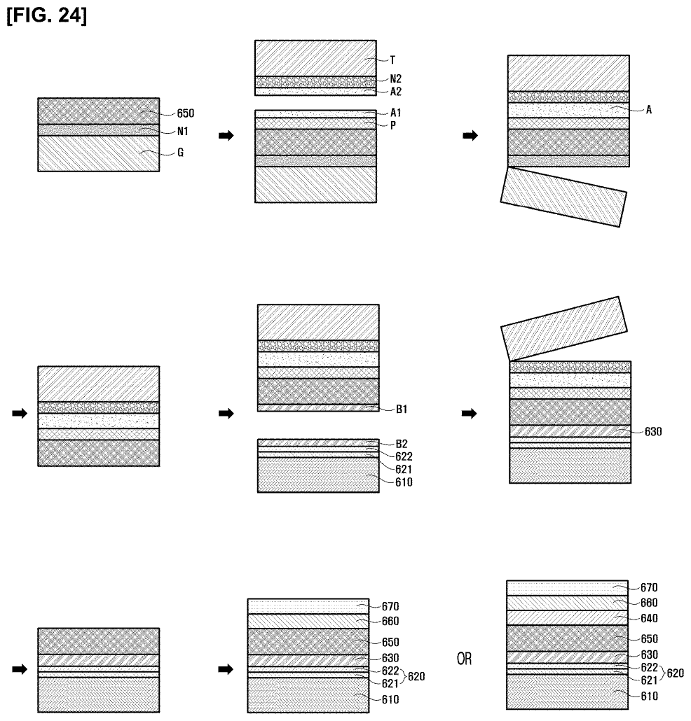

FIG. 23 is a flowchart of a method of manufacturing a group III nitride semiconductor template according to the sixth embodiment of the present invention, and FIG. 24 shows a process of manufacturing the group III nitride semiconductor template according to the sixth embodiment of the present invention.

As shown in FIGS. 23 and 24, the method S600 of manufacturing the group III nitride semiconductor template according to the sixth embodiment of the present invention includes a first operation S601, a second operation S602, a third operation S603, a fourth operation S604, a fifth operation S605, a sixth operation S606, a seventh operation S607, an eighth operation S608, a ninth operation S609, a tenth operation S610, an eleventh operation S611, a twelfth operation S612, and a thirteenth operation S613.

The first operation S601 is an operation of preparing the growth substrate G, the temporary substrate T, and a support substrate 610. Since the following descriptions are the same as those of the method S500 of manufacturing the group III nitride semiconductor template according to the fifth embodiment of the present invention, overlapping descriptions thereof will be omitted.

The second operation S602 is an operation of forming a first sacrificial layer N1 on the growth substrate G and then growing only a second high-quality group III nitride semiconductor buffer layer 650 on the first sacrificial layer N1 in a single layer or multiple layers. In this case, the second grown group III nitride semiconductor buffer layer 650 may be formed of a single layer or multiple layers of group III nitride semiconductors, and the second group III nitride semiconductor buffer layer 650 according to the present embodiment may be made of an aluminum nitride (AlN) material with high resistance characteristics for a leakage current even without separate doping such as iron (Fe) or carbon (C).

Since the descriptions of the third operation S603 to the twelfth operation S612 are the same as those of the method S500 of manufacturing the group III nitride semiconductor template according to the fifth embodiment of the present invention, overlapping descriptions thereof will be omitted.

The thirteenth operation S613 is an operation of re-growing a high-quality group III nitride semiconductor re-growth layer on the first group III nitride semiconductor buffer layer 640.

Specifically, the thirteenth operation S613 may include 1) re-growing the group III nitride semiconductor channel layer 660 directly on the group III nitride semiconductor buffer layer, or 2) re-growing a new first group III nitride semiconductor buffer layer 640 on the group III nitride semiconductor buffer layer made of aluminum nitride (AlN), then re-growing the group III nitride semiconductor channel layer 660, and then re-growing a high-quality group III nitride semiconductor re-grown layer 670 on the group III nitride semiconductor channel layer 660. In this case, the first group III nitride semiconductor buffer layer 650 may be formed of a single layer or multiple layers of group III nitride semiconductors, and the first group III nitride semiconductor buffer layer 640 according to the present embodiment may be made of a gallium nitride (GaN) material with high resistance characteristics for a leakage current and doped with iron (Fe), carbon (C), etc. to increase resistance as needed.

In this case, the re-grown re-growth layer 670 may be an aluminum gallium nitride (AlGaN) barrier layer, but is not limited thereto, and may include all structures of typical group III nitride semiconductor (HEMT) devices including a p-type nitride semiconductor injection layer, a silicon nitride (SiN) passivation layer, etc.

Hereinafter, a method S700 of manufacturing the group III nitride semiconductor template according to the seventh embodiment of the present invention will be described in detail with reference to the accompanying drawings.

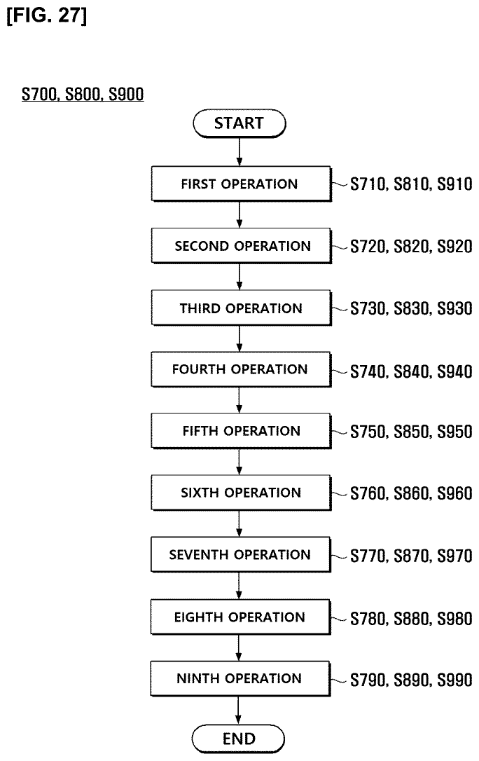

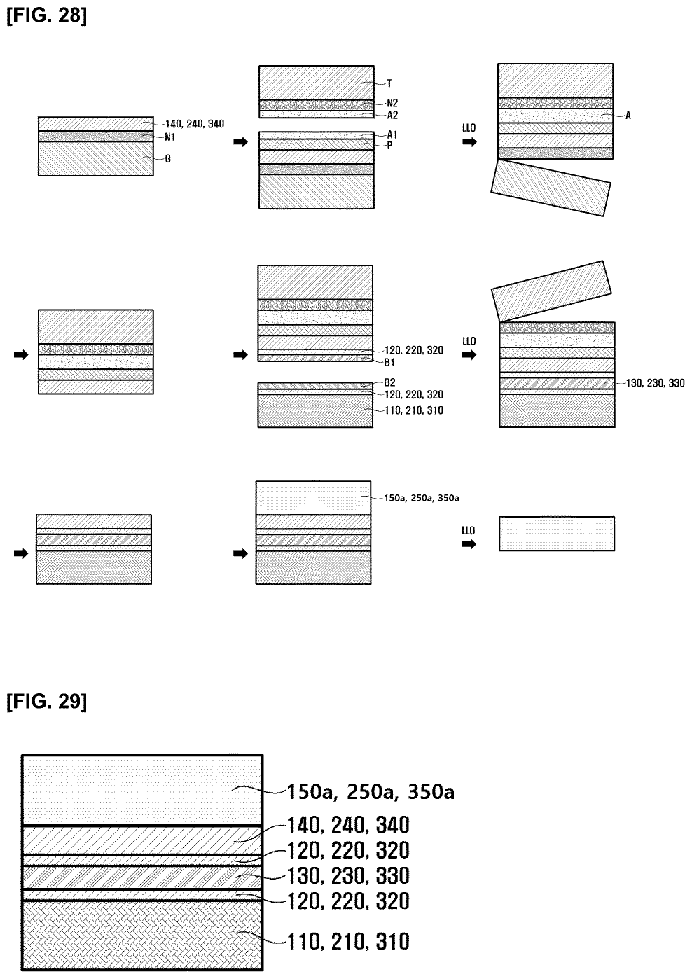

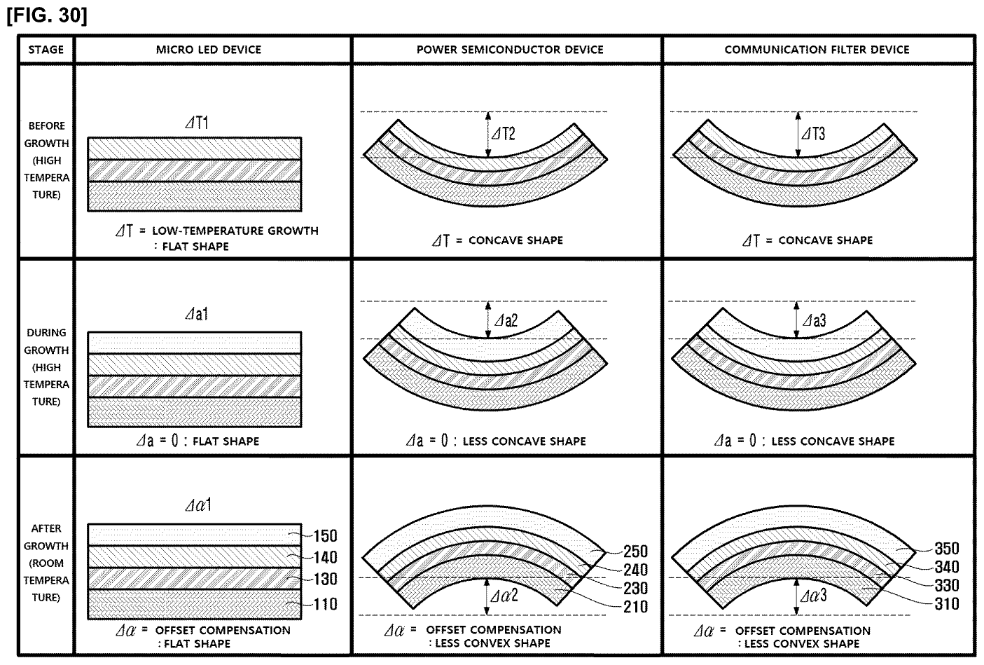

FIG. 27 is a flowchart of a method of manufacturing a group III nitride semiconductor template according to seventh to ninth embodiments of the present invention, FIG. 28 shows a process of manufacturing a semiconductor device by the method of manufacturing a group III nitride semiconductor template according to the seventh to ninth embodiments of the present invention, FIG. 29 shows that the semiconductor device is formed on the semiconductor template manufactured by the method of manufacturing a group III nitride semiconductor template according to the seventh to ninth embodiments of the present invention, and FIG. 30 shows an epitaxy wafer shape for each product according to a surface temperature difference, a lattice constant difference, and a coefficient of thermal expansion difference between upper and lower portions of a sapphire support substrate in the semiconductor device manufactured by the method of manufacturing a group III nitride semiconductor template according to the seventh to ninth embodiments of the present invention.

As shown in FIGS. 27 to 30, the method S700 of manufacturing the group III nitride semiconductor template according to the seventh embodiment of the present invention includes a first operation S710, a second operation S720, a third operation S730, a fourth operation S740, a fifth operation S750, a sixth operation S760, a seventh operation S770, an eighth operation S780, and a ninth operation S790.

The first operation S710 is an operation of preparing the growth substrate G, the temporary substrate T, and the support substrate 110.

The growth substrate G is an optically transparent and high-temperature heat-resistant substrate in which a laser beam (single-wavelength light) is 100% transmitted (theoretically) without absorption after a group III nitride semiconductor seed layer 140 is grown and may be made of sapphire materials (Al2O3, ScMgAlO4), silicon carbide (SiC), etc. In addition, the growth substrate G preferably has a protrusion shape patterned regularly or irregularly in various dimensions (size and shape) in microscale or nanoscale to minimize crystal defects inside the group III nitride semiconductor thin film grown thereon.

The support substrate 110 is a substrate that supports the group III nitride semiconductor seed layer 140 and the device active layer after undergoing each operation of the method S700 of manufacturing the group III nitride semiconductor template according to the seventh embodiment of the present invention, and the support substrate 110 may be made of the same sapphire materials (Al2O3, ScAlMgO4), silicon carbide (SiC), etc. as the growth substrate G.

The temporary substrate T is made of a material that has a coefficient of thermal expansion that is the same as or similar to that of the growth substrate G and at the same time, optically transparent, and it is preferable that a difference in coefficient of thermal expansion with the growth substrate G does not exceed a maximum of 2 ppm. The temporary substrate T material satisfying the above may include sapphire materials (Al2O3, ScAlMgO4), silicon carbide (SiC), glass whose coefficient of thermal expansion (CTE) is adjusted to have a difference of 2 ppm or less from the growth substrate G, etc., and in the present invention, the temporary substrate T is preferably made of the same sapphire materials (Al2O3, ScAlMgO4) as the growth substrate G and the support substrate 110.

The second operation S720 is an operation of forming a first sacrificial layer N1 on the growth substrate G and then growing a high-quality group III nitride semiconductor seed layer 140 on the first sacrificial layer N1 in a single layer or multiple layers.

Here, the first sacrificial layer N1 is a layer required for growing the high-quality group III nitride semiconductor seed layer 140 and may be made of a material capable of sacrificial separation by a thermal-chemical decomposition reaction caused by a laser beam, and for example, the sapphire growth substrate G may contain indium gallium nitride (InGaN), gallium nitride (GaN), aluminum gallium nitride (AlGaN), and indium aluminum nitride (InAlN). The first sacrificial layer N1 is grown directly on the initial growth substrate G to minimize crystal defects in the group III nitride semiconductor seed layer 140 and serves as a buffer layer.

In addition, the group III nitride semiconductor seed layer 140 may be formed of a single layer or multiple layers of group III nitride semiconductors and made of gallium nitride (GaN), indium gallium nitride (InGaN), aluminum nitride (AlN), aluminum gallium nitride (AlGaN), aluminum gallium nitride (AlGaInN), gallium nitride (indium)/n-type gallium nitride (indium) (Ga(In)N/nGa(In)N), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, etc., which have high-temperature (HT) and high-resistance (HR) characteristics. The group III nitride semiconductor seed layer 140 is a critical quality factor in reducing fatal crystal defects, that is, the density of threading dislocations (present in a vertical direction with respect to the initial growth substrate G) (≤Low 108/cm2).

Meanwhile, since a surface of the group III nitride semiconductor seed layer 140 formed on the growth substrate G and a surface of the group III nitride semiconductor seed layer 140 transferred onto the temporary substrate T are inverted, it is preferable to form a microstructure by treating a surface of the growth substrate G so that a predetermined preferred group III nitride semiconductor seed layer 140 surface may be formed. For example, in the case of a gallium nitride (GaN) semiconductor seed layer, a gallium polarity (Ga-polarity) or nitrogen polarity (N-polarity) surface may be selectively adjusted according to the surface treatment and growth conditions of the growth substrate G. Typically, when the group III nitride semiconductor seed layer 140 is grown on the sapphire growth substrate G in a MOCVD chamber, while the group III nitride semiconductor seed layer 140 has a surface with a metal (M: Ga, Al, In) polarity with 3 valence electrons, an interface in direct contact with the sapphire growth substrate G has a nitrogen polarity with 5 valence electrons.

The third operation S730 is an operation of forming an adhesive layer A by forming the epitaxy protection layer P on the group III nitride semiconductor seed layer 140, then forming an first adhesive layer A1, forming a second sacrificial layer N2 on the temporary substrate T, then forming a second adhesive layer A2, and then bonding the first adhesive layer A1 and the second adhesive layer A2. That is, the third operation S730 is an operation of turning over the temporary substrate T on which the second adhesive layer A2 has been formed and pressing and bonding the same to the growth substrate G on which the first adhesive layer A1 has been formed at a temperature of lower than 300° C.

Here, the epitaxy protection layer P is a layer for preventing the group III nitride semiconductor seed layer 140 from being damaged during a subsequent process, may be made of a material in consideration of selective wet etching, and the epitaxy protection layer P may preferentially contain, for example, an oxide including silicon oxide (SiO2), a nitride including silicon nitride (SiNx), etc. In some cases, a metal or alloy thin film may be formed of a single layer or multiple layers.

In addition, the optically transparent temporary substrate T is a substrate that is finally easily separated by an LLO technique in the subsequent process, and before forming the second adhesive layer A2, the second sacrificial layer N2 (LLO sacrificial layer) may be deposited on the temporary substrate T. The above-described second sacrificial layer N2 material may include oxides, nitrides, etc., which may be deposited by a PVD technique such as a sputtering, PLD, or evaporator technique and specifically, may contain a material such as indium tin oxide (ITO), gallium oxide (GaOx), gallium oxide nitride (GaON), gallium nitride (GaN), indium gallium nitride (InGaN), tin oxide (ZnO), indium gallium tin oxide (InGaZnO), indium tin oxide (InZnO), or indium gallium oxide (InGaO). In addition, as needed, a bonding reinforcement layer 120 may be separately provided before the second sacrificial layer N2 is deposited so that the second sacrificial layer N2 material may be strongly bonded to an upper portion of the temporary substrate T. In this case, the bonding reinforcement layer 120 may contain a material that is optically transparent when irradiated with a laser beam, for example, preferentially, an oxide including silicon oxide (SiO2), a nitride including silicon nitride (SiNx), etc. In addition, a protective film layer of silicon oxide (SiO2) may be included as needed.

In addition, the first adhesive layer A1 and the second adhesive layer A2 may contain benzocyclobutene (BCB), polyimide (PI), a SU-8 polymer, an epoxy, organic, indium (In), tin (Sn) material-based solder, silicon oxide (SiO2, 0.8 ppm), silicon nitride (SiNx, 3.8 ppm), silicon carbon nitride (SiCN, 3.8 to 4.8 ppm), aluminum nitride (AlN, 4.6 ppm), aluminum oxide (Al2O3, 6.8 ppm), or a flowable oxide (FOX) such as SOG or HSQ to improve surface roughness.

The fourth operation S740 is an operation of separating the growth substrate G from the first sacrificial layer N1 using an LLO technique and then separating the growth substrate G from the group III nitride semiconductor seed layer 140 by etching and removing the first sacrificial layer N1. Here, the LLO technique is a technique of separating an epitaxy-grown layer from the growth substrate G by irradiating a back surface of the transparent growth substrate G with an ultraviolet (UV) laser beam having a uniform optical output and beam profile, and a single wavelength. When the initial growth substrate G is separated, the inside of the group III nitride semiconductor seed layer 140 transferred onto the temporary substrate T is in a state in which the stress has been completely relieved and maintains a flat state together with the temporary substrate T. Then, it is preferable that a region damaged due to the separation of the growth substrate G, contaminated surface residue, and low-quality single crystalline thin film region be removed as completely as possible.

In addition, a lower surface of the group III nitride semiconductor seed layer 140 from which the first sacrificial layer N1 has been removed is a nitrogen polarity surface and is in a state of surface damage due to a thermo-chemical decomposition reaction, which makes it difficult to obtain the high-quality device active layer 150a to be described below. Therefore, for bonding with the final support substrate 110, it is very important to ensure that the lower surface of the group III nitride semiconductor seed layer 140 exposed to air has a surface in a particle-zero (0) state with residues completely removed.

Meanwhile, in some cases, it is preferable to introduce a regular or irregular patterning process to the group III nitride semiconductor seed layer 140 to improve the bonding strength with the final support substrate 110 in the subsequent process; in some cases, it is preferable to introduce a CMP process to increase a contact area with the final support substrate 110 in the subsequent process; and in some cases, it is preferable to deposit aluminum nitride (AlN), aluminum nitride oxide (AlNO), aluminum oxide (Al2O3), etc. at the lower surface side of the group III nitride semiconductor seed layer 140 to improve the quality of the product by inducing compressive stress.

The fifth operation S750 is an operation of forming the bonding layer 130 by forming the reinforcement layer 120 on the group III nitride semiconductor seed layer 140, then forming a first bonding layer B1, forming the reinforcement layer 120 on the support substrate 110, then forming a second bonding layer B2, and then bonding the first bonding layer B1 and the second bonding layer B2. That is, the fifth operation S750 is an operation of turning over the group III nitride semiconductor seed layer 140 on which the first bonding layer B1 has been formed (deposited) and the temporary substrate T and pressing and bonding the same to the support substrate 110 on which the second bonding layer B2 has been formed at a temperature of lower than 300° C. In addition, depending on the adhesive layer (A) material used in the third operation S730, bonding can be achieved by applying pressure even at a high temperature of 300° C. or higher.

Conventionally, although epitaxy wafer bowing occurs due to thermo-mechanical stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

In addition, the first bonding layer B1 and the second bonding layer B2 are each preferentially selected from materials whose properties do not change in the MOCVD chamber (at a temperature of 1000° C. or higher and in a reducing atmosphere) that the group III nitride semiconductor is grown, may contain, for example, silicon oxide (SiO2, 0.8 ppm), silicon nitride (SiNx, 3.8 ppm), silicon carbon nitride (SiCN, 3.8 to 4.8 ppm), aluminum nitride (AlN, 4.6 ppm), aluminum oxide (Al2O3, 6.8 ppm), and furthermore, may contain a flowable oxide (FOx) such as SOG (liquid SiO2) or HSQ to improve surface roughness.

Meanwhile, each reinforcement layer 120, more specifically, includes a bonding reinforcement layer and a compressive stress layer.

The bonding reinforcement layer is a layer introduced to reinforce bonding strength when the group III nitride semiconductor seed layer 140 is bonded on the final support substrate 110 through the bonding layer 130, is disposed in contact with each of the group III nitride semiconductor seed layer 140 or the support substrate 110, and it is preferable to preferentially select a material constituting the bonding reinforcement layer from silicon oxide (SiO2), silicon nitride (SiNx), etc.

The compressive stress layer is a layer that induces compressive stress, is disposed on the bonding reinforcement layer (i.e., the bonding reinforcement layer is disposed between the group III nitride semiconductor seed layer 140 and the compressive stress layer or between the compressive stress layer and the support substrate 110), and is made of a material that has a value larger than the coefficient of thermal expansion of the final support substrate 110, for example, a material that relieves tensile stress, that is, induces compressive stress, such as aluminum nitride (AlN, 4.6 ppm), aluminum nitride oxide (AlNO, 4.6 to 6.8 ppm), or aluminum oxide (Al2O3, 6.8 ppm), which serves to induce the quality improvement of products through stress control.

Meanwhile, in the present invention, the bonding reinforcement layer or the compressive stress layer may be omitted in some cases, and in some cases, the entire reinforcement layer 120 may be omitted so that the support substrate 110 and the bonding layer 130 or the bonding layer 130 and the group III nitride semiconductor seed layer 140 may be in direct contact.

The sixth operation S760 is an operation of separating the temporary substrate T from the second sacrificial layer N2 by separating the temporary substrate T from the adhesive layer A using an LLO technique.

The seventh operation S770 is an operation of etching and removing the second sacrificial layer N2, the adhesive layer A, and the epitaxy protection layer P. Here, the second sacrificial layer N2, the adhesive layer A, and the epitaxy protection layer P may be formed through dry etching and wet etching. Then, the residue on the surface of the contaminated group III nitride semiconductor seed layer 140 may be removed, and as needed, it is preferable to perform an annealing process at a high temperature of 400° C. or higher to reinforce the bonding strength of the permanent bonding layer 130.

The eighth operation S780 is an operation of forming a high-quality device active layer 150a on the group III nitride semiconductor seed layer 140. In this case, micro LED elements are formed on the device active layer 150a, and specifically, an n-type gallium nitride (nGaN), an indium gallium nitride (InGaN)-based active layer (MQWs), a p-type aluminum gallium nitride (pAlGaN), and a p-type gallium nitride (pGaN) are formed by being sequentially stacked on the group III nitride semiconductor seed layer 140. In addition, when the n-type gallium nitride (GaN) materials are contained in the group III nitride semiconductor seed layer 140, the n-type gallium nitride (nGaN) may be omitted.

FIG. 30 shows a shape of the epitaxy wafer for each product according to the differences in surface temperature, lattice constant, and coefficient of thermal expansion between upper and lower portions of the sapphire support substrate, and a micro LED having an InGaN-based active layer (MQWs) exhibits a state in which there is less bowing due to a low growth temperature of the MQWs. As shown in FIG. 30, according to the present invention, since the difference (Δa) in lattice constant during growth may be close to zero, and the difference (Δα) in coefficient of thermal expansion after growth may be compensated for, a flat shape is possible. Therefore, since stress relief and a temperature gradient can be improved during the growth of the MQW compared to the related art, the uniformity of a composition ratio of ternary or quaternary alloys (In, Ga, Al) and the doping amount of a dopant (Si, Mg) can be improved, thereby significantly improving the wavelength dispersion in the wafer, and the photoelectric characteristics and uniformity and significantly reducing a full width at half maximum (FWHM).

The ninth operation S790 is an operation of separating the device active layer 150a from the group III nitride semiconductor seed layer 140 using an LLO technique.

That is, when a back surface of the sapphire support substrate 110 is irradiated with a laser beam, the laser beam may pass through the optically transparent sapphire support substrate 110, the reinforcement layer 120, and the bonding layer 130, and due to the absorption in the group III nitride semiconductor seed layer 140, heat of about 900° C. is instantaneously generated, and thus the sapphire support substrate 110, the reinforcement layer 120, and the bonding layer 130 may be separated from the device active layer with a melting phenomenon. Therefore, since the LLO process is possible without a design that introduces a separate LLO sacrificial layer between the sapphire support substrate 110 and the group III nitride semiconductor seed layer 140, there can be a significant advantage in the field of micro LED displays in which an LLO transfer process is absolutely needed.

According to the method S700 of manufacturing the group III nitride semiconductor template according to the seventh embodiment of the present invention, which includes the first operation S710, the second operation S720, the third operation S730, the fourth operation S740, the fifth operation S750, the sixth operation S760, the seventh operation S770, the eighth operation S780, and the ninth operation S790, the stress caused by the differences in lattice constant (LC) and coefficient of thermal expansion (CTE) between the initial sapphire growth substrate G and the gallium nitride (GaN) materials can be significantly removed or relieved, and the compressive stress caused by the difference in coefficient of thermal expansion after the growth of the initial seed layer can also be completely removed or relieved after separating the sapphire growth substrate G, and thus it is possible to manufacture a flat group III nitride semiconductor template with almost no bowing phenomenon.

In addition, according to the present invention, when manufacturing micro LED devices, stress relief and a temperature gradient can be improved when growing InGaN-based active layers (MQWs), and thus the uniformity of the composition ratio of ternary or quaternary alloys (In, Ga, Al) and the doping amount of a dopant (Si, Mg) can be improved, thereby significantly improving the wavelength dispersion in the wafer, and the photoelectric characteristics and uniformity. This has a very large effect on quality improvement, especially, when manufacturing ultraviolet, blue, green, and red micro LED devices.

Hereinafter, a method S800 of manufacturing the group III nitride semiconductor template according to the eighth embodiment of the present invention will be described in detail with reference to the accompanying drawings.

FIG. 27 is a flowchart of a method of manufacturing a group III nitride semiconductor template according to seventh to ninth embodiments of the present invention, FIG. 28 shows a process of manufacturing a semiconductor device by the method of manufacturing a group III nitride semiconductor template according to the seventh to ninth embodiments of the present invention, FIG. 29 shows that the semiconductor device is formed on the semiconductor template manufactured by the method of manufacturing a group III nitride semiconductor template according to the seventh to ninth embodiments of the present invention, and FIG. 30 shows an epitaxy wafer shape for each product according to a surface temperature difference, a lattice constant difference, and a coefficient of thermal expansion difference between upper and lower portions of a sapphire support substrate in the semiconductor device manufactured by the method of manufacturing a group III nitride semiconductor template according to the seventh to ninth embodiments of the present invention.

As shown in FIGS. 27 to 30, the method S800 of manufacturing the group III nitride semiconductor template according to the eighth embodiment of the present invention includes a first operation S810, a second operation S820, a third operation S830, a fourth operation S840, a fifth operation S850, a sixth operation S860, a seventh operation S870, an eighth operation S880, and a ninth operation S890.

Here, since the first operation S810 to the seventh operation S870 are the same as those of the method S700 of manufacturing the group III nitride semiconductor template according to the seventh embodiment of the present invention, overlapping descriptions thereof will be omitted.

The eighth operation S880 is an operation of forming a high-quality device active layer 250a on the group III nitride semiconductor seed layer 240. In this case, a power semiconductor device is formed on the device active layer 250a, specifically, a power semiconductor having a horizontal channel structure such as a HEMT containing gallium nitride (GaN) materials or a power semiconductor having a vertical channel structure is formed.

FIG. 30 shows the shape of the epitaxy wafer for each product according to the differences in surface temperature, lattice constant, and coefficient of thermal expansion of the upper and lower portions of the sapphire support substrate 210, and as shown in FIG. 30, according to the present invention, the difference (Δa) in lattice constant during growth may be close to zero, and thus a less concave shape may be obtained, and the difference (Δα) in coefficient of thermal expansion after growth may be compensated for, and thus a less convex shape may be obtained. Therefore, since a high-quality thick-film gallium nitride (GaN) material-based layer without cracks may be grown compared to the related art, a high-quality power semiconductor device with a vertical drift structure may be manufactured. In addition, it is possible to manufacture a high-quality HEMT with an improved aluminum (Al) composition ratio and thickness uniformity in an aluminum gallium nitride (AlGaN) barrier with a thickness of about 20 nm.

The ninth operation S890 is an operation of separating the device active layer 250a from the group III nitride semiconductor seed layer 240 using an LLO technique.

That is, when the back surface of the sapphire support substrate 210 is irradiated with a laser beam, the laser beam may pass through the optically transparent sapphire support substrate 210, the reinforcement layer 220, and the bonding layer 230, and due to the absorption in the group III nitride semiconductor seed layer 240, heat of about 900° C. is instantaneously generated, and thus the sapphire support substrate 210, the reinforcement layer 220, and the bonding layer 230 may be separated from the device active layer with a melting phenomenon. Therefore, there is an effect that the LLO process is possible without a design that introduces a separate LLO sacrificial layer between the sapphire support substrate 210 and the group III nitride semiconductor seed layer 240.

According to the method S800 of manufacturing the group III nitride semiconductor template according to the eighth embodiment of the present invention, which includes the first operation S810, the second operation S820, a third operation S830, the fourth operation S840, the fifth operation S850, the sixth operation S860, the seventh operation S870, the eighth operation S880, and the ninth operation S890, the stress caused by the differences in lattice constant (LC) and coefficient of thermal expansion (CTE) between the initial sapphire growth substrate G and the gallium nitride (GaN) materials can be significantly removed or relieved, and the compressive stress caused by the difference in coefficient of thermal expansion after the growth of the initial seed layer can also be completely removed or relieved after separating the sapphire growth substrate G, and thus it is possible to manufacture a flat group III nitride semiconductor template with almost no bowing phenomenon.

In addition, according to the present invention, when manufacturing a power semiconductor device, the thickness of an aluminum gallium nitride (AlGaN) barrier layer with the thickness of about 20 nm of a HEMT having a horizontal channel structure, the uniformity of the aluminum (Al) composition ratio, and the uniformity of the carbon (C) or iron (Fe) doping amount in a high-resistivity gallium nitride (GaN) buffer layer can be significantly improved, thereby improving yield and characteristics.

In addition, according to the present invention, in addition to the above effects, the power semiconductor device having a vertical drift structure has an effect of securing high-quality gallium nitride (GaN) materials with a thickness of 10 μm or more without cracks during the growth of a thick film.

Hereinafter, a method S900 of manufacturing the group III nitride semiconductor template according to the ninth embodiment of the present invention will be described in detail with reference to the accompanying drawings.

FIG. 27 is a flowchart of a method of manufacturing a group III nitride semiconductor template according to seventh to ninth embodiments of the present invention, FIG. 28 shows a process of manufacturing a semiconductor device by the method of manufacturing a group III nitride semiconductor template according to the seventh to ninth embodiments of the present invention, FIG. 29 shows that the semiconductor device is formed on the semiconductor template manufactured by the method of manufacturing a group III nitride semiconductor template according to the seventh to ninth embodiments of the present invention, and FIG. 30 shows an epitaxy wafer shape for each product according to a surface temperature difference, a lattice constant difference, and a coefficient of thermal expansion difference between upper and lower portions of a sapphire support substrate in the semiconductor device manufactured by the method of manufacturing a group III nitride semiconductor template according to the seventh to ninth embodiments of the present invention.

As shown in FIGS. 27 to 30, the method S900 of manufacturing the group III nitride semiconductor template according to the ninth embodiment of the present invention includes a first operation S910, a second operation S920, a third operation S930, a fourth operation S940, a fifth operation S950, a sixth operation S960, a seventh operation S970, an eighth operation S980, and a ninth operation S990.

Here, since the first operation S910 to the seventh operation S970 are the same as those of the method S700 of manufacturing the group III nitride semiconductor template according to the seventh embodiment of the present invention, overlapping descriptions thereof will be omitted.

The eighth operation S980 is an operation of forming a high-quality device active layer 350a on the group III nitride semiconductor seed layer 340. In this case, a communication filter device is formed on the device active layer 350a, and specifically, a BAW or SAW filter device for 5G wireless and Wi-Fi communication, which contains aluminum nitride (AlN) materials, is formed.

FIG. 30 shows the shape of the epitaxy wafer for each product according to the differences in surface temperature, lattice constant, and coefficient of thermal expansion of the upper and lower portions of the sapphire support substrate 310, and as shown in FIG. 30, according to the present invention, the difference (Δa) in lattice constant during growth may be close to zero, and thus a less concave shape may be obtained, and the difference (Δα) in coefficient of thermal expansion after growth may be compensated for, and thus a less convex shape may be obtained. Therefore, a high-quality aluminum nitride (AlN) single crystalline thin film with a thickness of about 1.5 μm may be grown compared to the related art, and a high-performance BAW or SAW filter may be manufactured through the aluminum nitride (AlN) single crystalline thin film with a thickness uniformity within 1%.

The ninth operation S690 is an operation of separating the device active layer 350a from the group III nitride semiconductor seed layer 340 using an LLO technique.

That is, the back surface of the sapphire support substrate 310 is irradiated with a laser beam, the laser beam may pass through the optically transparent sapphire support substrate 310, the reinforcement layer 320, and the bonding layer 330, and due to the absorption in the group III nitride semiconductor seed layer 340, heat of about 900° C. is instantaneously generated, and thus the sapphire support substrate 310, the reinforcement layer 320, and the bonding layer 330 may be separated from the device active layer with a melting phenomenon. Therefore, there is an effect that the LLO process is possible without a design that introduces a separate LLO sacrificial layer between the sapphire support substrate 310 and the group III nitride semiconductor seed layer 340.

According to the method S900 of manufacturing the group III nitride semiconductor template according to the ninth embodiment of the present invention, which includes the first operation S910, the second operation S920, the third operation S930, the fourth operation S940, the fifth operation S950, the sixth operation S960, the seventh operation S970, the eighth operation S980, and the ninth operation S990, the stress caused by the differences in lattice constant (LC) and coefficient of thermal expansion (CTE) between the initial sapphire growth substrate G and the gallium nitride (GaN) materials can be significantly removed or relieved, and the compressive stress caused by the difference in coefficient of thermal expansion after the growth of the initial seed layer can also be completely removed or relieved after separating the sapphire growth substrate G, and thus it is possible to manufacture a flat group III nitride semiconductor template with almost no bowing phenomenon.

In addition, according to the present invention, when manufacturing a communication filter device, there is an effect of significantly improving the quality and thickness uniformity of an aluminum nitride (AlN) single crystalline with a thickness of about 1.5 μm.

Hereinafter, a method S1000 of manufacturing the group III nitride semiconductor template according to the tenth embodiment of the present invention will be described in detail with reference to the accompanying drawings.

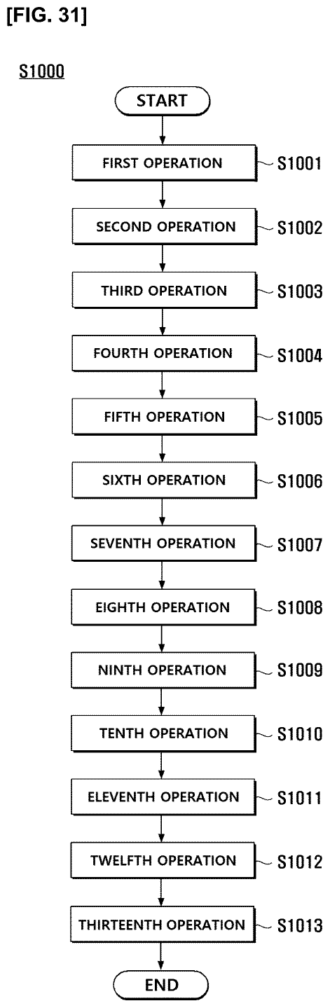

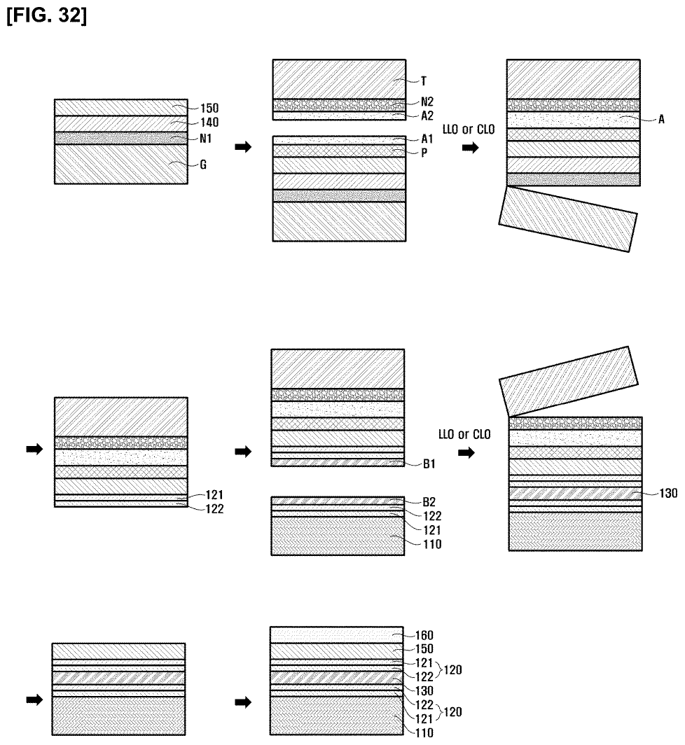

FIG. 31 is a flowchart of a method of manufacturing a group III nitride semiconductor template according to a tenth embodiment of the present invention, and FIG. 32 shows a process of manufacturing the group III nitride semiconductor template according to the tenth embodiment of the present invention.

As shown in FIGS. 31 and 32, the method S1000 of manufacturing the group III nitride semiconductor template according to the tenth embodiment of the present invention includes a first operation S1001, a second operation S1002, a third operation S1003, a fourth operation S1004, a fifth operation S1005, a sixth operation S1006, a seventh operation S1007, an eighth operation S1008, a ninth operation S1009, a tenth operation S1010, an eleventh operation S1011, a twelfth operation S1012, and a thirteenth operation S1013.

The first operation S1001 is an operation of preparing the growth substrate G, the temporary substrate T, and the support substrate 110.

When the growth substrate G is removed using an LLO process, the growth substrate G is an optically transparent and high-temperature heat-resistant substrate in which a laser beam (single-wavelength light) is 100% transmitted (theoretically) without absorption and preferably, is preferentially made of a material such as sapphire (α-phase Al2O3), ScMgAlO4, 4H-SiC, or 6H-SiC. In addition, the growth substrate G preferably has a protrusion shape patterned regularly or irregularly in various dimensions (size and shape) in microscale or nanoscale to minimize crystal defects inside the group III nitride semiconductor thin film grown thereon.

In addition, when the growth substrate G is removed using a chemical lift off (CLO) process, the growth substrate G may be removed by wet etching and is provided as a silicon (Si) growth substrate G that allows mechanical polishing and selective etching, and it is preferable that the silicon (Si) growth substrate G be made of silicon (Si) with a (111) crystal face so that a high-quality group III nitride semiconductor thin film may be grown.

When the temporary substrate T is removed using an LLO process, the temporary substrate T is made of an optically transparent material which has a coefficient of thermal expansion (CTE) that is equal to or similar to that of the support substrate 110 and at the same time, in which a laser beam (single wavelength light) may be 100% transmitted (theoretically) without absorption in the LLO process to be described below, and is preferably formed so that the difference in coefficient of thermal expansion with the support substrate 110 does not exceed a maximum difference of 2 ppm. Sapphire is preferable as the temporary substrate T material that satisfies the above, and silicon carbide (SiC) or glass whose coefficient of thermal expansion (CTE) is adjusted to have a difference of 2 ppm or less from the support substrate 110 may be contained.

In addition, when the temporary substrate T is removed using the CLO process to be described below, the temporary substrate T may be removed by wet etching, and is provided as a silicon (Si) substrate to minimize the difference in coefficient of thermal expansion (CTE) with the support substrate 110, and since the temporary substrate T is a substrate temporarily bonded in the manufacturing process, the temporary substrate T is preferably provided as a low-cost silicon (Si) substrate to secure cost competitiveness.

The support substrate 110 is a substrate that supports the channel layer 150 and the re-growth layer 160 after undergoing each operation of the method S1000 of manufacturing the group III nitride semiconductor template according to the tenth embodiment of the present invention.

The support substrate 110 may be provided as a sapphire support substrate 110 or provided as a silicon (Si) support substrate 110 with high heat dissipation performance. The silicon (Si) support substrate 110 may be single-crystalline, polycrystalline, or amorphous and made of silicon (Si) with a (111) crystal face, a (110) crystal face, or a (100) crystal face. Furthermore, in addition to the above-described silicon (Si) and sapphire, the support substrate 110 may include at least one material selected from materials including silicon carbide (SiC), silicon (Si), and aluminum nitride (AlN). In particular, silicon carbide (SiC) and aluminum nitride (AlN) may be single-crystalline or polycrystalline.

The second operation S1002 is an operation of forming a first sacrificial layer N1 on the growth substrate G and then growing a high-quality group III nitride semiconductor layer (including a group III nitride semiconductor buffer layer and a channel layer) on the first sacrificial layer N1 in a single layer or multiple layers and specifically, is an operation of growing a first high-quality buffer layer 140 on the first sacrificial layer N1 in a single layer or multiple layers and growing a high-quality channel layer 150 on the first buffer layer 140 in a single layer or multiple layers.

When the growth substrate G is removed using an LLO process, the first sacrificial layer N1 is a layer required for growing a high-quality group III nitride semiconductor layer (including a buffer layer and a channel layer) and is made of a material capable of sacrificial separation by a thermo-chemical decomposition reaction caused by a laser beam, and for example, the sapphire growth substrate G may contain indium gallium nitride (InGaN), gallium nitride (GaN), aluminum gallium nitride (AlGaN), and indium aluminum nitride (InAlN), and the silicon carbide (SiC) growth substrate G may contain indium gallium nitride (InGaN) and indium aluminum nitride (InAlN). The first sacrificial layer N1 is grown directly on the initial growth substrate G to minimize crystal defects in the group III nitride semiconductor layer and serves as a buffer layer.

In this case, a single layer or multiple layers made of a high-quality group III nitride, which is a highly electrical resistive insulator, as a layer other than the first high-quality buffer layer 140 and the high-quality channel layer 150 may be deposited (grown) on the first sacrificial layer N1.

In addition, the group III nitride semiconductor layer (including the group III nitride semiconductor buffer layer and channel layer, that is, the first buffer layer 140 and the channel layer 150) may be formed of a single layer or multiple layers of group III nitride semiconductors and may be made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), indium aluminum nitride (InAlN), gallium nitride/indium aluminum nitride (GaN/InAlN), aluminum scandium nitride (AlScN), gallium nitride/aluminum scandium nitride (GaN/AlScN), etc., which have high-temperature (HT) and high-resistance (HR) characteristics. The group III nitride semiconductor layer is a critical quality factor in reducing fatal crystal defects, that is, the density of threading dislocations (present in a vertical direction with respect to the initial growth substrate G) (≤ Low 108/cm2).

Meanwhile, since the surface of the first buffer layer 140 or the channel layer 150 formed on the growth substrate G and the surface of the first buffer layer 140 or the channel layer 150 transferred onto the temporary substrate T are inverted, a total thickness variation (TTV) should be minimized, the surface roughness should be minimized (RMS <1 nm), and foreign substances (particles) such as an organic substance and a metallic substance should be minimized after growth so that a predetermined preferred surface of the first buffer layer 140 or the channel layer 150 may be formed, and as a growth process that can achieve the above, both processes through MOCVD and molecular beam epitaxy (MBE) devices are possible, but the growth process is preferably performed through a process with a relatively low growth temperature. For example, in the case of a gallium nitride (GaN) semiconductor channel layer, a gallium polarity (Ga-polarity) or nitrogen polarity (N-polarity) surface may be selectively adjusted according to the surface treatment and growth conditions of the growth substrate G. Typically, when the group III nitride semiconductor channel layer 150 is grown on the sapphire growth substrate G in a MOCVD chamber, while the group III nitride semiconductor channel layer 150 has a surface with a metal (M: Ga, Al, In) polarity with 3 valence electrons, an interface in direct contact with the sapphire growth substrate G has a nitrogen polarity with 5 valence electrons.

Meanwhile, when the growth substrate G is removed using a CLO process, the first sacrificial layer N1 is a layer required to grow a high-quality group III nitride semiconductor layer and includes a melt-back etching prevention layer and a crack prevention layer.

The melt-back etching prevention layer is formed on the growth substrate G in a thickness of less than 500 nm and formed by containing aluminum nitride (AlN). The melt-back etching prevention layer serves as a buffer layer so that the group III nitride semiconductor layer (including the group III nitride semiconductor buffer layer and channel layer, that is, the first buffer layer 140 and the channel layer 150) may be grown directly on the silicon (Si) growth substrate G having a (111) crystal face, minimizes crystal defects in the group III nitride semiconductor layer, and serves to prevent Ga—Si chemical interface reactions with the surface of the silicon growth substrate during the growth of gallium nitride (GaN) materials.

The crack prevention layer is formed on the melt-back etching prevention layer in a thickness of less than 1 μm and formed by including aluminum gallium nitride (AlGaN). The crack prevention layer is a layer introduced to prevent cracks when cooling to room temperature after growth by artificially introducing compressive stress into the high-quality group III nitride semiconductor layer and may be omitted in some cases.

In addition, the group III nitride semiconductor layer (including the group III nitride semiconductor buffer layer and channel layer, that is, the first buffer layer 140 and the channel layer 150) may be formed of a single layer or multiple layers of group III nitride semiconductors and made of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), indium aluminum nitride (InAlN), gallium nitride/indium aluminum nitride (GaN/InAlN), aluminum scandium nitride (AlScN), gallium nitride/aluminum scandium nitride (GaN/AlScN), etc., which have high-temperature (HT) and high-resistance (HR) characteristics. The group III nitride semiconductor layer is a critical quality factor in reducing fatal crystal defects, that is, the density of threading dislocations (present in a vertical direction with respect to the initial growth substrate G) (≤Low 108/cm2).

Meanwhile, since the surface of the first buffer layer 140 or the channel layer 150 formed on the growth substrate G and the surface of the first buffer layer 140 or the channel layer 150 transferred onto the temporary substrate T are inverted, a total thickness variation (TTV) should be minimized, the surface roughness should be minimized (RMS <1 nm), and foreign substances (particles) such as an organic substance and a metallic substance should be minimized after growth so that a predetermined preferred surface of the first buffer layer 140 or the channel layer 150 may be formed, and as a growth process that can achieve the above, both processes through MOCVD and molecular beam epitaxy (MBE) devices are possible, but the growth process is preferably performed through a process with a relatively low growth temperature.

The third operation S1003 is an operation of forming an epitaxy protection layer P on the channel layer 150 and then forming a first adhesive layer A1 on the epitaxy protection layer P.

Here, the epitaxy protection layer P is a layer for preventing the channel layer 150 from being damaged during a subsequent process and may be made of a material in consideration of selective wet etching, and the epitaxy protection layer P may preferentially contain, for example, an oxide including silicon oxide (SiO2), a nitride including silicon nitride (SiNx), etc. and contain a metal, an alloy, etc.

The fourth operation S1004 is an operation of forming a second sacrificial layer N2 on the temporary substrate T and then forming an second adhesive layer A2 on the second sacrificial layer N2.

When the temporary substrate T is removed using an LLO process, the optically transparent temporary substrate T is a substrate that may be finally easily separated by the LLO technique in the subsequent process, and the second sacrificial layer N2 may be deposited on the temporary substrate T before forming the second adhesive layer A2, and the second sacrificial layer N2 material may contain an oxide, a nitride, etc. that may be formed by a PVD technique such as a sputtering, PLD, or evaporator technique, specifically, contain a material such as indium tin oxide (ITO), gallium oxide (GaOx), gallium oxide nitride (GaON), gallium nitride (GaN), indium gallium nitride (InGaN), tin oxide (ZnO), indium gallium tin oxide (InGaZnO), or indium tin oxide (InZnO),

In addition, the first adhesive layer A1 and the second adhesive layer A2 may contain a material such as silicon oxide (SiO2), SOG, a flowable oxide (FOx), silicon nitride (SiNx), aluminum oxide (Al2O3), aluminum nitride (AlN), and silicon carbon nitride (SiCN) as a dielectric material capable of direct bonding at a temperature of 100° C. or lower and contain materials such as resin, BCB, and PI as an organic adhesive capable of indirect bonding at a temperature of 100° C. or lower.

In addition, when the temporary substrate T is removed using a CLO process, the temporary substrate T is a substrate that may be finally easily separated by the CLO technique in the subsequent process, and the second sacrificial layer N2 may be deposited on the temporary substrate T before forming the second adhesive layer A2, and the second sacrificial layer N2 includes, more specifically, an adhesive reinforcement layer and an etch stop layer.

The adhesive reinforcement layer is a layer that reinforces adhesion with the temporary substrate T and may contain materials such as silicon oxide (SiO2), silicon nitride (SiNx), a metal, and an alloy.

The etch stop layer is a layer that protects the adhesive layer, the epitaxy protection layer, etc. from being affected by chemical etching during wet etching, and in the subsequent CLO process, wet etching is performed using a tetramethylammonium hydroxide (TMAH) or hydrofluoric+nitric+acetic acids (HNA) solution to completely remove the remaining thin silicon (Si) after mechanically grinding and polishing the silicon (Si) temporary substrate T, and in this case, the etch stop layer serves to protect the adhesive layer, the epitaxy protection layer, etc. from being affected by chemical etching after the silicon (Si) is completely removed, and in some cases, the etch stop layer may be omitted.

In addition, the first adhesive layer A1 and the second adhesive layer A2 may contain a material such as silicon oxide (SiO2), SOG, a flowable oxide (FOx), silicon nitride (SiNx), aluminum oxide (Al2O3), aluminum nitride (AlN), and silicon carbon nitride (SiCN) as a dielectric material capable of direct bonding at a temperature of 100° C. or lower and contain materials such as resin, BCB, and PI as an organic adhesive capable of indirect bonding at a temperature of 100° C. or lower.

The fifth operation S1005 is an operation of forming an adhesive layer A by bonding the first adhesive layer A1 and the second adhesive layer A2. That is, the fifth operation S1005 is an operation of turning over the temporary substrate T on which the second adhesive layer A2 has been formed and pressing and bonding the same to the growth substrate G on which the first adhesive layer A1 has been formed at a temperature of lower than 300° C.

Typically, although the epitaxy wafer is in a bowing state in a concave shape due to the thermo-mechanical tensile stress caused by the differences in lattice constant (LC) and coefficient of thermal expansion (CTE) between the growth substrate G and the group III nitride semiconductor, in the present invention, such a problem can be solved by strongly bonding a temporary substrate T identical to the growth substrate G to the upper surface of the grown group III nitride semiconductor epitaxy wafer through the adhesive layer. In this case, since the coefficient of thermal expansion (CTE) values of the initial growth substrate G and the temporary substrate T are almost the same, it is preferable to perform the bonding process to have strong bonding strength regardless of temperature.

The sixth operation is an operation of separating the growth substrate G from the first sacrificial layer N1 using an LLO or CLO technique.

When the growth substrate G is removed using an LLO process, the epitaxy-grown layer is separated from the growth substrate G by irradiating a back surface of the transparent growth substrate G with an ultraviolet (UV) laser beam having a uniform optical output and beam profile, and a single wavelength. When the initial growth substrate G is separated, the inside of the group III nitride semiconductor channel layer 150 transferred onto the temporary substrate T is in a state in which the stress has been completely relieved and maintains a flat state together with the temporary substrate T. Then, it is preferable that a region damaged due to the separation of the growth substrate G, contaminated surface residue, and low-quality single crystalline thin film region be removed as completely as possible.

In addition, when the growth substrate G is removed using a CLO process, the silicon (Si) material of the initial growth substrate G is separated and removed by performing wet etching using a TMAH or HNA solution to completely remove the remaining thin silicon (Si) after mechanically grinding and polishing the back surface of the silicon (Si) growth substrate G with a (111) crystal face. When the initial growth substrate G is separated, the inside of the channel layer 150 transferred onto the temporary substrate T is in a state in which the stress has been completely relieved and maintains a flat state together with the temporary substrate T. Meanwhile, before removing the residual silicon (Si) material after mechanically polishing the growth substrate G, it is preferable to protect the temporary substrate from the etching solution by depositing a protective film such as silicon oxide (SiO2) or silicon nitride (SiNx) on a back surface of the temporary substrate T.

The seventh operation S1007 is an operation of exposing the channel layer 150 by etching and removing the first sacrificial layer N1 and the first buffer layer 140. The lower surface of the channel layer 150 from which the first sacrificial layer N1 and the first buffer layer 140 have been removed is a nitrogen polarity surface, and for bonding with the final support substrate 110, it is very important to ensure that the lower surface of the channel layer 150 exposed to the air has a surface in a particle-zero (0) state with residues completely removed.

Meanwhile, in some cases, it is preferable to introduce a regular or irregular patterning process to the channel layer 150 to increase the bonding strength with the final support substrate 110 in the subsequent process, and in some cases, it is also preferable to introduce a CMP process to increase the contact area with the final support substrate 110 in the subsequent process.

The eighth operation S1008 is an operation of forming a first bonding layer B1 on the channel layer 150, and in some cases, after a reinforcement layer 120 identical to that in the ninth operation S1009, which will be described below, is formed on the channel layer 150, the first bonding layer B1 may be formed on the reinforcement layer 120.

The ninth operation S1009 is an operation of forming a second bonding layer B2 on the support substrate 110, and in some cases, after the reinforcement layer 120 is formed on the support substrate 110, the second bonding layer B2 may be formed on the reinforcement layer 120.

Here, the reinforcement layer 120 includes, more specifically, a bonding reinforcement layer 121 and a compressive stress layer 122.

The bonding reinforcement layer 121 is a layer introduced to reinforce bonding strength when the channel layer 150 is bonded to the final support substrate 110 through the bonding layer 130, and it is preferable to preferentially select a material constituting the bonding reinforcement layer 121 from silicon oxide (SiO2), silicon nitride (SiNx), etc.

The compressive stress layer 122 is a layer that induces compressive stress and is made of a dielectric material with a value larger than the coefficient of thermal expansion of the final support substrate 110, such as aluminum nitride (AlN, 4.6 ppm), aluminum nitride oxide (AlNO, 4.6 to 6.8 ppm), aluminum oxide (Al2O3, 6.8 ppm), silicon carbide (SiC, 4.8 ppm), silicon carbide nitride (SiCN, 3.8 to 4.8 ppm), gallium nitride (GaN, 5.6 ppm), gallium nitride oxide (GaNO, 5.6 to 6.8 ppm), which relieves tensile stress, that is, induces compressive stress, which serves to induce the quality improvement of products through stress control.

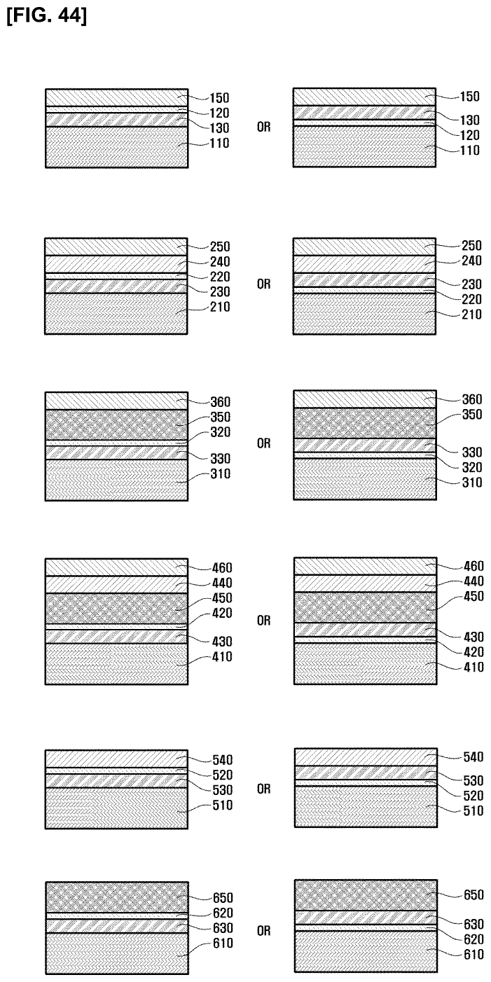

FIG. 44 shows a reinforcement layer differently disposed on the group III nitride semiconductor template according to the tenth embodiment to the fifteenth embodiment of the present invention.

Meanwhile, as shown in FIG. 44, in the present invention, the bonding reinforcement layer 121 or the compressive stress layer 122 may be omitted in some cases, and in some cases, the entire reinforcement layer 120 may be omitted so that the support substrate 110 may be in direct contact with the bonding layer 130 (or, in the eighth operation S1008, the channel layer 150 may be in direct contact with the bonding layer 130). This case may be a structure that induces compressive stress together with a bonding function by depositing a material with a larger coefficient of thermal expansion than the silicon (Si) support substrate 110 on the bonding layer 130.

In addition, the first bonding layer B1 and the second bonding layer B2 are each preferentially selected from dielectric materials whose properties do not change in the MOCVD chamber (at a temperature of 1000° C. or higher and in a reducing atmosphere) that the group III nitride semiconductor is grown, may contain, for example, silicon oxide (SiO2, 0.8 ppm), silicon nitride (SiNx, 3.8 ppm), silicon carbon nitride (SiCN, 3.8 to 4.8 ppm), aluminum nitride (AlN, 4.6 ppm), aluminum oxide (Al2O3, 6.8 ppm), and furthermore, may contain a flowable oxide (FOx) such as SOG (liquid SiO2) or HSQ to improve surface roughness.

The tenth operation S1010 is an operation of forming the bonding layer 130 by bonding the first bonding layer B1 and the second bonding layer B2 to separate the temporary substrate T. That is, the tenth operation S1010 is an operation of turning over the channel layer 150 on which the first bonding layer B1 has been formed (deposited) and the temporary substrate T and pressing and bonding the same to the support substrate 110 on which the second bonding layer B2 has been formed at a temperature of lower than 300° C.

Conventionally, although epitaxy wafer bowing occurs due to thermo-mechanical induced stress caused by the differences in lattice constant (LC) and coefficient of thermal expansion (CTE) between the initial growth substrate G and the group III nitride semiconductor, the epitaxy wafer bonded to the temporary substrate T of the present invention is in a stress-relieved state, and thus the wafer bowing can be minimized to almost zero (0). In this case, it is possible to minimize stress by setting a bonding process temperature to about room temperature and performing the process, thereby further minimizing wafer bowing.

The eleventh operation S1011 is an operation of separating the temporary substrate T from the second sacrificial layer N2 using an LLO technique or CLO technique.

When the temporary substrate T is removed using an LLO process, the epitaxy-grown layer is separated from the temporary substrate T by irradiating a back surface of the temporary substrate T with an ultraviolet (UV) laser beam having a uniform optical output and beam profile, and a single wavelength. When the temporary substrate T is separated, the inside of the group III nitride semiconductor channel layer 150 transferred onto the support substrate 110 is in a state in which the stress has been completely relieved and maintains a flat state together with the support substrate 110. Then, it is preferable that a region damaged due to the separation of the temporary substrate T, contaminated surface residue, and low-quality single crystalline thin film region be removed as completely as possible.

In addition, when the temporary substrate T is removed using a CLO process, the silicon (Si) material of the temporary substrate T is separated and removed by performing wet etching using a TMAH or HNA solution to completely remove the remaining thin silicon (Si) after mechanically grinding and polishing the back surface of the silicon (Si) temporary substrate T. Meanwhile, before removing the residual silicon (Si) material after mechanically grinding and polishing the temporary substrate T, it is preferable to protect the temporary substrate T from the etching solution by depositing a protective film such as silicon oxide (SiO2) or silicon nitride (SiNx) on the back surface of the temporary substrate T. Meanwhile, before removing the residual silicon (Si) material after mechanically grinding and polishing the temporary substrate T, it is preferable to protect the temporary substrate T from the etching solution by depositing a protective film such as silicon oxide (SiO2) or silicon nitride (SiNx) on a back surface of the support substrate 110.

The twelfth operation S1012 is an operation of etching and removing the second sacrificial layer N2, the adhesive layer A, and the epitaxy protection layer P. Here, the second sacrificial layer N2, the adhesive layer A, and the epitaxy protection layer P may be formed through dry etching and wet etching. Then, the residue on the surface of the contaminated channel layer 150 may be removed, and as needed, it is preferable to perform an annealing process at a high temperature of 400° C. or higher to reinforce the bonding strength of the permanent bonding layer 130.

The thirteenth operation S1013 is an operation of re-growing a high-quality re-growth layer 160 on the channel layer 150. In this case, the re-grown re-growth layer 160 may be an aluminum gallium nitride (AlGaN) barrier layer, but is not limited thereto, and a power semiconductor device structure, a semiconductor light-emitting device structure, a communication filter structure, etc. may be re-grown.

For example, in the power semiconductor device structure, each layer suitable for a typical HEMT structure may be re-grown and may have a structure including a channel layer of gallium nitride (GaN) or indium aluminum nitride (InAlN), a barrier layer of aluminum gallium nitride (AlGaN), aluminum scandium nitride (AlScN), or indium aluminum nitride (InAlN), an injection layer of p-type gallium nitride (pGaN), p-type aluminum gallium nitride (pAlGaN), or p-type aluminum gallium indium nitride (pAlGaInN), a passivation layer of silicon nitride (SiNx) or aluminum nitride (AlN), etc.

In addition, in the semiconductor light-emitting device structure such as a micro LED, stress relief and temperature gradients can be improved when an InGaN-based active layer (MQWs) is grown, and the uniformity of the composition ratio of ternary or quaternary alloys (In, Ga, Al) and the doping amount of dopant (Si, Mg) can be improved, thereby significantly improving wavelength dispersion in the wafer, and the photoelectric characteristics and uniformity, and as a result, ultraviolet, blue, green, and red micro LED device structures in which the photoelectric characteristics and uniformity can be significantly improved may be re-grown.

In addition, in the communication filter structure, a communication filter structure that can significantly improve the quality and thickness uniformity of an aluminum nitride (AlN) single crystal with a thickness of about 1.5 μm may be re-grown.

The above-described group III nitride semiconductor template manufactured by the method S1000 of manufacturing the group III nitride semiconductor template according to the tenth embodiment of the present invention may have a structure in which the support substrate 110, the reinforcement layer 120, the bonding layer 130, the reinforcement layer 120, the channel layer 150, and the re-growth layer 160 are sequentially stacked.

Hereinafter, a method S1100 of manufacturing the group III nitride semiconductor template according to the eleventh embodiment of the present invention will be described in detail with reference to the accompanying drawings.

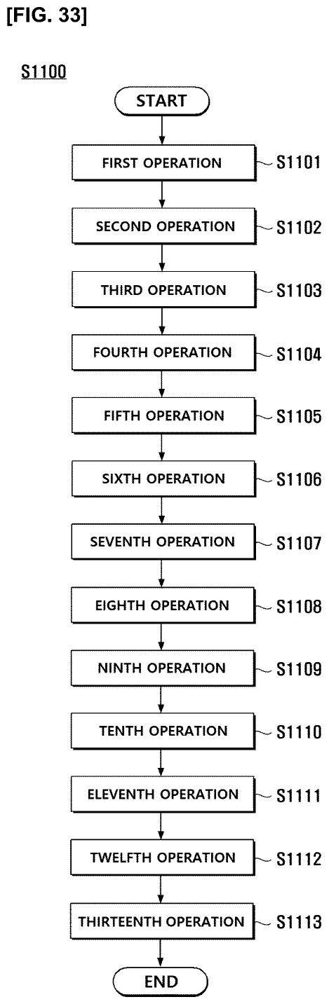

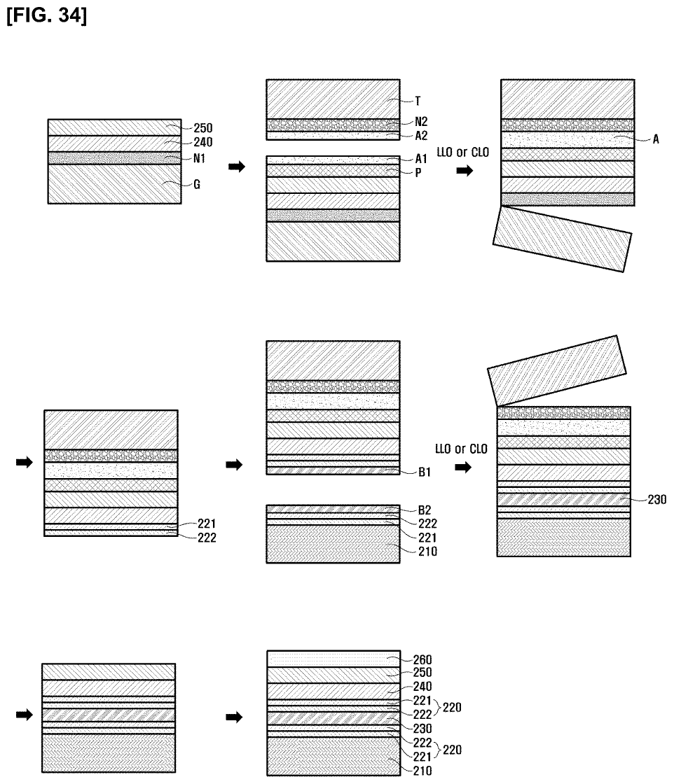

FIG. 33 is a flowchart of a method of manufacturing a group III nitride semiconductor template according to an eleventh embodiment of the present invention, and FIG. 34 shows a process of manufacturing the group III nitride semiconductor template according to the eleventh embodiment of the present invention.

As shown in FIGS. 33 and 34, the method S1100 of manufacturing the group III nitride semiconductor template according to the eleventh embodiment of the present invention includes a first operation S1101, a second operation S1102, a third operation S1103, a fourth operation S1104, a fifth operation S1105, a sixth operation S1106, a seventh operation S1107, an eighth operation S1108, a ninth operation S1109, a tenth operation S1110, an eleventh operation S1111, a twelfth operation S1112, and a thirteenth operation S1113.

The first operation S1101 is an operation of preparing the growth substrate G, the temporary substrate T, and the support substrate 210.

Since the following descriptions of the first operation S1101 to the sixth operation S1106 are the same as those of the method S1000 of manufacturing the group III nitride semiconductor template according to the tenth embodiment of the present invention, overlapping descriptions thereof will be omitted.

The seventh operation S1107 is an operation of exposing the first buffer layer 240 by etching and removing the first sacrificial layer N1. A lower surface of the first buffer layer 240 from which the first sacrificial layer N1 has been removed is a nitrogen polarity surface, and for bonding with the final support substrate 210, it is very important to ensure that the lower surface of the first buffer layer 240 exposed to air has a surface in a particle-zero (0) state with residues completely removed.

Meanwhile, in some cases, it is preferable to introduce a regular or irregular patterning process to the first buffer layer 240 to increase the bonding strength with the final support substrate 210 in the subsequent process, and in some cases, it is also preferable to introduce a CMP process to increase the contact area with the final support substrate 210 in the subsequent process.

The eighth operation S1108 is an operation of forming a first bonding layer B1 on the first buffer layer 240, and in some cases, after a reinforcement layer 220 identical to that in the ninth operation S1109, which will be described below, is formed on the first buffer layer 240, the first bonding layer B1 may be formed on the reinforcement layer 220.

The ninth operation S1109 is an operation of forming a second bonding layer B2 on the support substrate 210, and in some cases, after the reinforcement layer 220 is formed on the support substrate 210, the second bonding layer B2 may be formed on the reinforcement layer 220. Here, the reinforcement layer 220 includes, more specifically, a bonding reinforcement layer 221 and a compressive stress layer 222.

Meanwhile, as shown in FIG. 44, in the present invention, the bonding reinforcement layer 221 or the compressive stress layer 222 may be omitted in some cases, and in some cases, the entire reinforcement layer 220 may be omitted so that the support substrate 210 may be in direct contact with the bonding layer 230 (or, in the eighth operation S1108, the first buffer layer 240 may be in direct contact with the bonding layer 230). This case may be a structure that induces compressive stress together with a bonding function by depositing a material with a larger coefficient of thermal expansion than the silicon (Si) support substrate 210 on the bonding layer 230.

The tenth operation S1110 is an operation of forming the bonding layer 230 by bonding the first bonding layer B1 and the second bonding layer B2 to separate the temporary substrate T. That is, the tenth operation S1110 is an operation of turning over the first buffer layer 240 on which the first bonding layer B1 has been formed (deposited) and the temporary substrate T and pressing and bonding the same to the support substrate 210 on which the second bonding layer B2 has been formed at a temperature of lower than 300° C.

Since the following descriptions of the eleventh operation S1111 to the thirteenth operation S1113 are the same as those of the method S1000 of manufacturing a group III nitride semiconductor template according to the tenth embodiment of the present invention, overlapping descriptions thereof will be omitted.

The above-described group III nitride semiconductor template manufactured by the method S1100 of manufacturing the group III nitride semiconductor template according to the eleventh embodiment of the present invention may have a structure in which the support substrate 210, the reinforcement layer 220, the bonding layer 230, the reinforcement layer 220, the first buffer layer 240, the channel layer 250, and the re-growth layer 260 are sequentially stacked.

Hereinafter, a method S1200 of manufacturing the group III nitride semiconductor template according to the twelfth embodiment of the present invention will be described in detail with reference to the accompanying drawings.

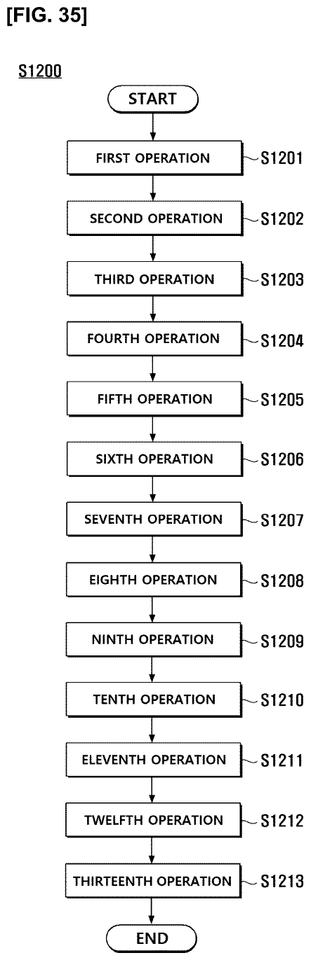

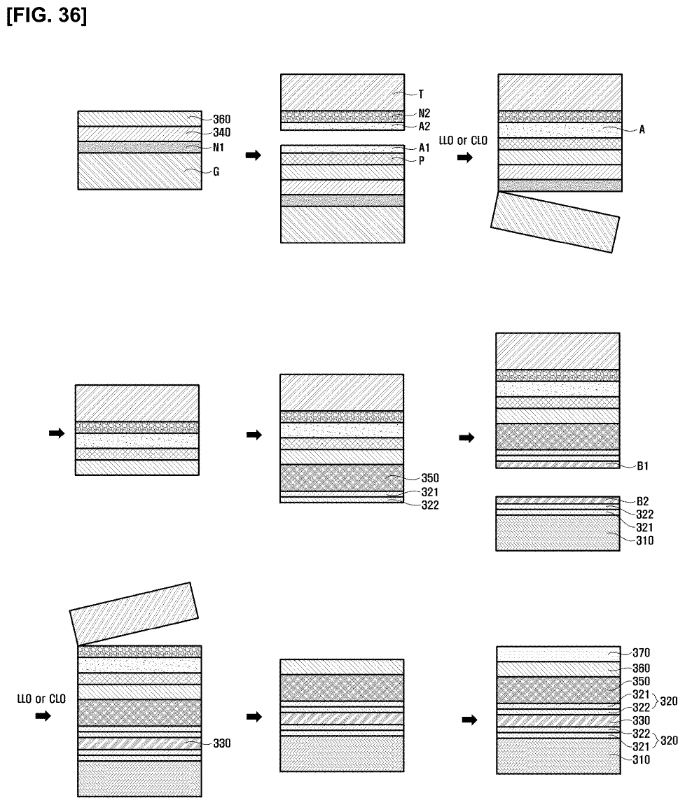

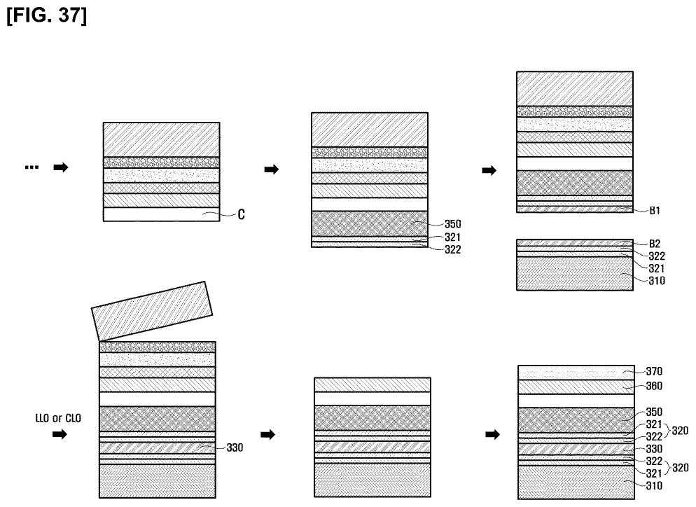

FIG. 35 is a flowchart of a method of manufacturing a group III nitride semiconductor template according to a twelfth embodiment of the present invention, FIG. 36 shows a process of manufacturing the group III nitride semiconductor template according to the twelfth embodiment of the present invention, and FIG. 37 shows another process of manufacturing the group III nitride semiconductor template according to the twelfth embodiment of the present invention.

As shown in FIGS. 35 to 37, the method S1200 of manufacturing the group III nitride semiconductor template according to the twelfth embodiment of the present invention includes a first operation S1201, a second operation S1202, a third operation S1203, a fourth operation S1204, a fifth operation S1205, a sixth operation S1206, a seventh operation S1207, an eighth operation S1208, a ninth operation S1209, a tenth operation S1210, an eleventh operation S1211, a twelfth operation S1212, and a thirteenth operation S1213.

The first operation S1301 is an operation of preparing the growth substrate G, the temporary substrate T, and the support substrate 310.

Since the following descriptions of the first operation S1201 to the sixth operation S1206 are the same as those of the method S1000 of manufacturing the group III nitride semiconductor template according to the tenth embodiment of the present invention, overlapping descriptions thereof will be omitted.

The seventh operation S1207 is an operation of exposing the channel layer 360 by etching and removing the first sacrificial layer N1 and the first buffer layer 340. The lower surface of the channel layer 360 from which the first sacrificial layer N1 and the first buffer layer 340 have been removed is a nitrogen polarity surface, and for bonding with the final support substrate 210, it is very important to ensure that the lower surface of the channel layer 360 exposed to the air has a particle-zero (0) state surface with residues completely removed.

Meanwhile, in some cases, it is preferable to introduce a regular or irregular patterning process to the channel layer 360 to increase the bonding strength with the final support substrate 210 in the subsequent process, and in some cases, it is also preferable to introduce a CMP process to increase the contact area with the final support substrate 210 in the subsequent process.

The eighth operation S1208 is an operation of depositing a new second buffer layer 350 on a surface of the channel layer 360 with a nitrogen polarity and forming a first bonding layer B1 on the second buffer layer 350. Here, the newly formed second buffer layer 350 may be made of a material such as aluminum (Al)-containing nitride or oxide (AlN, AlNO, Al2O3) with high resistance characteristics for a leakage current without separate doping such as iron (Fe) or carbon (C), and in some cases, after a reinforcement layer 320 identical to that in the ninth operation S1209, which will be described below, is formed on the second buffer layer 350, the first bonding layer B1 may be formed on the reinforcement layer 320.

Meanwhile, when the aluminum nitride (AlN) material-based second buffer layer 350 is directly deposited on the gallium nitride (GaN) material-based channel layer 360, cracks may occur due to the differences in lattice constant (LC) and coefficient of thermal expansion (CTE) between the channel layer 360 and the second buffer layer 350. Therefore, as shown in FIG. 37, the eighth operation S308 may form a crack suppression layer C that provides compressive stress to suppress cracking on the channel layer 360 and then deposit the second buffer layer 350 on the crack suppression layer C.

The ninth operation S1209 is an operation of forming a second bonding layer B2 on the support substrate 310, and in some cases, after the reinforcement layer 320 is formed on the support substrate 310, the second bonding layer B2 may be formed on the reinforcement layer 320. Here, the reinforcement layer 320 includes, more specifically, a bonding reinforcement layer 321 and a compressive stress layer 322.

Meanwhile, as shown in FIG. 44, in the present invention, the bonding reinforcement layer 321 or the compressive stress layer 322 may be omitted in some cases, and in some cases, the entire reinforcement layer 320 may be omitted so that the support substrate 310 may be in direct contact with the bonding layer 330 (or, in the eighth operation S1208, the second buffer layer 350 may be in direct contact with the bonding layer 330). This case may be a structure that induces compressive stress together with a bonding function by depositing a material with a larger coefficient of thermal expansion than the silicon (Si) support substrate 310 on the bonding layer 330.

The tenth operation S1210 is an operation of forming the bonding layer 330 by bonding the first bonding layer B1 and the second bonding layer B2 to separate the temporary substrate T. That is, the tenth operation S1210 is an operation of turning over the second buffer layer 350 on which the first bonding layer B1 has been formed (deposited) and the temporary substrate T and pressing and bonding the same to the support substrate 310 on which the second bonding layer B2 has been formed at a temperature of lower than 300° C.

Since the following descriptions of the eleventh operation S1211 to the thirteenth operation S1213 are the same as those of the method S1000 of manufacturing a group III nitride semiconductor template according to the tenth embodiment of the present invention, overlapping descriptions thereof will be omitted.

The above-described group III nitride semiconductor template manufactured by the method S1200 of manufacturing the group III nitride semiconductor template according to the twelfth embodiment of the present invention may have a structure in which the support substrate 310, the reinforcement layer 320, the bonding layer 330, the reinforcement layer 320, the second buffer layer 350, the channel layer 360, and the re-growth layer 370 are sequentially stacked.

Hereinafter, a method S1300 of manufacturing the group III nitride semiconductor template according to the thirteenth embodiment of the present invention will be described in detail with reference to the accompanying drawings.

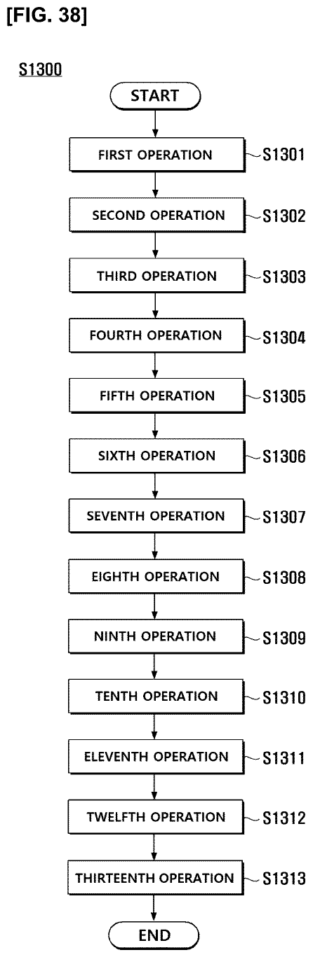

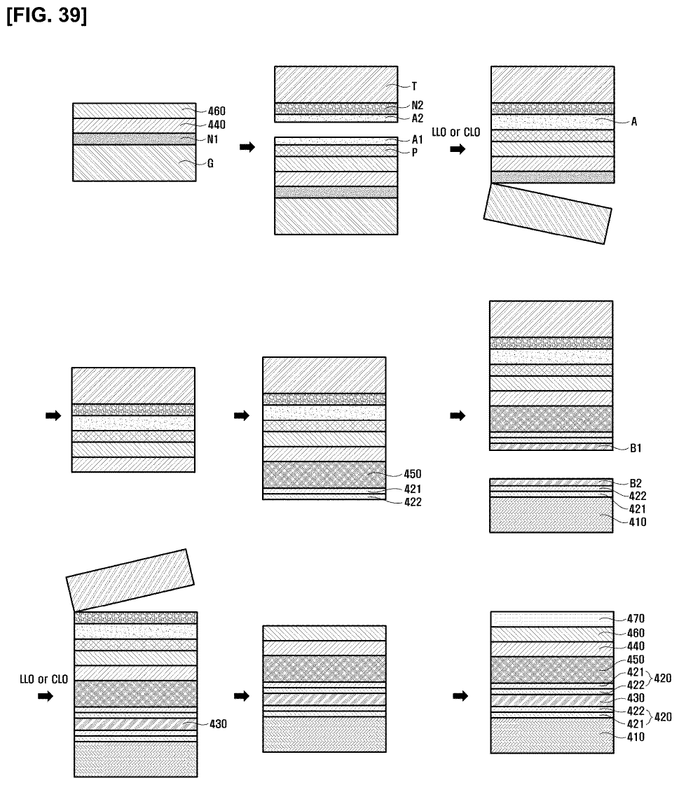

FIG. 38 is a flowchart of a method of manufacturing a group III nitride semiconductor template according to a thirteenth embodiment of the present invention, and FIG. 39 shows a process of manufacturing the group III nitride semiconductor template according to the thirteenth embodiment of the present invention.

As shown in FIGS. 38 and 39, the method S1300 of manufacturing the group III nitride semiconductor template according to the thirteenth embodiment of the present invention includes a first operation S1301, a second operation S1302, a third operation S1303, a fourth operation S1304, a fifth operation S1305, a sixth operation S1306, a seventh operation S1307, an eighth operation S1308, a ninth operation S1309, a tenth operation S1310, an eleventh operation S1311, a twelfth operation S1312, and a thirteenth operation S1313.

The first operation S1301 is an operation of preparing the growth substrate G, the temporary substrate T, and the support substrate 410.

Since the following descriptions of the first operation S1301 to the sixth operation S1306 are the same as those of the method S1000 of manufacturing the group III nitride semiconductor template according to the tenth embodiment of the present invention, overlapping descriptions thereof will be omitted.

The seventh operation S1307 is an operation of exposing the first buffer layer 440 by etching and removing the first sacrificial layer N1. A lower surface of the first buffer layer 440 from which the first sacrificial layer N1 has been removed is a nitrogen polarity surface, and it is very important to ensure that the lower surface of the first buffer layer 440 exposed to the air has a surface in a particle-zero (0) state with residues completely removed.

Meanwhile, in some cases, it is preferable to introduce a regular or irregular patterning process to the first buffer layer 440 to increase bonding strength in the subsequent process, and in some cases, it is also preferable to introduce a CMP process to increase a contact area in the subsequent process.

The eighth operation S1308 is an operation of depositing a new second buffer layer 450 on a surface of the first buffer layer 440 with a nitrogen polarity and forming a first bonding layer B1 on the second buffer layer 450. Here, the newly formed second buffer layer 450 may be made of a material such as aluminum (Al)-containing nitride or oxide (AlN, AlNO, Al2O3) with high resistance characteristics for a leakage current without separate doping such as iron (Fe) or carbon (C), and in some cases, after a reinforcement layer 420 identical to that in the ninth operation S1309, which will be described below, is formed on the second buffer layer 450, the first bonding layer B1 may be formed on the reinforcement layer 420.

The ninth operation S1309 is an operation of forming a second bonding layer B2 on the support substrate 410, and in some cases, after the reinforcement layer 420 is formed on the support substrate 410, the second bonding layer B2 may be formed on the reinforcement layer 420. Here, the reinforcement layer 420 includes, more specifically, a bonding reinforcement layer 421 and a compressive stress layer 422.

Meanwhile, as shown in FIG. 44, in the present invention, the bonding reinforcement layer 421 or the compressive stress layer 422 may be omitted in some cases, and in some cases, the entire reinforcement layer 420 may be omitted so that the support substrate 410 may be in direct contact with the bonding layer 430 (or, in the eighth operation S1308, the second buffer layer 450 may be in direct contact with the bonding layer 430). This case may be a structure that induces compressive stress together with a bonding function by depositing a material with a larger coefficient of thermal expansion than the silicon (Si) support substrate 410 on the bonding layer 430.

The tenth operation S1310 is an operation of forming the bonding layer 430 by bonding the first bonding layer B1 and the second bonding layer B2 to separate the temporary substrate T. That is, the tenth operation S1310 is an operation of turning over the second buffer layer 450 on which the first bonding layer B1 has been formed (deposited) and the temporary substrate T and pressing and bonding the same to the support substrate 410 on which the second bonding layer B2 has been formed at a temperature of lower than 300° C.

Since the following descriptions of the eleventh operation S1311 to the thirteenth operation S1313 are the same as those of the method S1000 of manufacturing a group III nitride semiconductor template according to the tenth embodiment of the present invention, overlapping descriptions thereof will be omitted.

The above-described group III nitride semiconductor template manufactured by the method S1300 of manufacturing the group III nitride semiconductor template according to the thirteenth embodiment of the present invention may have a structure in which the support substrate 410, the reinforcement layer 420, the bonding layer 430, the reinforcement layer 420, the second buffer layer 450, the first buffer layer 440, the channel layer 460, and the re-growth layer 470 are sequentially stacked.

Hereinafter, a method S1400 of manufacturing the group III nitride semiconductor template according to the fourteenth embodiment of the present invention will be described in detail with reference to the accompanying drawings.

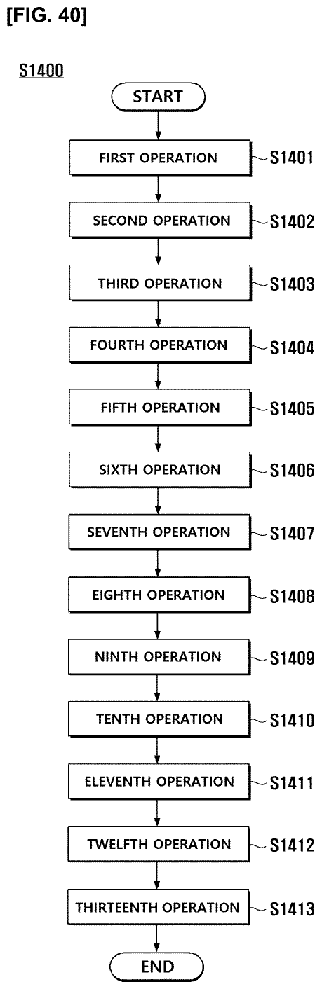

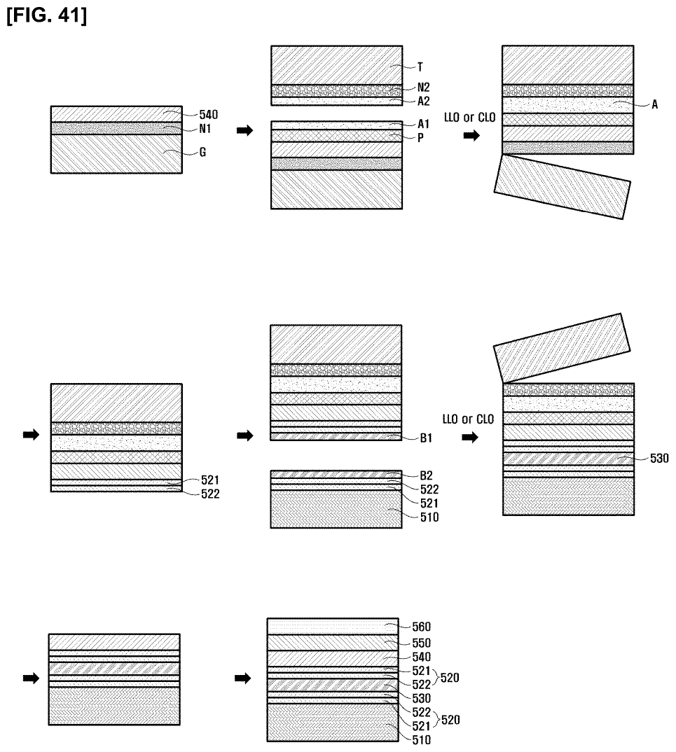

FIG. 40 is a flowchart of a method of manufacturing a group III nitride semiconductor template according to a fourteenth embodiment of the present invention, and FIG. 41 shows a process of manufacturing the group III nitride semiconductor template according to the fourteenth embodiment of the present invention.

As shown in FIGS. 40 and 41, the method S1400 of manufacturing the group III nitride semiconductor template according to the fourteenth embodiment of the present invention includes a first operation S1401, a second operation S1402, a third operation S1403, a fourth operation S1404, a fifth operation S1405, a sixth operation S1406, a seventh operation S1407, an eighth operation S1408, a ninth operation S1409, a tenth operation S1410, an eleventh operation S1411, a twelfth operation S1412, and a thirteenth operation S1413.

The first operation S1401 is an operation of preparing the growth substrate G, the temporary substrate T, and the support substrate 510.

Since the following description of the first operation S1201 is the same as that of the method S1000 of manufacturing the group III nitride semiconductor template according to the tenth embodiment of the present invention, overlapping descriptions thereof will be omitted.

The second operation S1402 is an operation of forming a first sacrificial layer N1 on the growth substrate G and then growing a high-quality group III nitride semiconductor layer on the first sacrificial layer N1 in a single layer or multiple layers and specifically, forming only a high-quality first buffer layer 540 on the first sacrificial layer N1 in a single layer or multiple layers.

The third operation S1403 is an operation of forming an epitaxy protection layer P on the first buffer layer 540 and then forming a first adhesive layer A1 on the epitaxy protection layer P.

Since the following descriptions of the third operation S1403 to the sixth operation S1406 are the same as those of the method S1000 of manufacturing the group III nitride semiconductor template according to the tenth embodiment of the present invention, overlapping descriptions thereof will be omitted.

The seventh operation S1407 is an operation of exposing the first buffer layer 540 by etching and removing the first sacrificial layer N1. A lower surface of the first buffer layer 540 from which the first sacrificial layer N1 has been removed is a nitrogen polarity surface, and for bonding with the final support substrate 510, it is very important to ensure that the lower surface of the first buffer layer 540 exposed to air has a surface in a particle-zero (0) state with residues completely removed.

Meanwhile, in some cases, it is preferable to introduce a regular or irregular patterning process to the first buffer layer 540 to increase the bonding strength with the final support substrate 510 in the subsequent process, and in some cases, it is also preferable to introduce a CMP process to increase the contact area with the final support substrate 510 in the subsequent process.

The eighth operation S1408 is an operation of forming a first bonding layer B1 on the first buffer layer 540, and in some cases, after a reinforcement layer 520 identical to that in the ninth operation S1409, which will be described below, is formed on the first buffer layer 540, the first bonding layer B1 may be formed on the reinforcement layer 520.

The ninth operation S1409 is an operation of forming a second bonding layer B2 on the support substrate 510, and in some cases, after the reinforcement layer 520 is formed on the support substrate 510, the second bonding layer B2 may be formed on the reinforcement layer 520. Here, the reinforcement layer 520 includes, more specifically, a bonding reinforcement layer 521 and a compressive stress layer 522.

Meanwhile, as shown in FIG. 44, in the present invention, the bonding reinforcement layer 521 or the compressive stress layer 522 may be omitted in some cases, and in some cases, the entire reinforcement layer 520 may be omitted so that the support substrate 510 may be in direct contact with the bonding layer 530 (or, in the eighth operation S1408, the first buffer layer 540 may be in direct contact with the bonding layer 530). This case may be a structure that induces compressive stress together with a bonding function by depositing a material with a larger coefficient of thermal expansion than the silicon (Si) support substrate 510 on the bonding layer 530.

The tenth operation S1410 is an operation of forming the bonding layer 530 by bonding the first bonding layer B1 and the second bonding layer B2 to separate the temporary substrate T. That is, the tenth operation S1410 is an operation of turning over the first buffer layer 540 on which the first bonding layer B1 has been formed (deposited) and the temporary substrate T and pressing and bonding the same to the support substrate 510 on which the second bonding layer B2 has been formed at a temperature of lower than 300° C.

Since the following descriptions of the eleventh operation S1411 and the twelfth operation S1412 are the same as those of the method S1000 of manufacturing the group III nitride semiconductor template according to the tenth embodiment of the present invention, overlapping descriptions thereof will be omitted.

The thirteenth operation S1413 is an operation of re-growing a high-quality channel layer 550 on the first buffer layer 540 and re-growing a high-quality re-grown layer 570 on the re-grown channel layer 550. In this case, the re-grown re-growth layer 570 may be an aluminum gallium nitride (AlGaN) barrier layer, but is not limited thereto, and a power semiconductor device structure, a semiconductor light-emitting device structure, a communication filter structure, etc. may be re-grown.

The above-described group III nitride semiconductor template manufactured by the method S1400 of manufacturing the group III nitride semiconductor template according to the fourteenth embodiment of the present invention may have a structure in which the support substrate 510, the reinforcement layer 520, the bonding layer 530, the reinforcement layer 520, the first buffer layer 540, the channel layer 550, and the re-growth layer 560 are sequentially stacked.

Hereinafter, a method S1500 of manufacturing the group III nitride semiconductor template according to the fifteenth embodiment of the present invention will be described in detail with reference to the accompanying drawings.

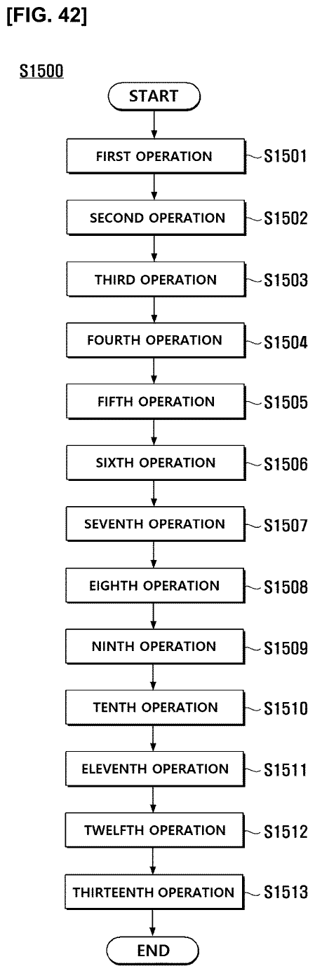

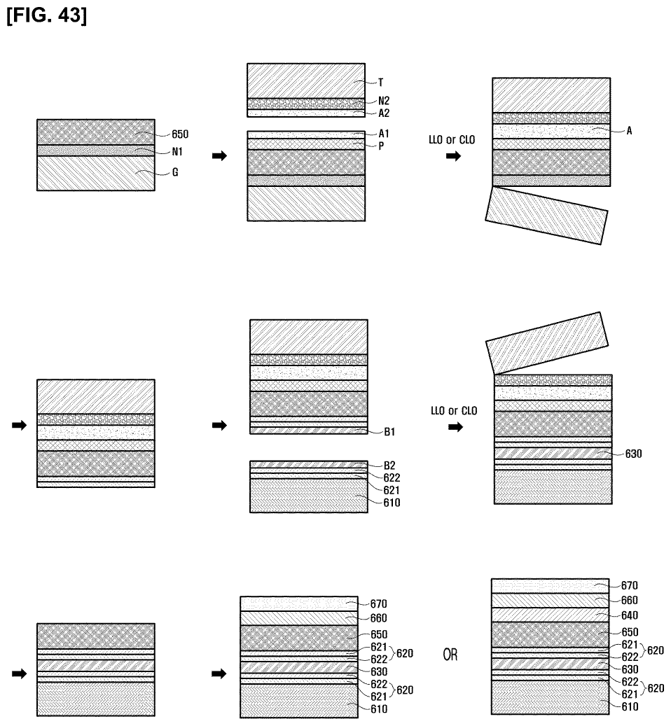

FIG. 42 is a flowchart of a method of manufacturing a group III nitride semiconductor template according to a fifteenth embodiment of the present invention, and FIG. 43 shows a process of manufacturing the group III nitride semiconductor template according to the fifteenth embodiment of the present invention.

As shown in FIGS. 42 and 43, the method S1500 of manufacturing the group III nitride semiconductor template according to the fifteenth embodiment of the present invention includes a first operation S1501, a second operation S1502, a third operation S1503, a fourth operation S1504, a fifth operation S1505, a sixth operation S1506, a seventh operation S1507, an eighth operation S1508, a ninth operation S1509, a tenth operation S1510, an eleventh operation S1511, a twelfth operation S1512, and a thirteenth operation S1513.

The first operation S1501 is an operation of preparing the growth substrate G, the temporary substrate T, and the support substrate 610.

Since the following description of the first operation S1501 is the same as that of the method S1400 of manufacturing the group III nitride semiconductor template according to the fourteenth embodiment of the present invention, overlapping descriptions thereof will be omitted.

The second operation S1502 is an operation of forming a first sacrificial layer N1 on the growth substrate G and then growing a high-quality group III nitride semiconductor layer on the first sacrificial layer N1 in a single layer or multiple layers and specifically, depositing only a high-quality second buffer layer 650 on the first sacrificial layer N1 in a single layer or multiple layers. In this case, the second formed (deposited) buffer layer 650 may be formed of a single layer or multiple layers of group III nitride semiconductors, and the second buffer layer 650 according to the present embodiment may be made of an aluminum-containing nitride or oxide (AlN, AlNO, Al2O3) material with high resistance characteristics for a leakage current even without separate doping such as iron (Fe) or carbon (C).

Since the following descriptions of the third operation S1503 to the twelfth operation S1512 are the same as those of the method S1400 of manufacturing the group III nitride semiconductor template according to the fourteenth embodiment of the present invention, overlapping descriptions thereof will be omitted.

The thirteenth operation S1513 is an operation of re-growing a high-quality group III nitride semiconductor re-growth layer on the second buffer layer 650.

Specifically, the thirteenth operation S1513 may include 1) directly re-growing the channel layer 660 on the second buffer layer 650 or 2) re-growing a new first buffer layer 640 on the second buffer layer 650 made of an aluminum-containing nitride or oxide (AlN, AlNO, Al2O3) and then re-growing a high-quality re-grown layer 670 on the channel layer 660. In this case, the first buffer layer 640 may be formed of a single layer or multiple layers of group III nitride semiconductors, and the first buffer layer 640 according to the present embodiment may be made of a gallium nitride (GaN) material with high resistance characteristics for a leakage current and doped with iron (Fe), carbon (C), etc. to increase resistance as needed.

The above-described group III nitride semiconductor template manufactured by the method S1500 of manufacturing the group III nitride semiconductor template according to the fifteenth embodiment of the present invention may have a structure in which the support substrate 610, the reinforcement layer 620, the bonding layer 630, the reinforcement layer 620, the second buffer layer 650, the channel layer 660, and the re-growth layer 670 are sequentially stacked, or have a structure in which the support substrate 610, the reinforcement layer 620, the bonding layer 630, the reinforcement layer 620, the second buffer layer 650, the first buffer layer 640, the channel layer 660, and the re-growth layer 670 are sequentially stacked.

According to the above-described methods for manufacturing the group III nitride semiconductor template according to the tenth to fifteenth embodiments, it is possible to secure a HEMT active region such as a high-quality gallium nitride (GaN) channel layer and an aluminum gallium nitride (AlGaN) barrier layer by omitting a low-quality high-resistance gallium nitride (GaN) buffer layer, thereby significantly improving the reliability and performance of the power semiconductor device, and the above methods may be applied to epitaxially growing a high-quality BGR (blue, green, red) micro-LED structure as well as implementing a high-quality power semiconductor device.

As described above, although all the components constituting embodiments disclosed herein were described as being combined or combined to operate as one, the present invention is not necessarily limited to these embodiments. That is, one or more of all the components may be selectively combined to operate as one without departing from the scope of the purpose of the present invention.

In addition, the terms such as “comprise,” “constitute,” or “have” described above mean that the corresponding component may be inherent unless otherwise stated, and thus should be construed as further including another component rather than excluding another component. All terms including technical or scientific terms have the same meaning as commonly understood by those skilled in the art to which the present invention pertains unless defined otherwise. Commonly used terms, such as terms defined in a dictionary, should be interpreted as being consistent with the contextual meaning of the related art and are not interpreted in an ideal or excessively formal meaning unless explicitly defined herein.

In addition, the above description is merely the exemplary description of the technical spirit of the present invention, and those skilled in the art to which the present invention pertains will be able to variously modify and change the present invention without departing from the essential characteristics of the present invention.

Therefore, the embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A group III nitride semiconductor template comprising:
a support substrate;
a bonding layer disposed on the support substrate;
a group III nitride semiconductor channel layer disposed on the bonding layer; and
a reinforcement layer disposed in contact with an upper surface or lower surface of the bonding layer so that bonding strength of the bonding layer is reinforced and compressive stress is induced,
wherein the reinforcement layer includes a bonding reinforcement layer that reinforce bonding strength of the bonding layer, and a compressive stress layer that induces compressive stress.

2-6. (canceled)

7. The group III nitride semiconductor template of claim 1, further comprising a group III nitride semiconductor buffer layer disposed between the bonding layer and the group Ill nitride semiconductor channel layer.

8. The group III nitride semiconductor template of claim 7, wherein the group III nitride semiconductor buffer layer is formed from a gallium nitride (GaN)-based material.

9. The group III nitride semiconductor template of claim 7, wherein the group III nitride semiconductor buffer layer is formed from a aluminum nitride (AlN)-based material.

10. The group III nitride semiconductor template of claim 7, wherein the group Ill nitride semiconductor buffer layer includes a second group III nitride semiconductor buffer layer disposed on a bonding layer, and a first group III nitride semiconductor buffer layer disposed on the second group III nitride semiconductor buffer layer,
wherein the first group Ill nitride semiconductor buffer layer is formed from a gallium nitride (GaN)-based material, and the second group III nitride semiconductor buffer layer is formed from a aluminum nitride (AlN)-based material.

11. The group III nitride semiconductor template of claim 1, the group III nitride semiconductor template further comprising a re-growth layer disposed on the group III nitride semiconductor channel layer.

12. A group III nitride semiconductor template comprising:
a support substrate;
a bonding layer disposed on the support substrate;
a group III nitride semiconductor buffer layer disposed on the bonding layer; and
a reinforcement layer disposed in contact with an upper surface or lower surface of the bonding layer so that bonding strength of the bonding layer is reinforced and compressive stress is induced.

13. The group III nitride semiconductor template of claim 12, wherein the group III nitride semiconductor buffer layer is formed from a gallium nitride (GaN)-based material.

14. The group III nitride semiconductor template of claim 12, wherein the group III nitride semiconductor buffer layer is formed from a aluminum nitride (AlN)-based material.

15. The group III nitride semiconductor template of claim 12, wherein the reinforcement layer includes a bonding reinforcement layer that reinforce bonding strength of the bonding layer, and a compressive stress layer that induces compressive stress.
